(19) United States
(12) Patent Application Publication
(10) Pub. No.: US 2024/0005977 A1
(43) Pub. Date: Jan. 4, 2024

(54) COMPUTE-IN-MEMORY DEVICES, NEURAL NETWORK ACCELERATORS, AND ELECTRONIC DEVICES

(71) Applicant: Tsinghua University, Beijing (CN)

(72) Inventors: Xueqing LI, Beijing (CN); Guodong YIN, Beijing (CN); Yiming CHEN, Beijing (CN); Lingan CHEONG, Beijing (CN); Tianyu LIAO, Beijing (CN); Wenjun TANG, Beijing (CN); Mingyen LEE, Beijing (CN); Xirui DU, Beijing (CN); Zhonghao CHEN, Beijing (CN); Mufeng ZHOU, Beijing (CN); Chen WANG, Beijing (CN); Zekun YANG, Beijing (CN); Yongpan LIU, Beijing (CN); Huazhong YANG, Beijing (CN)

(21) Appl. No.: 18/342,917

(22) Filed: Jun. 28, 2023

(30) Foreign Application Priority Data
Jun. 30, 2022 (CN) 202210769401.8
Dec. 12, 2022 (CN) 202211599037.1
Dec. 30, 2022 (CN) 202211728423.6
Mar. 9, 2023 (CN) 202310259263.3

(51) Int. Cl. G11C 11/4072; G11C 11/408; G11C 11/4094

(52) U.S. Cl. CPC G11C 11/4072; G11C 11/4085; G11C 11/4094

(57) ABSTRACT

The disclosed apparatus comprises a computing array comprising a plurality of computing modules, wherein each computing module comprises at least one storage cell, a reset switch, and a capacitor; the storage cell comprises at least one storage switch, and the storage switch comprises a storage control terminal, a storage detection terminal, and a storage terminal, the storage control terminal to receive a storage state voltage to adjust the impedance characteristic between the storage detection terminal and the storage terminal; the reset switch comprises a reset control terminal, a reset detection terminal, and a reset terminal, the reset control terminal to receive a reset voltage and the reset terminal is used to receive a reset state voltage. The disclosed apparatus also comprises a control module, which is used to control the computing array to perform at least one of a store operation, a read operation, and a compute operation.

### CROSS-REFERENCE TO RELATED APPLICATION

The present application is based upon and claims the benefit of priorities of Chinese Patent Application No. 202210769401.8, filed on Jun. 30, 2022; Chinese Patent Application No. 202211599037.1, filed on Dec. 12, 2022; Chinese Patent Application No. 202211728423.6, filed on Dec. 30, 2022; and Chinese Patent Application No. 202310259263.3, filed on Mar. 9, 2023, the entire contents of all of which are incorporated herein by reference.

### TECHNICAL FIELD

The present disclosure relates to a field of storage technology and integrated circuit technology, and particularly to a compute-in-memory devices, neural network accelerators, and electronic devices.

### BACKGROUND

With the wide application of technologies such as artificial intelligence, the demand for data processing is increasing rapidly, but the computing performance and power consumption of modern computing systems based on the von Neumann architecture are limited by the movement of data between the storage part and the computing part. Compute-in-memory is an attempt to solve this problem, which attempts to reduce energy consumption and improve performance by reducing data movement activities. Conventional storage cells are optimized for storage without considering the cost of computing. Therefore, a compute-in-memory system that can be applied on a large scale is to combine the computing part with the storage part, and has a convenient interface, with consideration of cost, power consumption, performance, scalability, and stability.

Because of the advantages of Static Random-Access Memory (SRAM) such as fast read/write speed, low read/write energy consumption, good durability, and available mature technology, many compute-in-memory designs based on SRAM have emerged in recent years. Some existing designs use foundry-provided SRAM cells comprising 6 transistors (6T). Due to the more compact layout and smaller transistors used by foundries, this SRAM cell has a smaller cell area than non-6T SRAM cells. However, when 6T SRAM cells are used for computing, the swing range of the bit line voltage is limited, which leads to problems such as read disturbance and too small signal margin. Therefore, some designs choose to sacrifice a certain area efficiency and use SRAM composing more transistors as the computing unit.

The area of compute cells has a large impact on the overall cost of a chip and is thus a very imterminalant issue in edge artificial intelligence devices. In actual industrial applications, area efficiency is one of the core indicators of compute-in-memory design. Even with the adoption of foundry-provided 6T SRAM as the compute cell, compute-in-memory designs still face the problem of inadequate area efficiency. For large neural networks, SRAM-based compute-in-memory designs face difficulties storing all weights on the chip, thus needing to repeatedly read weight values from dynamic random access memory (DRAM), causing huge energy consumption and delay. Therefore, it is necessary to further improve the area efficiency of SRAM-based compute-in-memory.

As shown in FIG. 17, traditional von Neumann architecture separates data storage and computation to maintain computational universality and control flexibility. The frequent data movement between memory and processors has become a critical bottleneck limiting the performance metrics such as latency, energy efficiency, throughput, and scalability of mainstream computing platforms such as CPUs and GPUs. Therefore, traditional computing platforms have lagged behind the computational requirements of cutting-edge applications. This situation results in many computing tasks that cannot be completed directly at the edge, requiring data transmission to cloud computing platforms for processing. This not only increases communication overhead but also contradicts the requirements of users in terms of real-time performance, interactivity, and security and privacy.

To address the aforementioned issues, compute-in-memory is a viable solution. As shown in FIG. 17, it attempts to integrate storage and computational units to reduce unnecessary data movement, thereby reducing latency, power consumption, and improving overall system performance, enabling large-scale deployment of edge computing platforms. In the development process of mainstream memories over the past decades, they have only been improved for storage requirements and lack circuit optimization design for computation. Therefore, designing an compute-in-memory system of a certain scale requires comprehensive consideration of cost, power consumption, performance, scalability, reliability, and designing appropriate data interfaces to achieve an organic integration of computation and storage units.

Currently, the compute-in-memory research conducted by academia and industry mainly relies on devices such as Static Random-Access Memory (SRAM) and emerging non-volatile memories (e-NVM) represented by Resistor Random-Access Memory. SRAM has advantages of fast read/write speed, low read/write power consumption, good durability, and mature manufacturing processes. However, the significant drawback of using SRAM units for compute-in-memory is high static power consumption and low area efficiency. In addition, there is a trade-off between noise margin and storage density in SRAM units, and read interference problems limit the voltage swing of bitlines. To ensure system reliability, many design schemes have abandoned the compact 6T SRAM structure and introduced more transistors as shown in FIG. 18, further reducing the area efficiency of SRAM. Compared to SRAM, the compute-in-memory units implemented using emerging non-volatile memories have advantages such as high area efficiency and low power consumption. However, they suffer from limitations such as immature manufacturing processes, significant device mismatch, slow read/write speeds, and poor durability, making them unsuitable for building large-scale compute-in-memory systems in the short term.

According to the specific implementation method, compute-in-memory can be divided into two categories: digital compute-in-memory and analog compute-in-memory. The advantage of digital compute-in-memory lies in its ability to maintain accuracy on par with traditional computing platforms, while its improvement in computational efficiency is relatively limited. The advantage of analog compute-in-memory lies in its higher energy efficiency, but it has drawbacks such as certain accuracy loss and additional data conversion overhead. Analog compute-in-memory can be further divided into charge-domain computing and current-domain computing. The former is based on the principle of charge conservation and performs weighted accumulation operations based on the capacitance values. It has the advantage of high matching accuracy but introduces delay costs and area overhead due to capacitors. The latter is based on Kirchhoff s current law and performs weighted accumulation operations. It has the advantage of fast operation speed but relatively lower accuracy.

In the design of compute-in-memory circuits, the area efficiency of the computational unit is a key metric. On one hand, the area of the computational unit directly determines the manufacturing cost and commercial potential of the chip. On the other hand, due to the large number of parameters trained by mainstream neural network algorithms, compute-in-memory chips require frequent data interaction with Dynamic Random-Access Memory (DRAM) during the execution of AI algorithms, introducing additional delays and energy consumption. Therefore, improving the area efficiency of compute-in-memory can reduce the number of DRAM accesses, contributing to the overall performance improvement of the system.

Content-addressable memory (CAM) is a type of memory with search functionality. Its characteristic is that when performing a search operation, input data is used as the search content, the contents stored in the memory are matched with the input data, and the address of the matching data in the memory is outputted as the search result.

The characteristic of content-based search in CAM enables it to support the needs of some key applications. In computer networks, a routing table is a collection of data stored in a router or networked computer. The routing table stores paths pointing to specific network addresses, and the search for the routing table is a content-based search method as described earlier. Traditional search methods such as linear search and hash table search are software search methods based on random access memory (RAM), which are slow and cannot meet the search requirements of high-speed real-time communication systems. However, the hardware search method based on CAM completes the search within one clock cycle by querying all data in the memory in the same clock cycle, making the search speed unaffected by the amount of routing table data. The average search speed is much faster than that of the RAM-based search method, which significantly improves network transmission speed and network performance.

Currently, the common CAM in academia is mainly based on storage units composed of Static Random-Access Memory (SRAM) cells, Resistor Random-Access Memory (ReRAM) cells, Ferroelectric gate field-effect transistors (FeFET), and so on. These storage units are usually composed of multiple devices, with a large area and high power consumption. Since the area determines the manufacturing cost of the CAM chip, and power consumption affects the application value of the CAM chip, it is necessary to reduce the complexity of CAM storage units, thereby improving the area efficiency and reducing the power consumption of CAM.

To improve overall system throughput and energy efficiency, a compute-in-memory architecture has been proposed to eliminate the “memory wall” bottleneck in von Neumann architectures. Compute-in-memory integrates the memory and processing units, enabling computations to be performed within the memory units themselves, reducing the additional consumption associated with data movement. This makes compute-in-memory architectures highly promising for deploying machine learning models on edge devices.

Compute-in-memory shares similar computing principles among different types of memory devices, such as Static Random Access Memory (SRAM), Dynamic Random Access Memory (DRAM), Flash memory, Resistive Random-Access Memory (ReRAM), and other emerging memory technologies. However, due to its mature manufacturing process, durability, flexibility in read/write operations, and fast access speed, SRAM is currently the mainstream choice for compute-in-memory architectures. However, using 6T SRAM for compute-in-memory faces challenges like read disturbance due to the limited voltage swing range of the bit-lines during 6T SRAM cell computation. Therefore, to improve the performance of SRAM-based compute-in-memory, some circuits utilize SRAM configurations with more transistors, such as 8T SRAM, 10T SRAM, and 12T SRAM.

To enable the widespread adoption of AI applications on edge devices, the area efficiency of the storage units in compute-in-memory devices is a crucial consideration during design. However, due to the low storage density characteristics of SRAM, even with the smallest 6T SRAM cells employed on the chip, large-scale neural networks still face challenges in complete deployment on a chip. This leads to the need for frequent reading of weight values from off-chip memory during computations, resulting in significant data transfer energy consumption and latency. Therefore, improving the area efficiency of compute-in-memory devices becomes a core optimization objective.

### SUMMARY

According to a first aspect of the present disclosure, a compute-in-memory apparatus is provided, and the apparatus comprises:
a computing array, which comprises a plurality of computing modules, wherein each computing module comprises at least one storage cell, a reset switch, and a capacitor, the storage cell comprises at least one storage switch, wherein:
the storage switch comprises a storage control terminal, a storage detection terminal, and a storage terminal, the storage terminal is connected to a data storage line to receive a storage state voltage and the associated information, and the storage control terminal is connected to a control word-line to receive a control voltage to adjust the impedance characteristic between the storage detection terminal and the storage terminal;
the reset switch comprises a reset control terminal, a reset detection terminal, and a reset terminal. The reset control terminal is connected to a control word-line to receive a reset voltage to adjust the impedance characteristic between the reset detection terminal and the reset terminal;
the reset terminal is connected to a reset state voltage line to receive a reset state voltage, the reset detection terminal and a first terminal of the capacitor are connected to an output terminal of the storage cell, and a second terminal of the capacitor is connected to a computing bit-line;
a control module, which is connected to the computing array to control the computing array to perform at least one of a store operation, a read operation and a compute operation.

In an embodiment of the present disclosure, the storage cell comprises a first storage switch and a second storage switch, wherein the storage detection terminals of both the first storage switch and the second storage switch are connected to the output terminal of the storage cell.

In an embodiment of the present disclosure, the computing module additionally comprises a selection switch. The selection switch comprises a selection control terminal, a first detection terminal, and a second detection terminal, wherein,
the selection control terminal is connected to a control bit line to receive a control voltage to adjust the impedance characteristic between the first selection detection terminal and the second selection detection terminal;
the first detection terminal is connected to the output terminal of the storage cell, and the second detection terminal is connected to each storage detection terminal.

In an embodiment of the present disclosure, the storage cell comprises a first selection switch, a second selection switch, a third storage switch, a fourth storage switch, a fifth storage switch, and a sixth storage switch,
the first detection terminals of the first selection switch and the second selection switch are connected to the output terminal of the storage cell, the second detection terminal of the first selection switch is connected to the storage detection terminals of the third storage switch and the fourth storage switch, the selection control terminal of the first selection switch is connected to a first control bit line, and the selection control terminal of the second selection switch is connected to a second control bit line,
the storage control terminals of the third storage switch and the fifth storage switch are connected to a second control word-line, and the storage terminals of both the third storage switch and the fourth storage switch are connected to a first data storage line. The storage control terminals of both the fourth storage switch and the sixth storage switch are connected to a third control bit line, and the storage terminals of both the fifth storage switch and the sixth storage switch are connected to a second data storage line.

In an embodiment of the present disclosure, the compute operation includes a multiply-and-accumulate operation. The control module is additionally used to:
activate the storage control terminal of the storage switch of the storage cell of the target computing module, thereby a logic AND operation is performed on the information carried by the control word-line connected to the storage control terminal of the activated storage switch and the information associated with the storage state voltage of the storage terminal of the activated storage switch;
obtain a result of the multiply-and-accumulate operation through the computing bit-line.

In an embodiment of the present disclosure, the compute operation includes a logic AND operation. The control module is additionally used to:
activate both the reset control terminal of the reset switch of a target computing module and the computing bit-line, thereby forming a voltage difference between the two terminals of the capacitor of the target computing module;
turn off the reset control terminal and set the computing bit-line into floating state;
input a set of operands for the logic AND operation via the reset control terminal, the control word-line connected to the storage control terminal of the storage switch, and the data storage line connected to the storage terminal of the storage switch;
obtain a result of the logic AND operation on the set of operands through the computing bit-line.

In an embodiment of the present disclosure, within each column of the computing array, the control bit lines and computing bit-lines of at least one computing module are connected; within each row of the computing array, the control word-lines, data storage lines and reset state voltage lines of at least one computing module are connected.

In an embodiment of the present disclosure, the compute operation includes a multiply-and-accumulate operation. The control module is additionally used to:
control one or more columns of computing modules of the computing array to perform the multiply-and-accumulate operation, and/or control some or all of the computing modules connected to the same computing bit-line to perform the multiply-and-accumulate operation.

In an embodiment of the present disclosure, the control module is additionally used to:
control the computing modules connected to different computing bit-lines to perform a pipelined compute operation.

In an embodiment of the present disclosure, the control module is additionally used to:
control each of the control word-lines, control bit lines, computing bit-lines, data storage lines, and reset state voltage lines to be grounded, whereby the computing array enters an idle mode.

According to a second aspect of the present disclosure, a neural network accelerator is provided. The neural network accelerator comprises at least one neural network module, the neural network module comprises at least one original convolutional layer, and the original convolutional layer comprises a backbone layer that has fixed weights and a branch layer that has adjustable weights. The backbone layer comprises one or more convolutional layers, and the branch layer at least comprises a first branch convolutional layer, a second branch convolutional layer, and a third branch convolutional layer, which are sequentially connected. The input channel number of the first branch convolutional layer is equal to that of the backbone layer, the output channel number of the third branch convolutional layer is equal to that of the backbone layer, the input channel number of the second branch convolution layer is smaller than that of the backbone layer, and the output channel number of the second branch convolution layer is smaller than that of the backbone layer,
wherein, the backbone layer and the convolutional layers of the branch layer are implemented using the compute-in-memory apparatus.

In an embodiment of the present disclosure, the backbone layer and the first branch layer are used to receive an input to the neural network, and an output of the neural network module is obtained by aggregating the output of the backbone layer and the output of the third branch convolution layer.

In an embodiment of the present disclosure, in a training process of the neural network accelerator, the weights of each backbone layer are fixed, and/or the weight gradient of the backbone layer is zero in a back-propagation stage of the training process, and the weights of each branch layer are adjusted by gradient descent.

According to a third aspect of the present disclosure, an electronic device is provided, which includes the compute-in-memory apparatus, or includes the neural network accelerator.

The compute-in-memory apparatus of embodiments of the present disclosure comprises a computing array and a control module. The computing array comprises a plurality of computing modules, wherein each computing module comprises at least one storage cell, a reset switch Qf and a capacitor. The storage cell comprises at least one storage switch, wherein: the storage switch comprises a storage control terminal, a storage detection terminal, and a storage terminal, the storage terminal is connected to a data storage line to receive a storage state voltage and the information associated with the storage state voltage; the storage control terminal is connected to a control word-line to receive a control voltage to adjust the impedance characteristic between the storage detection terminal and the storage terminal. The reset switch Qf comprises a reset control terminal, a reset detection terminal, and a reset terminal, the reset control terminal is connected to a control word-line to receive a reset voltage to adjust the impedance characteristic between the reset detection terminal and the reset terminal, and the reset terminal is connected to a reset state voltage line to receive a reset state voltage. The reset detection terminal and a first terminal of the capacitor are connected to the output terminals of at least one storage cell, and a second terminal of the capacitor is connected to the compute word-line. The control module controls the computing array to perform at least one of a store operation, a read operation, and a compute operation. Embodiments of the present disclosure include at least one storage switch, while the storage cells of the related art include at least six transistors, therefore, embodiments of the present disclosure have higher area efficiency. In addition, embodiments of the present disclosure store data through storage state voltages, and a single storage switch can realize multi-bit storage, which further improves area efficiency and significantly reduces the power consumption of data access and compute-in-memory.

According to a fourth aspect of the present disclosure, a compute-in-memory apparatus is provided, the apparatus comprises: a plurality of read-only memory devices, a plurality of current sources, and a control module, wherein:
each storage terminal of the read-only memory devices is connected to one end of the corresponding current source, and the other end of the current source is used to receive a preset voltage for data storage;
the control terminal of each read-only memory device is connected to the corresponding control word line to receive the data to be computed;
the output terminal of each read-only memory device is used to output the result data through a compute bit line;
the control module is used to select the corresponding read-only memory devices for operation through the control word line and output the result data, wherein the operation includes multiplication and data read operations, if the operation is a multiplication operation, then the result data is the product of the stored data corresponding to the preset voltage received by the current source and the data to be computed input through the control word line; if the operation is a data read operation, the result data is the stored data corresponding to the preset voltage received by the current source.

In an embodiment of the present disclosure, the apparatus comprises a plurality of compute modules, wherein each compute module comprises a read-only memory device; the output terminal of the read-only memory device is directly connected to the corresponding compute bit line to output the result data.

In an embodiment of the present disclosure, the apparatus comprises a plurality of compute modules, wherein each compute module comprises two or more read-only memory devices and at least one selection device; the control terminals of the selection devices are connected to the corresponding control bit lines, the input terminals of the selection devices are connected to the output terminals of the read-only memory devices, and the output terminals of the selection devices are connected to the corresponding compute bit lines to output the result data.

In an embodiment of the present disclosure, the read-only memory devices in each compute module are arranged in a multi-row and multi-column layout, the control terminals of each row of read-only memory devices are connected to the same control word line, the output terminals of each column of read-only memory devices are connected to the same selection devices, and the output terminals of each selection device are connected to the same compute bit line.

In an embodiment of the present disclosure, a plurality of compute modules are combined into a multi-row and multi-column layout through electrical connections, wherein the control word lines of the compute modules in the same row are electrically connected, the control bit lines of the compute modules in the same column are electrically connected, the compute bit lines of the compute modules in the same column are electrically connected, and the compute bit lines are connected to the power supply voltage through selection devices.

In an embodiment of the present disclosure, the operation further includes a multiply-and-accumulate operation, and the result data includes the multiply-and-accumulate result; the control module is further used to:
input a group of data through the control word lines, activate the control terminals of the corresponding selection devices through the control bit lines to select the compute modules participating in the multiply-and-accumulate operation, use the control word lines to select the read-only memory devices participating in the computation in each compute module, perform a multiplication operation on the input data and the stored data corresponding to the preset voltage received by the current sources in the compute modules, accumulate the multiplication results obtained in each compute module and output them in the form of a current through the compute bit lines to obtain the multiply-and-accumulate result.

In an embodiment of the present disclosure, the control module is further used to adjust the signal timing of the control word lines and control bit lines to achieve pipelining operations between different compute bit lines.

In an embodiment of the present disclosure, the control module is further used to control the compute modules to enter a working mode or an idle mode, wherein
in the working mode, the read-only memory devices in the compute modules perform the operations,
in the idle mode, no current flows inside the compute modules.

According to a fifth aspect of the present disclosure, a neural network accelerator is provided, wherein the neural network accelerator comprises the compute-in-memory apparatus.

According to a sixth aspect of the present disclosure, an electronic device is provided, wherein the electronic device comprises a neural network accelerator.

According to a seventh aspect of the present disclosure, a content-addressable storage device is provided, including:
Multiple storage units, each storage unit including the read-only memory device and the capacitor. The read-only memory device includes the first input terminal, the second input terminal, and the output terminal, with the output terminal of the read-only memory device connected to the first terminal of the capacitor. The read-only memory device stores data based on the connection relationship between the first input terminal, the second input terminal, and the output terminal. Specifically, when the first input terminal of the read-only memory device is connected to the output terminal, the memory device stores the first data. Alternatively, when the second input terminal of the memory device is connected to the output terminal, the read-only memory device stores the second data, with the voltage levels of the first and second stored data being different.

The control module, connected to various storage units, is used to control the voltage of the first and second input terminals of the read-only memory devices in each storage unit, in order to perform the required operation.

The operation result of the target operation is determined based on the voltage of the second terminal of the capacitor as described.

In one possible implementation, the required operation includes a XNOR logic operation, and the first and second input terminals of each memory device are voltage-controlled to perform the required operation, including:
Grounding the first and second input terminals of the read-only memory device, and discharging the capacitor;
Floating the first and second input terminals of the read-only memory device, and leaving the output terminal floating electrically;
Applying the signals to the first and second input terminals of the read-only memory device according to the input data, and executing the XNOR logic operation between the input data and the stored data with the device.

The required operation's result is then determined based on the voltage of the second terminal of the capacitor, obtaining the XNOR logic operation result between the input data and the stored data.

In one possible implementation, the control module is connected to the first input terminal of the read-only memory device via the first bitline, and to the second input terminal of the read-only memory device via the second bitline. The control module is also connected to the second terminal of the capacitor through the matching line. Multiple storage units are combined into a layout of multiple rows and columns through electrical connections, where the electrical connection method is such that the matching lines of some or all storage units in the same row are connected, and the first and second bitlines of some or all storage units in the same column are respectively connected.

In one possible implementation, the required operation mentioned includes content-addressable operation, which involves controlling the voltage of the first and second input terminals of the read-only memory device for each storage unit to perform the required operation, including:
Grounding the first and second inputs of each read-only memory element in one or more rows of storage units and discharging the corresponding capacitors;
Floating the first and second inputs of each read-only memory element in one or more rows of storage units and leaving the corresponding match lines floating;
Applying the signals to the first and second input terminals of the read-only memory devices in one or more rows of storage units, according to the input data, to perform the content addressing operations in one or more rows. The operation results of the required operations are determined by the voltages of the second terminal of the capacitors, obtaining the addressing calculation result of the input data and the stored data, based on the voltage of the match lines of each activated row of storage units.

In one possible implementation, the required operation includes a content-addressable operation, which involves controlling the voltage of the first and second input terminals of the read-only memory device for each storage unit to perform the required operation, including:
Grounding the first and second input terminals of each read-only storage device in the storage units connected to the same matching line, and discharging each capacitor connected to the storage units connected to the same matching line;
Floating the first and second input terminals of each read-only storage device in the storage units connected to the same matching line, and leaving the matching lines electrically floating;
Applying the signals to the first and second input terminals of the read-only memory devices in the storage units connected to the same matching line, according to the input data, to perform the content addressing operations. The operation results of the required operations are determined by the voltages of the second terminal of the capacitors, obtaining the addressing calculation result of the input data and the stored data, based on the voltage of the match.

In one possible implementation, the required operation also includes a read operation to retrieve the data stored in the storage unit. The control module is also used to: maintain complementary voltage levels at the first and second input terminals, distinguish whether the output terminal is connected to the first or second input terminal based on the magnitude of the output voltage, and thereby obtain the stored data.

In one possible implementation, the control module is also used to control at least one storage unit to operate in a working mode or an idle mode, wherein the storage unit in the working mode performs the required operation, or the first input terminal, the second input terminal, and the output terminal of the read-only memory device of the storage unit in the idle mode are set to low level.

According to an eighth aspect of this disclosure, a memory is provided, which includes a content-addressable storage device.

According to a ninth aspect of this disclosure, an electronic device is provided, which includes the memory as described above.

Various aspects of the implementations disclosed herein implement content-addressable storage devices based on read-only memory devices, which can improve the area efficiency of the content-addressable storage device, reduce or even eliminate unnecessary energy consumption caused by memory access, and thus achieve the goal of reducing power consumption.

According to a tenth aspect of the present disclosure, a high-density CiM device based on read-only memory (ROM) devices is provided, characterized by the following components:
multiple computing modules, each of which includes at least one ROM device, multiple selection devices, electrical sources, data storage lines, control word-lines, computing bit-lines, and data selection control lines, wherein:
the control terminal of the ROM device is connected to the corresponding control word-line to receive control signals, the two data terminals of the ROM device are connected to different data storage lines, the data storage lines are connected to the electrical source and computing bit-lines through selection devices, the data status of each data storage line is represented by current or voltage form depending on the type of electrical source, the control terminal of the selection device is connected to the corresponding data selection control line to receive data selection control signals, which are used to enable the corresponding selection device;
a control module is connected to the control word-lines and data selection control lines of each computing module, it is used to select the desired ROM devices and selection devices through the control word-lines and data selection control lines, and output the resulting data through the computing bit-lines.

In an embodiment of the present disclosure, the device comprises selection devices, specifically data selection devices, the data selection devices consist of upper data selection devices and lower data selection devices, the upper data selection devices include a first upper data selection device and a second upper data selection device, the lower data selection devices include a first lower data selection device and a second lower data selection device, the device also includes data selection control lines, namely the first data selection control line and the second data selection control line, additionally, it comprises data storage lines, which are the first data storage lines and the second data storage lines;
both the input terminals of the first lower data selection device and the second lower data selection device are connected to the electrical source;
the output terminal of the first lower data selection device is connected to the input terminal of the second upper data selection device through the first data storage line;
the output terminal of the second lower data selection device is connected to the input terminal of the first upper data selection device through the second data storage line;
the control terminal of the first lower data selection device and the control terminal of the first upper data selection device are both connected to the first data selection control line;
the control terminal of the second lower data selection device and the control terminal of the second upper data selection device are both connected to the second data selection control line;
the output terminals of the first upper data selection device and the second upper data selection device are connected to the computing bit-lines;
the first data terminal and the second data terminal of each ROM device are respectively connected to the corresponding first data storage line and second data storage line.

In an embodiment of the present disclosure, the device is characterized by the inclusion of column selection devices as part of the selection devices, wherein:
the control terminals of each column selection device are connected to control lines to receive column selection signals, the input terminals of the serially connected components formed by the column selection devices and lower data selection devices are connected to the electrical source, the output terminals of these serially connected components are connected to the respective data storage lines.

In an embodiment of the present disclosure, the device is characterized by having multiple current sources or multiple voltage sources as the electrical source, if the electrical source is multiple voltage sources, the computing module further includes a reset switch and a capacitor, the control terminal of the reset switch is connected to a reset control word-line to receive a reset signal, the reset terminal of the reset switch is used to receive a reset state voltage, the reset detection terminal of the reset switch and the first terminal of the capacitor are connected to the output terminal of the upper data selection device, the second terminal of the capacitor is connected to the computing bit-line.

In an embodiment of the present disclosure, the device is characterized by having each ROM devices in the computing module in a layout of multiple rows and columns, wherein:
the control terminals of each row of ROM devices are connected to the same control word-line, the two data terminals of each ROM device in each column are respectively connected to the corresponding first data storage line and second data storage line, the output terminals of each upper data selection device are connected to the corresponding computing bit-line either through a capacitor or directly, and the result is outputted through the computing bit-line.

In an embodiment of the present disclosure, the device is characterized by the feature that the first data storage lines connected to each individual ROM device in the (K+1)th column is the second data storage lines connected to each individual ROM device in the Kth column, where K is an integer.

In an embodiment of the present disclosure, the device is characterized by the following:
the selection devices include data selection devices and column selection devices, the data selection devices include upper data selection devices and lower data selection devices, the upper data selection devices consist of the first upper data selection device and the second upper data selection device, the lower data selection devices consist of the first lower data selection device and the second lower data selection device, the data selection control lines include the first data selection control line and the second data selection control line, the data storage lines include the first data storage lines and the second data storage lines;
the input terminals of the first lower data selection device and the input terminals of the second lower data selection device are connected to each other and connected to the electrical source;
the output terminal of the first lower data selection device is connected to the input terminal of the second upper data selection device, and it is also connected to the input terminal of the corresponding column selection device;
the output terminal of the second lower data selection device is connected to the input terminal of the first upper data selection device, and it is also connected to the input terminal of another column selection device, the output terminals of each column selection device are connected to the corresponding data storage lines;
the output terminals of the first upper data selection device and the second upper data selection device are connected to the computing bit-line;
the control terminal of the first lower data selection device and the control terminal of the first upper data selection device are both connected to the first data selection control line;
the control terminal of the second lower data selection device and the control terminal of the second upper data selection device are both connected to the second data selection control line;
the first data terminal and the second data terminal of each ROM device are respectively connected to the corresponding first data storage line and second data storage line.

In an embodiment of the present disclosure, the device is characterized by having each ROM devices in the computing module in a layout of multiple rows and columns, wherein:
the control terminals of each row of ROM devices are connected to the same control word-line, the two data terminals of each ROM device in each column are respectively connected to the corresponding first data storage line and second data storage line, the output terminals of each upper data selection device are connected to the corresponding computing bit-line either through a capacitor or directly, and the result is outputted through the computing bit-line.

In an embodiment of the present disclosure, the device is characterized by the feature that the first data storage lines connected to each individual ROM device in the (K+1)th column is the second data storage lines connected to each individual ROM device in the Kth column, where K is an integer;
wherein, multiple column selection devices in each column of ROM devices share the same set of data selection devices, the output terminals of each first upper data selection device and each second upper data selection device are connected to the same computing bit-line either through a capacitor or directly.

In an embodiment of the present disclosure, the device is characterized by the following:
multiple computing modules are arranged in a layout of multiple rows and multiple columns through electrical connections, the control word-lines of computing modules in the same row are electrically connected, the control bit-lines of computing modules in the same column are electrically connected, the computing bit-lines of computing modules in the same column are electrically connected.

In an embodiment of the present disclosure, the device is characterized by the following:
the target operations include multiplication, data reading, and multiply-accumulate (MAC) operations, in the case of multiplication, the result data is the product of the stored data of the corresponding ROM device at the respective moment and the input data from the control word-line, in the case of data reading operation, the result data is the stored data of the corresponding read-only memory device at the respective moment, the result data also includes the MAC result;
the control module is further used to control one or multiple columns of computing modules to perform MAC operations, and/or control a portion or all of the computing modules connected to the same compute bit-line to perform MAC operations;
specifically, the control module input a set of data through the control word-line and select the computing modules participating in the MAC operation, select the ROM devices participating in the calculation in each computing module using the control word-line, select the stored data participating in the calculation using the data selection control line, perform the multiplication operation between the input data and the stored data in each computing module, accumulate the multiplication results from each computing module through the computing bit-line and output the MAC result.

In an embodiment of the present disclosure, the device is characterized by the following:
the control module is further used to control each computing module to enter the working mode or idle mode. In the working mode, each computing module performs the target operations.

In an embodiment of the present disclosure, the device is characterized by the following:
the control module is further used to control the entry of each computing module into the working mode or idle mode. In the working mode, each computing module performs the target operations.

According to an eleventh aspect of the present disclosure, a neural network accelerator, characterized by comprising a high-density CiM based on ROM, is provided.

According to a twelfth aspect of the present disclosure, an electronic device, characterized by comprising a high-density CiM device based on ROM, is provided.

The disclosed embodiment of the high-density CiM device based on ROM implements multi-level cell storage for a single ROM, enabling each computing module to have multi-bit data storage and computation capabilities. This improves the storage density of the device and enhances the area efficiency of CiM, thereby reducing or even eliminating the device's need for off-chip memory access.

It should be understood that the general description above and the detailed description below are exemplary and explanatory only, and are not intended to limit the disclosure. The other features and aspects of the disclosure will become apparent from the following detailed description of exemplary implementations with reference to the accompanying drawings.

### BRIEF DESCRIPTION OF THE DRAWINGS

The accompanying drawings here are incorporated into the description and constitute a part of the present description. These drawings show embodiments consistent with the present disclosure, and are used together with the description to explain the technical solution of the present disclosure.

FIG. 1 schematically illustrates a compute-in-memory apparatus according to embodiments of the present disclosure.

FIG. 2 schematically illustrates a storage cell according to embodiments of the present disclosure.

FIG. 3 schematically illustrates a storage cell according to embodiments of the present disclosure.

FIG. 4 schematically illustrates a storage cell according to embodiments of the present disclosure.

FIG. 5 schematically illustrates a compute-in-memory apparatus according to embodiments of the present disclosure.

FIG. 6a and FIG. 6b are schematic illustrations of a MIM capacitor and a MOM capacitor according to embodiments of the present disclosure respectively.

FIG. 7a schematically illustrates a circuit symbol of a metal-oxide-semiconductor field effect transistor according to embodiments of the present disclosure, and FIG. 7b schematically illustrates a drain-source current versus gate-source voltage hysteresis characteristic curve of a metal-oxide-semiconductor field effect transistor according to embodiments of the present disclosure.

FIG. 8 schematically illustrates a computing module according to embodiments of the present disclosure performing a logic AND operation.

FIG. 9 schematically illustrates a compute-in-memory apparatus according to embodiments of the present disclosure.

FIG. 10 schematically illustrates the equivalent capacitance of the circuit shown in FIG. 9 which requires charging when performing the multiply-and-accumulate operation.

FIG. 11 schematically illustrates the computing array according to embodiments of the present disclosure performing a multiply-and-accumulate operation.

FIG. 12 schematically illustrates the idle mode of the compute-in-memory apparatus according to embodiments of the present disclosure.

FIG. 13 schematically illustrates an implementation of the pipelined operation using the computing array according to the embodiments of the present disclosure.

FIG. 14 schematically illustrates the neural network accelerator according to the embodiments of the present disclosure.

FIG. 15 schematically illustrates a neural network accelerator system comprising the neural network accelerator.

FIG. 16 shows a block diagram of an electronic device according to embodiments of the present disclosure.

FIG. 17 shows a comparison diagram between the von Neumann architecture and the compute-in-memory (CiM) architecture.

FIG. 18 shows a schematic symbol of a metal-oxide-semiconductor field-effect transistor according to an implementation of the present invention.

FIG. 19 shows a typical situation of drain-source current versus gate-source voltage for the metal-oxide-semiconductor field-effect transistor according to an implementation of the present invention.

FIG. 20 shows a schematic diagram of a compute-in-memory device according to the present disclosure.

FIG. 21 shows a schematic diagram comparing the area of the calculation module in the present disclosure with that of related technology.

FIGS. 22a and 22b shows schematic diagrams of the calculation module according to an implementation of the present disclosure.

FIG. 23 shows schematic diagrams of using the calculation module of the compute-in-memory device according to the present disclosure for the multiplication operation.

FIG. 24 shows a structural schematic diagram of the compute-in-memory device according to the present invention.

FIG. 25 shows schematic diagrams of performing multiply-accumulate operations with the compute-in-memory device according to the present disclosure.

FIG. 26 shows a schematic diagram of the calculation module of the compute-in-memory device according to the present disclosure being configured as an idle mode.

FIGS. 27a and 27b show schematic diagrams of performing pipeline operations with the compute-in-memory device according to the present disclosure.

FIG. 28 shows a schematic diagram of a neural network accelerator according to an implementation of the present disclosure.

FIG. 29 shows a schematic diagram of a content-addressable storage device according to an implementation of the present disclosure.

FIG. 30 shows the structural schematic of a MIM capacitor and a MOM capacitor that can be used in the implementation of the present disclosure.

FIG. 31 shows a schematic diagram of performing an XNOR logic operation on a storage unit of the content-addressable storage device according to the implementation of the present disclosure.

FIG. 32 shows a schematic diagram of the content-addressable storage device according to the implementation of the present disclosure.

FIG. 33 shows a proportional schematic diagram of equivalent capacitors that need to be charged and storage units with logic operation results of ‘1’ when performing multiply-accumulate operations on the content-addressable storage device according to the implementation of the present disclosure.

FIG. 34 shows a schematic diagram of performing content addressing operations using the content-addressable storage device according to the implementation of the present disclosure.

FIG. 35 shows a schematic diagram of the idle mode of the content-addressable storage device using the implementation of the present disclosure.

FIG. 36 shows a schematic diagram of the content-addressable storage device using the implementation of the present disclosure.

FIG. 37 schematically illustrates the CiM device based on ROM according to embodiments of the present disclosure;

FIG. 38 schematically illustrates the circuit symbol of a metal-oxide-semiconductor field-effect transistor (MOSFET) according to embodiments of the present disclosure;

FIG. 39 schematically illustrates the i_{DS}-v_{GS} characteristic of the MOSFET according to embodiments of present disclosure;

FIGS. 40a and 40b schematically illustrate the computing module implemented in the current domain according to embodiments of present disclosure;

FIGS. 41a and 41b schematically illustrate the computing module implemented in the charge domain according to embodiments of present disclosure;

FIGS. 42a and 42b schematically illustrate the computing module implemented in the first type of sharing of selection devices in the current domain and charge domain according to embodiments of present disclosure;

FIGS. 43a and 43b schematically illustrate the computing module implemented in the second type of sharing of selection devices in the current domain and charge domain according to embodiments of present disclosure;

FIG. 44 schematically illustrates the structure of the CiM device according to embodiments of the present disclosure;

FIGS. 45a and 45b schematically illustrate the multiplication operation of the computing module implemented in the current domain according to embodiments of present disclosure;

FIGS. 46a and 46b schematically illustrate the multiplication operation of the computing module implemented in the charge domain according to embodiments of present disclosure;

FIGS. 47a and 47b schematically illustrate the Multiply- and Accumulate (MAC) operation of the computing module implemented in the current domain according to embodiments of present disclosure;

FIGS. 48a and 48b schematically illustrate the Multiply- and Accumulate (MAC) operation of the computing module implemented in the charge domain according to embodiments of present disclosure;

FIGS. 49a and 49b schematically illustrate the idle mode of the computing module implemented in the current domain and the charge domain according to embodiments of present disclosure;

FIGS. 50a, 50b, 50c and 50d schematically illustrate the pipeline operation of the CiM device according to embodiments of present disclosure;

FIG. 51 schematically illustrates the neural network accelerator according to embodiments of present disclosure.

### DETAILED DESCRIPTION

Various exemplary embodiments, features, and aspects of the present disclosure will be described in detail below with reference to the accompanying drawings. The same reference signs in the drawings represent the same or similar elements with the same or similar functions. While various aspects of the embodiments are illustrated in drawings, the drawings are not necessarily drawn to scale unless specifically indicated.

In the description of the present disclosure, it shall be understood that the orientations or positional relationships indicated by terms such as “length”, “width”, “upper”, “lower”, “front”, “rear”, “left”, “right”, “vertical”, “horizontal”, “top”, “bottom”, “inner”, “outer”, etc. are based on the orientations or positional relationships shown in the drawings, and are only for the convenience of describing the present disclosure and simplifying the description, but not to indicate or imply that an apparatus or element referred to must have a particular orientation or must be constructed or operated in a particular orientation, and thus shall not be understood as a limitation of the present disclosure.

In addition, the terms “first” and “second” are used for descriptive purposes only, and shall not be understood as indicating or implying relative significance or implicitly specifying the quantity of indicated technical features. Thus, a feature defined as “first” or “second” may explicitly or implicitly include one or more of these features. In the description of the present disclosure, “plurality” means two or more, unless otherwise clearly and specifically defined.

In the present disclosure, unless otherwise clearly and specifically defined and limited, terms such as “install”, “connect”, “connection” and “fix” shall be understood in a broad sense, for example, the indicated relationship can be a fixed connection, a detachable connection, or integrated; it can be mechanically connected or electrically connected; it can be directly connected or indirectly connected via a medium, and it can be an internal connection of two components or an interaction relationship between two components. A person skilled in the art can understand the specific meanings of the above terms in the present disclosure according to specific situations.

The word “exemplary” is used exclusively herein to mean “serving as an example, embodiment, or illustration.” Any embodiment described herein as “exemplary” is not necessarily to be understood as superior or better than other embodiments.

The term “and/or” herein is just an association relationship describing associated objects, which means that there can be three relationships, for example, A and/or B can mean the following three situations: A exists alone, A and B exist simultaneously, or B exists alone. In addition, the term “at least one of” herein means any one of a variety or any combination of two or more of a variety, for example, including at least one of A, B, and C can mean including any one or more elements selected from the set formed by A, B and C.

In addition, in order to better describe the present disclosure, numerous details are given in the following specific embodiments. It will be understood by a person skilled in the art that the present disclosure may be practiced without some of the specific details. In some instances, methods, means, components, and circuits that are well known to a person skilled in the art have not been described in detail in order to highlight the subject of the present disclosure.

Storage cells in the related art of compute-in-memory include at least 6 transistors, thus having relatively low area efficiency and high power consumption.

The compute-in-memory apparatus of embodiments of the present disclosure comprises a computing array and a control module. The computing array comprises a plurality of computing modules, wherein each computing module comprises at least one storage cell, a reset switch Qf and a capacitor. The storage cell comprises at least one storage switch, wherein: the storage switch comprises a storage control terminal, a storage detection terminal, and a storage terminal, the storage terminal is connected to a data storage line to receive a storage state voltage and the information associated with the storage state voltage; the storage control terminal is connected to a control word-line to receive a control voltage to adjust the impedance characteristic between the storage detection terminal and the storage terminal. The reset switch Qf comprises a reset control terminal, a reset detection terminal, and a reset terminal, the reset control terminal is connected to a control word-line to receive a reset voltage to adjust the impedance characteristic between the reset detection terminal and the reset terminal, and the reset terminal is connected to a reset state voltage line to receive a reset state voltage. The reset detection terminal and a first terminal of the capacitor are connected to the output terminals of at least one storage cell, and a second terminal of the capacitor is connected to the compute word-line. The control module controls the computing array to perform at least one of a store operation, a read operation, and a compute operation. Embodiments of the present disclosure include at least one storage switch, while the storage cells of the related art include at least six transistors, therefore, embodiments of the present disclosure have higher area efficiency. In addition, embodiments of the present disclosure store data through storage state voltages, and a single storage switch can realize multi-bit storage, which further improves area efficiency and significantly reduces the power consumption of data access and compute-in-memory.

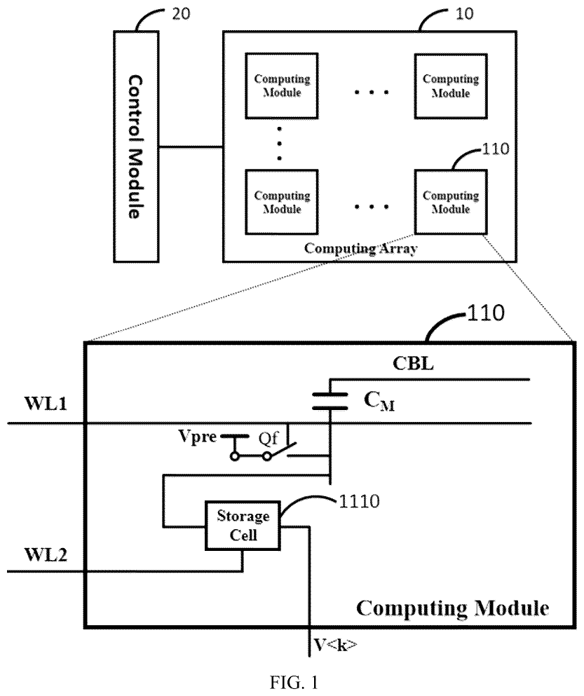

Please refer to FIG. 1, which schematically illustrates a compute-in-memory apparatus according to embodiments of the present disclosure.

As illustrated in FIG. 1, the apparatus comprises:
a computing array 10, which comprises a plurality of computing modules 110. The computing module 110 comprises at least one storage cell 1110, a reset switch Qf and a capacitor CM, the storage cell 1110 comprises at least one storage switch, wherein:
the storage switch comprises a storage control terminal, a storage detection terminal, and a storage terminal, wherein the storage terminal is connected to a data storage line V<k> to receive a storage state voltage to store the information associated with the storage state voltage, the storage control terminal is connected to a control word-line (WL2) to receive a control voltage to adjust the impedance characteristic between the storage detection terminal and the storage terminal;
the reset switch Qf comprises a reset control terminal, a reset detection terminal, and a reset terminal, wherein the reset control terminal is connected to a control word-line (WL1) to receive a reset voltage to adjust the impedance characteristic between the reset detection terminal and the reset terminal;
the reset terminal is connected to a reset state voltage line to receive a reset state voltage Vpre; both the reset detection terminal and a first terminal of the capacitor CM are connected to an output terminal of the storage cell 1110, and a second terminal of the capacitor CM is connected to a computing bit-line CBL;
a control module 20, which is connected to the computing array 10 to control the computing array 10 to perform at least one of a store operation, a read operation and a compute operation.

The above-mentioned k can be any positive integer.

Embodiments of the present disclosure do not limit the specific implementation manner of the storage cell, and a person skilled in the art may select an appropriate implementation manner according to the actual situation and needs. The possible implementation manners of the storage cell are exemplarily introduced below.

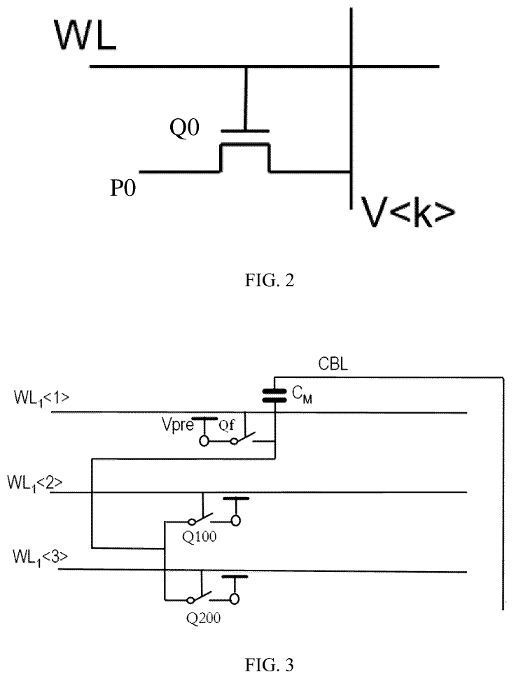

Please refer to FIG. 2, which schematically illustrates a storage cell according to embodiments of the present disclosure.

In an embodiment of the present disclosure, the storage cell may include at least one storage switch, as illustrated in FIG. 2, the storage cell may include a zeroth storage switch Q0. The storage control terminal of the zeroth storage switch Q0 is connected to a control word-line WL (for example, WL2 in FIG. 1), the storage terminal of the zeroth storage switch Q0 is connected to the storage state voltage lien V<k> to receive and store the associated storage state voltage. The storage detection terminal P0 of the zeroth storage switch Q0 is connected to the output terminal of the storage cell. As mentioned above, the storage cells adopted by modern compute-in-memory designs include at least 6 transistors, while embodiments of the present disclosure need to use at least one storage switch, thus far exceeding existing designs in terms of area efficiency. Exemplarily, if only two storage state voltages are used, the area of the storage cell is only 0.07x that of a 6T SRAM. In addition, embodiments of the present disclosure can realize multi-bit storage with a single storage switch through the use of multiple storage state voltages, which further improves area efficiency.

Please refer to FIG. 3, which schematically illustrates a storage cell according to embodiments of the present disclosure.

In an embodiment of the present disclosure, as illustrated in FIG. 3, the storage cell 1110 may comprise a first storage switch Q100 and a second storage switch Q200, wherein the storage detection terminals of both the first storage switch Q1 and the second storage switch Q200 are both connected to the output terminal of the storage cell 1110, the storage control terminals of the first storage switch Q100 and the second storage switch Q200 are connected to a control word-line WL1<2> and a control word-line WL1<3> respectively, and the reset control terminal of the reset switch Qf is connected to a control word-line WL1<1>.

In an embodiment of the present disclosure, the computing module 110 may additionally comprise a selection switch, which comprises a selection control terminal, a first detection terminal and a second detection terminal, wherein,
the selection control terminal is connected to a control bit line to receive a control voltage to adjust the impedance characteristic between the first detection terminal and the second detection terminal;
through installing selection switches, embodiments of the present disclosure can realize the selection of storage cells, to select the corresponding storage cells to perform compute operations based on needs. Through installing selection switches, embodiments of the present disclosure have high flexibility and scalability.

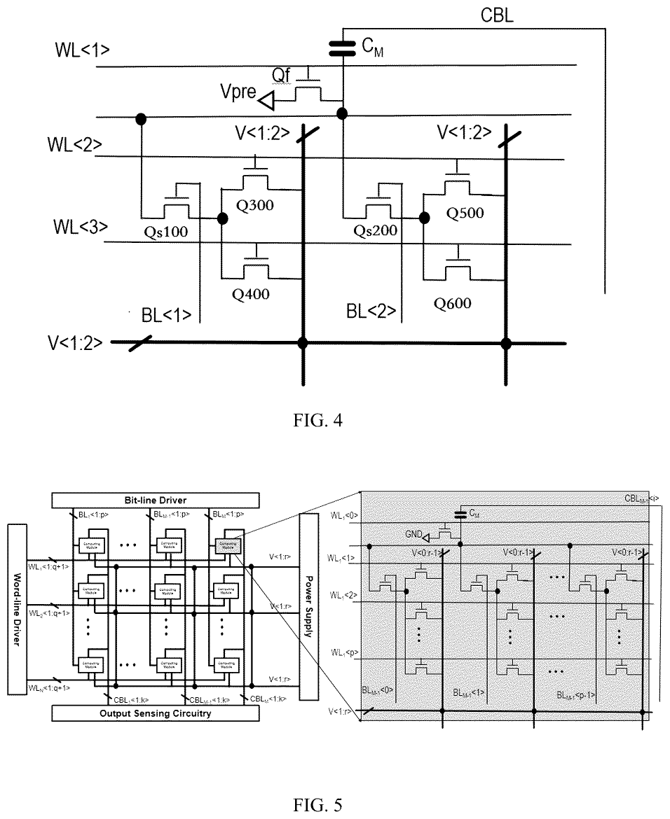

Please refer to FIG. 4, which schematically illustrates a storage cell according to embodiments of the present disclosure.

In an embodiment of the present disclosure, as illustrated in FIG. 4, the storage cell 1110 may comprise a first selection switch Qs100, a second selection switch Qs200, a third storage switch Q300, a fourth storage switch Q400, a fifth storage switch Q500, and a sixth storage switch Q600.
the first detection terminals of the first selection switch Qs100 and the second selection switch Qs200 are connected to the output terminal of the storage cell 1110 (a terminal of the capacitor CM), the second detection terminal of the first selection switch Qs100 is connected to the storage detection terminal of the third storage switch Q300 as well as the storage detection terminal of the fourth storage switch Q400, the selection control terminal of the first selection switch Qs100 is connected to a first control bit line BL<1>, and the selection control terminal of the second selection switch Qs200 is connected to a second control bit line BL<2>,
the storage control terminals of the third storage switch Q300 and the fifth storage switch Q500 are connected to a second control word-line WL<2>, the storage terminals of the third storage switch Q300 and the fourth storage switch Q400 are connected to a first data storage line V<1:2>, the storage control terminals of the fourth storage switch Q400 and the sixth storage switch Q600 are connected to a third control word-line WL<3>, and the storage terminals of the fifth storage switch Q500 and the sixth storage switch Q600 are connected to a second data storage line V<1:2>.

Possible implementations of the storage cell are described above exemplarily, but they shall not be understood as a limitation to embodiments of the present disclosure. The number of storage switches in the storage cell of embodiments of the present disclosure can be arbitrary, and the number of storage cells in a computing module can also be arbitrary.

Please refer to FIG. 5, which schematically illustrates a compute-in-memory apparatus according to embodiments of the present disclosure.

In an embodiment of the present disclosure, as illustrated in FIG. 5, the computing array may comprise a plurality of computing modules. Each computing module may comprise at least one storage cell, each storage cell may comprise at least one storage switch, and each storage switch may include a selection switch Qs, or may not include a selection switch Qs.

In an example, the compute-in-memory apparatus as illustrated in FIG. 5 may be used to implement a fixed-point number neural network accelerator, wherein the weights of the neural network may be stored in the electrical connections between the transistors and the storage state voltages, the feature map may be inputted via the control word-line, and the result of the multiply-and-accumulate operation may be outputted via the output sensing circuitry for subsequent operations.

In an example, as illustrated in FIG. 5, a plurality of computing modules within a computing array are arranged in multiple columns and multiple rows. Within each column of the computing array, the control bit lines and computing bit-lines of some or all of the computing modules are mutually electrically connected. Within each row of the computing array, the control word-lines, data storage lines and reset state voltage lines of some or all of the computing modules are electrically connected.

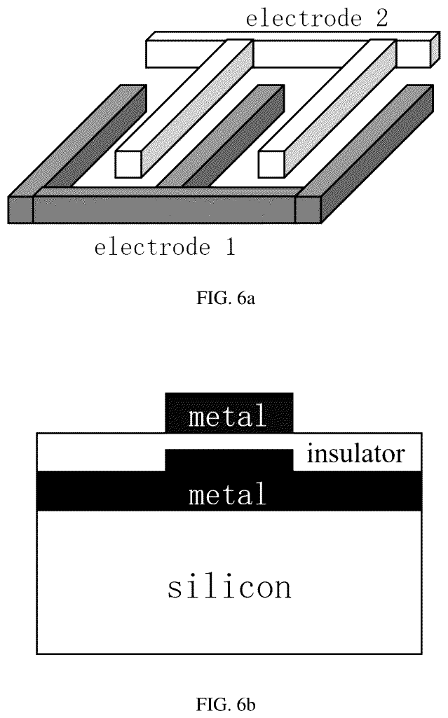

Please refer to FIG. 6a and FIG. 6b, which are schematic illustrations of a MIM capacitor and a MOM capacitor according to embodiments of the present disclosure respectively.

The capacitor CM of embodiments of the present disclosure may be implemented with the metal-insulator-metal capacitor (MIM) as illustrated in FIG. 6a, the metal-oxide-metal capacitor (MOM) as illustrated in FIG. 6b, the gate capacitor of a transistor, or capacitors of other forms, which are not specifically limited herein.

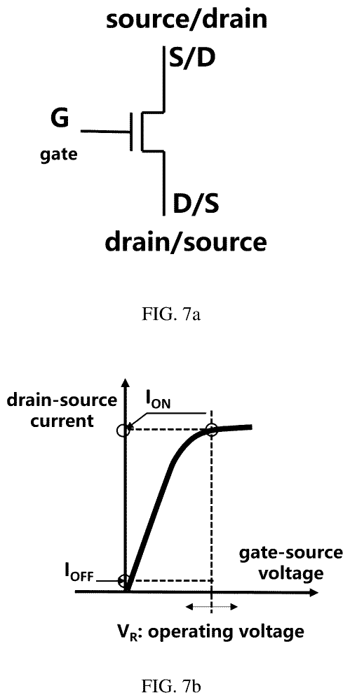

Please refer to FIG. 7a and FIG. 7b. FIG. 7a schematically illustrates a circuit symbol of a metal-oxide-semiconductor field effect transistor according to embodiments of the present disclosure, FIG. 7b schematically illustrates a drain-source current versus gate-source voltage hysteresis characteristic curve of a metal-oxide-semiconductor field effect transistor according to embodiments of the present disclosure.

The storage switches, selection switches, and reset switches of embodiments of the present disclosure may be metal-oxide-semiconductor field effect transistors (MOSFET) (the circuit symbol is shown in FIG. 7a, and the drain-source current versus gate-source voltage hysteresis characteristic curve is shown in FIG. 7b), it shall be noted that in embodiments of the present disclosure, metal-oxide-semiconductor field effect transistors are only exemplary, and theoretically, any device with switching characteristics and high on-off ratio may be used to construct the computing module in embodiments of the present disclosure.

In embodiments of the present disclosure, devices such as metal-oxide-semiconductor field effect transistors may be used as read-only storage devices, and the electrical connections of the devices is used to store information without write operations, and the in-memory computation is performed in the charge domain. Metal-oxide-semiconductor field effect transistor process is currently the most common integrated circuit process, and the process is widely used and highly mature.

In embodiments of the present disclosure, the adoption of the metal-oxide-semiconductor field effect transistors has the advantage of convenient operation. Taking the N-type metal-oxide-semiconductor field effect transistor as an example, a single metal-oxide-semiconductor field effect transistor can change the impedance characteristic between the source and drain of the metal-oxide-semiconductor field effect transistor by controlling the difference between the gate voltage and the source voltage. When the voltage difference is in a certain range, the metal-oxide-semiconductor field effect transistor exhibits a low resistance between the source and drain, and the circuit between the source and drain is turned on. The drains are connected to different storage state voltages, taking only two storage state voltages for example, connecting to a high voltage is equivalent to storing “1”, and connecting to a low voltage is equivalent to storing “0”. In practical applications, connecting to a low voltage may also represent “1” and connecting to a high voltage may also represent “0”. In addition, the drains may be connected to multiple storage state voltages, achieving multi-bit storage with a single transistor. When performing read operations on a single metal-oxide-semiconductor field effect transistor, the gate-source voltage difference is kept within a certain range and the source is pulled down to a low voltage, and the voltage of the data storage line to which the drain is connected can be distinguished through the magnitude of the current between drain and source, thus the stored information is obtained.

Please refer to introductions of the related art for detailed descriptions of the metal-oxide-semiconductor field effect transistor MOSFET, which are not repeated here.

Taking MOSFET as an example for the storage switch, the connection relationships of each device in the computing module as illustrated in FIG. 4 are described exemplarily below.

Refer to FIG. 4 again, as illustrated in FIG. 4, the first selection switch Qs100, the second selection switch Qs200, the third storage switch Q300, the fourth storage switch Q400, the fifth storage switch Q500, the sixth storage switch Q600 and the reset switch Qf can all be MOSFETs, in embodiments of the present disclosure, the impedance characteristic between the drain and source of the first selection switch Qs100, the second selection switch Qs200, the third storage switch Q300, the fourth storage switch Q400, the fifth storage switch Q500, the sixth storage switch Q600 and the reset switch Qf can be controlled through the gate currents and gate voltages thereof.

In an example, as illustrated in FIG. 4, a terminal of the capacitor CM is connected to the drains of the first selection switch Qs100, the second selection switch Qs200, and the reset switch Qf, and the other terminal of the capacitor CM is connected to the computing bit-line CBL; the drains of the third storage switch Q300 and the fourth storage switch Q400 are connected to the source of the first selection switch Qs100, the gates of the third storage switch Q300 and the fifth storage switch Q500 are connected to the control word-line WL<2>, the drains of the fifth storage switch Q500 and the sixth storage switch Q600 are connected to the source of the second selection switch Qs200, the gates of the fourth storage switch Q400 and the sixth storage switch Q600 are connected to the control word-line WL<3>, the sources of the third storage switch Q300, the fourth storage switch Q400, the fifth storage switch Q500 and the sixth storage switch Q600 are connected to a certain data storage line, and information is stored through the connection relationship between the storage devices and the data storage lines; the gate of the first selection switch Qs100 and is connected to the control bit line BL<1>, and the gate of the second selection switch Qs200 is connected to the control bit line BL<2>; the source of the reset switch Qf is connected to the reset state voltage Vpre, and the gate of the reset switch Qf is connected to the control word-line WL<1>.

In an embodiment of the present disclosure, the compute operations include a logic AND operation, and the control module 20 is additionally used to:
activate the reset control terminal of the reset switch Qf of the target computing module 110, thereby a voltage difference is maintained between the two terminals of the capacitor CM of the target computing module 110;
turn off the reset control terminal thereby the computing bit-line CBL is floating;
input a set of operands for the logic operation via the reset control terminal, the control word-lines connected to the storage control terminals of the storage switches, and the data storage lines connected to the storage terminals of the storage switches;
obtain a result of the logic AND operation on the set of operands via the computing bit-lines.

In embodiments of the present disclosure, a voltage difference is maintained between the two terminals of the capacitor of the target computing module by activating the reset control terminal of the reset switch of the target computing module and the computing bit-line, the computing bit-line is floating by turning off the reset control terminal, and a set of operands for the logic operation is inputted via the reset control terminal, the control word-lines connected to the storage control terminals of the storage switches and the data storage lines connected to the storage terminals of the storage switches; thereby a logic AND operation on the set of input operands is performed quickly and efficiently, and the result of the logic AND operation is obtained via the computing bit-lines.

The “activate” used herein can also be referred to as “enable”, for example, the activated terminal is brought to a high voltage, whereby the activated device is enabled.

The computing module illustrated in FIG. 4 is taken as an example below to introduce the logic AND operation. Of course, embodiments of the present disclosure are not limited thereto, and computing modules with storage cells implemented in other manners may also implement the logic AND operation.

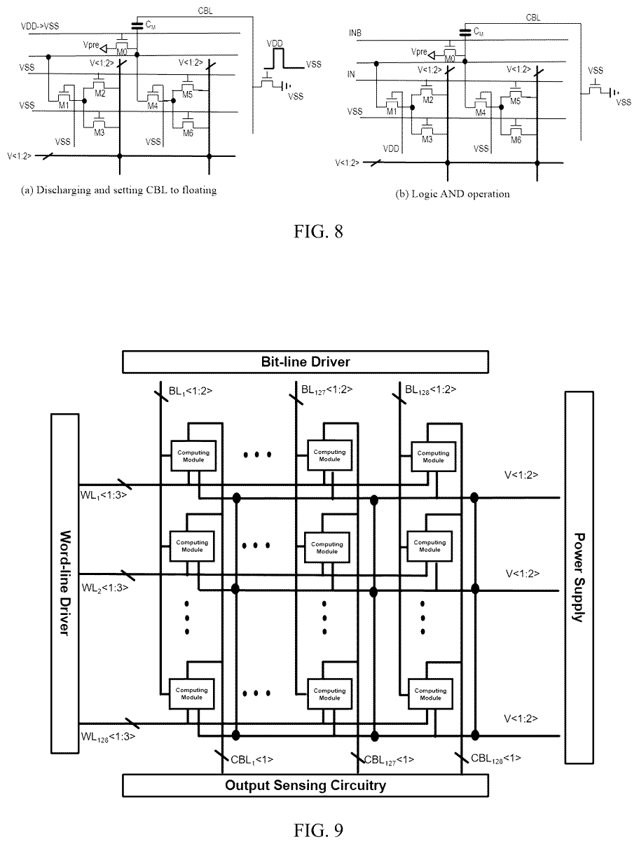

Please refer to FIG. 8, which schematically illustrates a computing module according to embodiments of the present disclosure performing a logic AND operation.

In an example, as illustrated in the left diagram of FIG. 8, the control word-line WL<1> is first set to a high voltage VDD, and the control word-lines WL<2:3> and the control bit lines BL<1:2> are set to a low voltage VSS to clear the charge on the computing bit-line CBL as well as the lower plate of the capacitor CM, and then the control word-line WL<1> is set to the low voltage VSS and thereby the computing bit-line CBL is kept in floating.

Then, as illustrated in the right diagram of FIG. 8, the control word-line WL<3> and the control word-line WL<2> are kept at the low voltage VSS, the control bit line BL<1> is set to VDD to turn on the selection switch Qs100, the control word-line WL<2> is set to different voltages (IN) according to different input values, and the voltage of the control word-line WL<1> is set to be complimentary to that of the control word-line WL<2>, thereby realizing a logic AND operation on the input value to the control word-line WL<2> and the weight value represented by the storage state voltage connected to the third storage switch Q300.

The computing module based on the read-only storage devices for compute-in-memory in the charge domain according to embodiments of the present disclosure has the advantages of high area efficiency and low power consumption, and can effectively mitigate the leakage problem in the idle state, and is therefore a class of compute-in-memory circuit that can greatly improve area efficiency and reduce energy consumption.

In an embodiment of the present disclosure, the compute operations include a multiply-and-accumulate operation, and the control module 20 is additionally used to:
activate the storage control terminal of the storage switch of the storage cell 1110 of the target computing module 110, whereby a logic AND operation is performed on the information carried by the word-line connected to the storage control terminal of the activated storage switch and the information associated with the storage state voltage of the storage terminal of the activated storage switch;
obtain the result of the multiply-and-accumulate operation via the computing bit-line.

In embodiments of the present disclosure, by activating the storage control terminal of the storage switch of the storage cell 1110 of the target computing module 110, a logic AND operation is performed on the information carried by the word-line connected to the storage control terminal of the activated storage switch and the information associated with the storage state voltage of the storage terminal of the activated storage switch, and the result of the multiply-and-accumulate operation is obtained via the computing bit-line. It can be seen that for the computing module that does not include a selection switch, the multiply-and-accumulate operation can be realized quickly and efficiently.

In an embodiment of the present disclosure, the compute operations include a multiply-and-accumulate operation, and the control module 20 is additionally used to: activate the storage control terminal of the storage switch of the storage cell 1110 of
the target computing module 110 as well as the selection control terminal of the selection switch connected to the storage switch, whereby a logic AND operation is performed on the information carried by the control word-line connected to the storage control terminal of the activated storage switch and the information associated with the storage state voltage of the storage terminal of the activated storage switch;
obtain the result of the multiply-and-accumulate operation via the computing bit-line.

In embodiments of the present disclosure, by activating the storage control terminal of the storage switch of the storage cell 1110 of the target computing module 110 and the selection control terminal of the selection switch connected to the storage switch, a logic AND operation is performed on the information carried by the control word-line connected to the storage control terminal of the activated storage switch and the information associated with the storage state voltage of the storage terminal of the activated storage switch, and the result of the multiply-and-accumulate operation is obtained via the computing bit-line. It can be seen that for the computing module that includes a selection switch, the multiply-and-accumulate operation can also be realized quickly and efficiently.

The multiply-and-accumulate operation based on the computing array is introduced below.

Please refer to FIG. 9, which schematically illustrates a compute-in-memory apparatus according to embodiments of the present disclosure.

In an embodiment of the present disclosure, as illustrated in FIG. 9, the computing array that comprises a plurality of computing modules includes at least one computing module with the circuit structure as described above, and some or all of the elements of the array circuit are combined into a multi-row and multi-column layout via electrical connections. The rule of the electrical connections is: within the same column, the control bit lines of some or all of the computing modules are electrically connected, and the computing bit-lines of some or all of the computing modules are electrically connected; within the same row, the control word-lines of some or all of the computing modules are electrically connected, the data storage lines of some or all of the computing modules are electrically connected, and the reset state voltage lines of some or all of the computing modules are electrically connected.

It can be understood that the energy consumption of the computing array of the compute-in-memory apparatus of embodiments of the present disclosure mainly lies in charging the capacitors. Since the equivalent capacitance of embodiments of the present disclosure does not increase linearly with the increase of the ratio of “1”'s in the result of the logic AND operation, when the number of cells whose result of the logic AND operation are “1” exceeds a certain value, embodiments of the present disclosure can greatly reduce the energy consumption of computation.

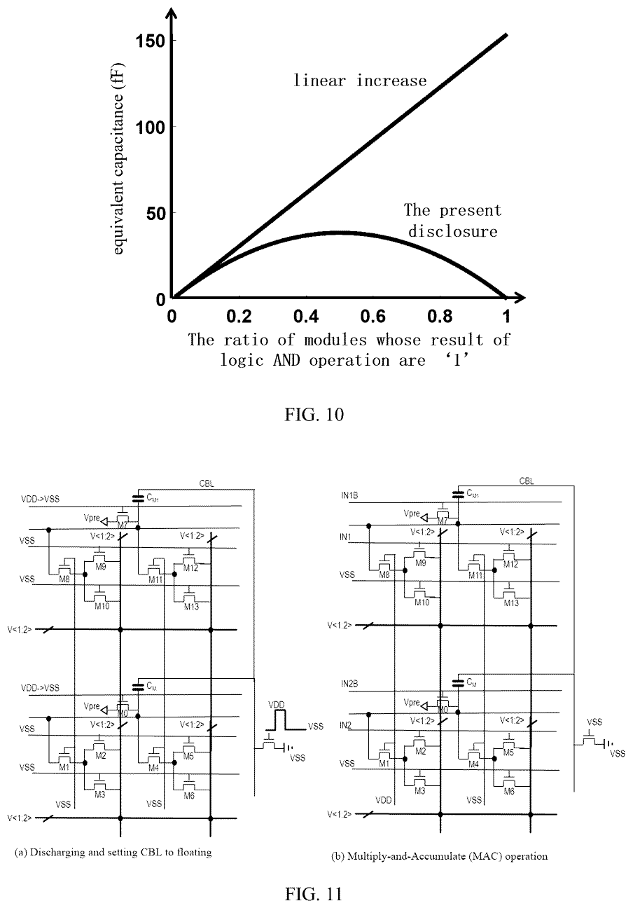

Please refer to FIG. 10, which schematically illustrates the equivalent capacitance of the circuit shown in FIG. 9 which requires charging when performing the multiply-and-accumulate operation.

As illustrated in FIG. 10, embodiments of the present disclosure can greatly reduce the energy consumption of computation. In FIG. 10, the unit capacitance is 1.2 fF, and the array size is 128×128. In addition, when in the idle state, the compute-in-memory circuit of embodiments of the present disclosure has almost no leakage current, which significantly alleviates the leakage problem of SRAM storage cells in the idle state.

In an embodiment of the present disclosure, when performing a multiply-and-accumulate operation with the computing array circuit, one or more computing bit-lines, and/or computing modules connected to the same computing bit-line may be controlled simultaneously to perform logic AND operations, and the result of the multiply-and-accumulate operation is obtained by evaluating the effect of the process on the electrical characteristics of the computing bit-lines.

Please refer to FIG. 11, which schematically illustrates the computing array according to embodiments of the present disclosure performing a multiply-and-accumulate operation.

First, as illustrated in the left diagram (a) of FIG. 11, in embodiments of the present disclosure, first, the control word-line WL<1> is set to a high voltage VDD, and the control word-lines WL<2:3> and the control bit lines BL<1:2> are set to a low voltage VSS to clear the charge om the computing bit-line CBL and the capacitor CM, and then the control word-line WL<1> is set to the low voltage VSS to keep the computing bit-line CBL in floating.

Then, as illustrated in the right diagram (b) of FIG. 11, the control word-line WL<3> and the control bit line BL<2> are kept at the low voltage VSS, the control bit line BL<1> is set to VDD to on the storage switches M1 and M8, the control word-line WL<2> is set to different voltages according to different input values, and the voltage of the control word-line WL<1> is set to be complimentary to that of the control word-line WL<2>, thereby implementing a logic AND operation on the input value of the control word-line WL<2> and the weight values represented by the storage state voltages connected to the storage switches M2 and M9. Then a normalized multiply-and-accumulate operation is performed on the circuit connected to the entire computing bit-line CBL. Exemplarily, if the voltage of V<2> is VDD and the voltage of V<1> is VSS, the CBL will obtain a voltage between VDD and VSS.

In an embodiment of the present disclosure, the control module 20 is additionally used to:
control each control word-line, control bit line, computing bit-line, data storage line, and reset state voltage line to be grounded whereby the computing array 10 enters an idle mode.

In an example, the compute-in-memory apparatus of embodiments of the present disclosure supports an operating mode and an idle mode, wherein in the operating mode the write operation and compute operations (such as the logic AND operation and the multiply-and-accumulate operation, as described above) are performed, while in the idle mode, by controlling the voltages of the word-lines and the bit lines, the information stored by the circuit cells are nonvolatile.

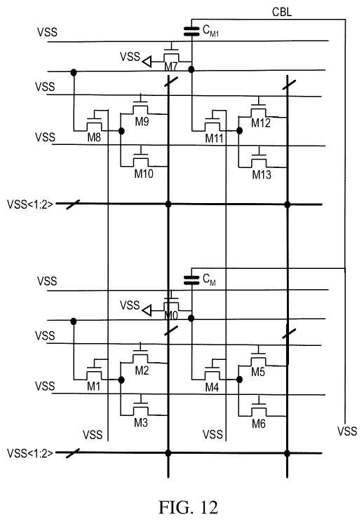

Please refer to FIG. 12, which schematically illustrates the idle mode of the compute-in-memory apparatus according to embodiments of the present disclosure.

In an example as illustrated in FIG. 12, in embodiments of the present disclosure, by connecting all the word-lines and all the bit lines to ground (VSS), the compute-in-memory apparatus is controlled to enter an idle mode, thereby reducing the energy consumption of the array. In addition, the information stored by the storage cells is nonvolatile and therefore embodiments of the present disclosure are free from the information loss problem.

In an example, in the operating mode, the voltages of each word-line and bit line can be configured for compute operations such as the multiply-and-accumulate operation and the logic AND operation, as described above.

In an embodiment of the present disclosure, the control module 20 is used additionally to:
Control the computing module 110 connected to different computing bit-lines to perform a pipelined operation.

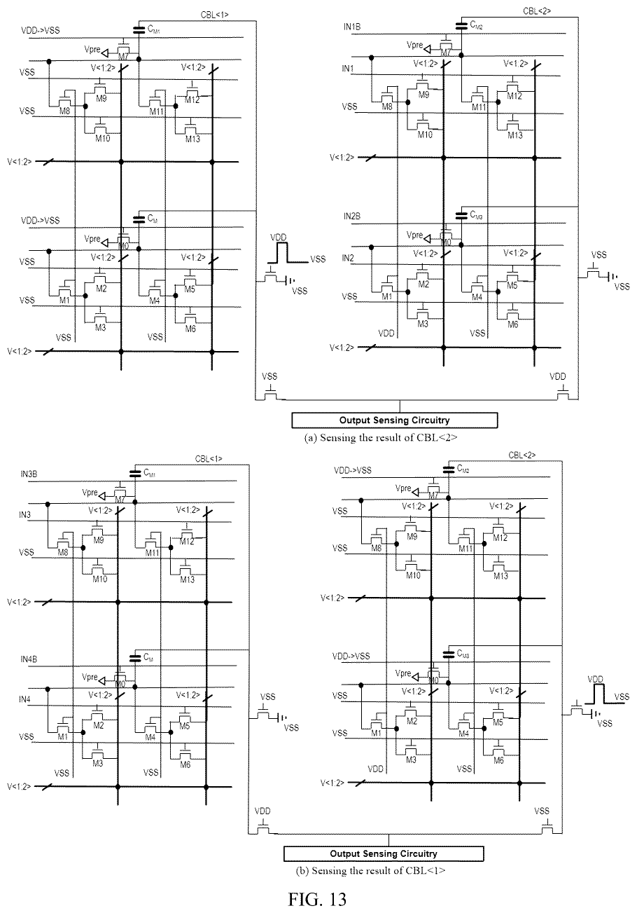

Please refer to FIG. 13, which schematically illustrates an implementation of the pipelined operation using the computing array according to the embodiments of the present disclosure.

In an example, using the compute-in-memory apparatus as illustrated in FIG. 5, together with other circuits (such as inserting one or more MOSFET transistors between the computing modules), when performing the multiply-and-accumulate operation with the array circuit, a pipelined operation between the computing parts and output sensing parts of the computing modules connected to different computing bit-lines can be implemented by adjusting the timing of the control word-lines and the control bit lines.

Exemplarily, the pipelined operation may refer to passing the compute result of the former computing module to the current computing module via the computing bit-line CBL, and input it to the compute operation of the current computing module, and then pass the compute result of the current computing module to the next computing module via the computing bit-line CBL.

Of course, the embodiments of the present disclosure do not limit the specific timing of signals of the control word-lines and the control bit lines during the pipelined operation, and a person skilled in the art can set them according to actual conditions and needs.

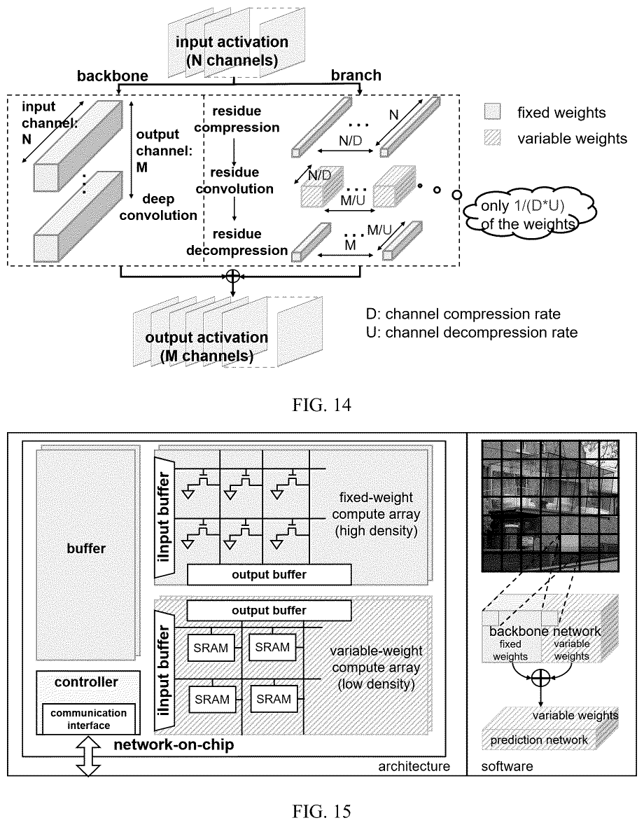

Please refer to FIG. 14, which schematically illustrates the neural network accelerator according to the embodiments of the present disclosure.

As illustrated in FIG. 14, the neural network accelerator comprises at least one neural network module, wherein the neural network module comprises at least one original convolutional layer, wherein the original convolutional layer comprises a backbone layer which has a fixed weight and a branch layer which has an adjustable weight. The backbone layer comprises one or more convolutional layers, the branch layer at least comprises a first branch convolutional layer (residual compression layer), a second branch convolutional layer (residual convolutional layer) and a third branch convolutional layer (residual decompression layer), which are sequentially connected, the input channel number of the first branch convolutional layer (N) is equal to the input channel number of the backbone layer (N), the output channel number of the third branch convolutional layer (M) is equal to the output channel number of the backbone layer (M), the input channel number of the second branch convolution layer (N/D) is smaller than the input channel number of the backbone layer, the output channel number of the second branch convolution layer (M/U) is smaller than the output channel number of the backbone layer.

The backbone layer and the convolutional layers in the branch layer are implemented using the compute-in-memory apparatus.

The symbols N, M, D, and U represent integers.

In an example as illustrated in FIG. 14, the neural network accelerator is configured in the form of a residual branch, which overcomes the problem that the weights of the neural network on a fabricated chip cannot be modified.

In an example as illustrated in FIG. 14, the residual branch method transforms at least one layer of the neural network into a backbone and a branch which are parallelly computed, wherein the backbone layer comprises one or more convolutional layers whose weights are fixed, and the branch layer comprises at least one residual compression layer with fixed weights, at least one residual decompression layer with fixed weights, and at least one residual convolutional layer with modifiable weights. The residual compression layer is used to transform the input channel number of the input activation to reduce the input channel number of the residual convolutional layer; the residual decompression layer is used to transform the output channel number of the output activation to reduce the output channel number of the residual convolutional layer; and the residual convolutional layer is used to perform a convolution operation.

In embodiments of the present disclosure, using the neural network accelerator, deep neural networks can be transformed into models suitable for fixed-weight neural network accelerators, with the backbone layer that has a huge number of parameters deployed in the high-density fixed-weight accelerator, and the branch layer with only a small amount of parameters deployed in the low-density but flexible-weight accelerator; thereby, when the task has changed, only the branch layer needs to be retrained, and the backbone layer stays unchanged.

Exemplarily, the branch convolutional layer may be 16 times smaller than the backbone layer. It can be seen that the embodiments of the present disclosure can significantly reduce the size of neural network accelerators.

The neural network accelerator according to embodiments of the present disclosure may be based on fixed-point numbers. In convolutional neural networks, the multiply-and-accumulate operation is the key operation and main source of energy consumption of the inference process. According to reports from existing research, neural networks with multi-bit weights and inputs can decompose multiplication operations into logic AND operations and addition operations. Fixed-point number neural networks have been shown to be successful on many datasets and have achieved very low energy consumption and marginal accuracy loss compared to float-point number neural networks.

Because of the advantages of high area efficiency and low energy consumption of the above-described compute-in-memory apparatus and the applicability thereof to various applications such as neural network acceleration, through the use of the compute-in-memory apparatus or the computing array or the storage cell as described above to implement the neural network accelerator, the embodiments of the present disclosure can to some extent solve the technical problems related to high-area efficiency compute-in-memory design and low-power compute-in-memory design.

In an embodiment of the present disclosure, the backbone layer and the first branch convolutional layer are used to receive an input to the neural network, and the output of the neural network module is obtained by aggregating the outputs of the backbone layer and the third branch convolutional layer.

In an example, the fixed-weight read-only memory computing array of embodiments of the present disclosure may be fine-tuned after fabrication; thereby, the neural network accelerator can adapt to the change of recognition targets after hardware deployment.

Please refer to FIG. 15, which schematically illustrates a neural network accelerator system comprising the neural network accelerator.

Exemplarily, as illustrated in FIG. 15, the neural network accelerator system comprises an on-chip architecture and a software part. The on-chip architecture comprises a cache, a controller, a high-density fixed-weight computing array and a low-density variable-weight computing array; the software part comprises a backbone network and a prediction network, wherein the backbone network contains fixed weights and variable weights, and the prediction network contains only variable weights.

In an example, in embodiments of the present disclosure, all parameters of a large-scale network may be stored on the chip, the cache is used to temporarily store the intermediate values of the computation, and the controller is used to schedule the data flow and to execute non-neural network computations. With this method, only a small fraction of weights are deployed in the low-density variable-weight computing array, and most (more than percent, for example) of the parameters may be stored in the high-density fixed-weight computing array. Meanwhile, this method is able to fine-tune the network weights even after chip deployment, thus realizing the transfer of tasks.

The compute-in-memory apparatus of embodiments of the present disclosure has the advantages of high area efficiency and low energy consumption, and can effectively mitigate the leakage current problem faced with SRAM storage cells in the idle state, and is a class of compute-in-memory circuit that can greatly improve area efficiency and reduce energy consumption.

According to an aspect of the present disclosure, an electronic device is provided. The electronic device includes the compute-in-memory apparatus or the neural network accelerator.

The electronic device may be provided in the form of a terminal, a server, or a device of other forms.

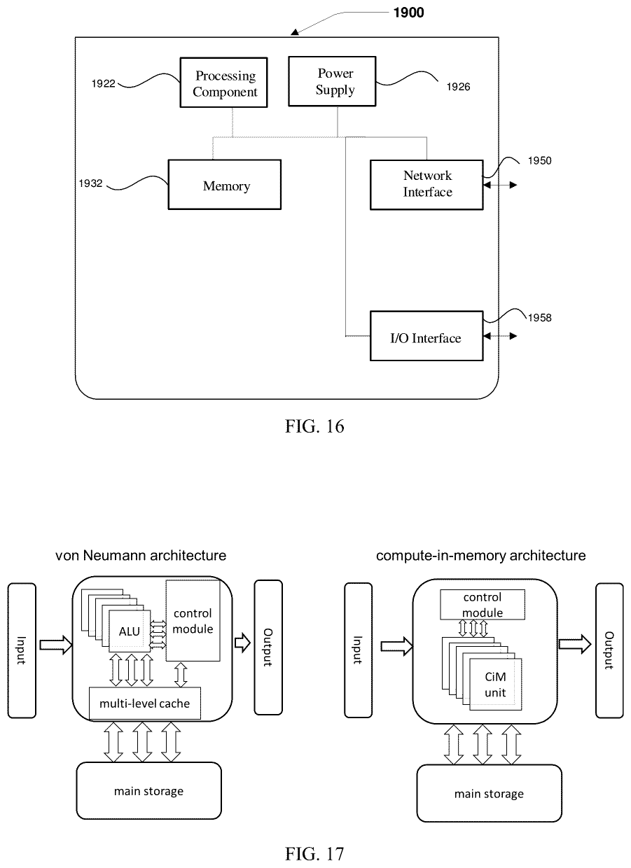

Please refer to FIG. 16, which shows an electronic device according to embodiments of the present disclosure.

For example, the electronic device 1900 may be provided as a server. Referring to FIG. 16, the electronic device 1900 comprises a processing component 1922 which further comprises one or more processors, and memory resources represented by the memory 1932, which is used to store instructions such as application programs that can be executed by the processing component 1922. The application programs that are stored in the memory 1932 may comprise one or more modules that each correspond to a set of instructions. In addition, the processing component 1922 is configured to execute the instructions to realize the method described above.

The electronic device 1900 may additionally comprise a power supply component 1926 which is configured to perform the power management of the electronic device 1900, a wired or wireless network interface 1950 which is configured to connect the electronic device 1900 to a network, and an input-output (I/O) interface 1958. The electronic device 1900 may operate based on the operating system stored in the memory 1932, such as Microsoft server operating system (Windows Server™), the graphical user interface-based operating system (Mac OS X™) introduced by Apple company, a multi-user and multi-process computer operating system (Unix™), a free and open-source Unix-like operating system (Linux™), an open-source Unix-like operating system (FreeBSD™) or alike.

In the exemplary embodiment of the present disclosure, a non-transitory computer-readable storage medium is provided, such as the memory 1932 which stores computer program instructions, and the computer program instructions may be executed by the processing component 1922 of the electronic device 1900 to accomplish the above method.

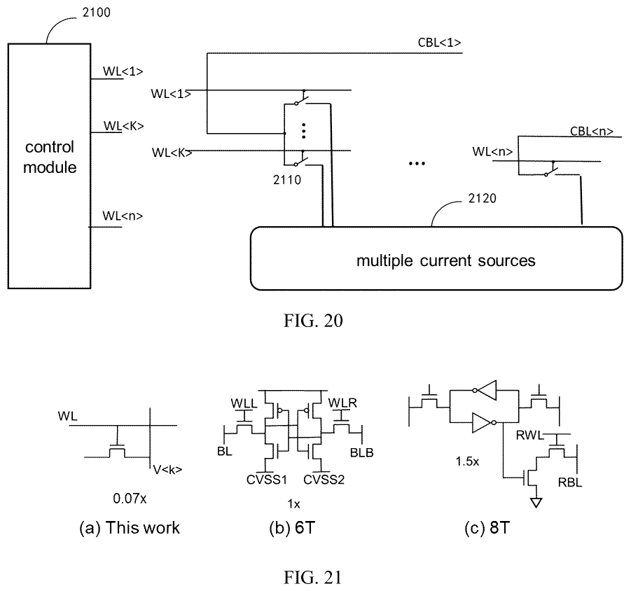

Please refer to FIG. 20, which shows a schematic diagram of a compute-in-memory device according to the present disclosure.

As shown in FIG. 20, the compute-in-memory device includes multiple read-only memory devices 2110, multiple current sources 2120, and a control module 2100. Each storage terminal of each read-only memory device 2110 is connected to one terminal of a corresponding current source 2120, and the other terminal of the current source 2120 is used to receive a preset voltage to achieve data storage.

The control terminal of each read-only memory device 2110 is connected to a corresponding control wordline WL<n> for receiving data to be computed. The output terminal of each read-only memory device 2110 is used to output result data through a computation bitline CBL<n>.

The control module 2100 selects the corresponding read-only memory device 2110 for operation through the control word line WL<n>, so as to output the result data. The operations include multiplication and data reading operations. For a multiplication operation, the result data is the product of the stored data corresponding to the preset voltage received by the current source 2120 and the data to be computed input through the control wordline WL<n>. For a data reading operation, the result data is the stored data corresponding to the preset voltage received by the current source 2120.

The present disclosure does not limit the specific implementation of the control module. For example, the control module may include a processing component, such as a stand-alone processor or a combination of discrete components. The processor can include a controller that executes instructions in any appropriate manner, such as by one or more application-specific integrated circuits (ASICs), digital signal processors (DSPs), digital signal processing devices (DSPDs), programmable logic devices (PLDs), field-programmable gate arrays (FPGAs), controllers, microcontrollers, microprocessors, or other electronic components. Within the processor, hardware circuits such as logic gates, switches, ASICs, programmable logic controllers, and embedded microcontrollers can execute the executable instructions.

Read-only memory (ROM) is a type of storage device with high storage density, non-volatility, and low read power consumption. The present disclosure implements compute-in-memory based on read-only memory, making it possible to fully store large-scale neural network parameters on-chip, thereby eliminating the additional power consumption caused by repeated transfer of weights between on-chip and off-chip, greatly reducing the energy consumption of on-chip inference operations, and allowing deep learning algorithms to be deployed massively and efficiently on intelligent terminal devices.

The present disclosure utilizes read-only memory to implement a storage-based computing device, fully utilizing the high-density characteristics of read-only memory to improve the area efficiency of storage-based computing, and hence reduce or even eliminate unnecessary energy consumption caused by memory access.

The present implementation does not limit the number of read-only memory devices and current sources in the compute-in-memory device, nor does it limit the specific current source connected to the storage terminal of the read-only memory. The size of the preset voltage received by the current source is also not limited. The read-only memory devices in the compute-in-memory device can be separately set up, that is, one or more read-only memory devices in the compute-in-memory device output calculation results through separate calculation bitlines and are controlled by separate control wordlines. Alternatively, the read-only memory devices in the compute-in-memory device can be jointly set up, that is, two or more read-only memory devices in the compute-in-memory device can output calculation results through a single calculation bitline and can be controlled by the same control wordline. The present implementation does not limit the setting method of the read-only memory devices in the compute-in-memory device, and those skilled in the art can set them according to actual application situations and needs.

For example, the compute-in-memory device may include multiple calculation modules, each of which includes at least one read-only memory device. The calculation module can be viewed as the basic unit for data storage and calculation in the compute-in-memory device. The minimum size of the calculation module in the present implementation is that of one read-only memory device. Compared with the solution of using multiple transistors to implement the calculation module in the related art, the present implementation can significantly improve area efficiency and storage density.

Please refer to FIG. 21(a)-21(c), which shows a schematic diagram comparing the area of the computation modules in the disclosed example and related technologies. In one example, as shown in FIG. 21(a), the computation module of the disclosed implementation is as small as the size of a read-only memory device. Accordingly, the minimum normalized area of the computation module in the disclosed implementation is 0.07x, where x can be regarded as the unit area (such as the normalized area of the 6T structure). As shown in FIG. 21(b), the computation module in the related technology is a 6T structure (including six transistors), with a normalized area of 1x. As shown in FIG. 21(c), the computation module in the related technology is an 8T structure (including eight transistors), and the normalized area of the 8T structure computation module is 1.5x.

As described above, the mainstream CMOS storage computing circuit design currently uses SRAM as the storage unit, which consists of at least six transistors. However, by using the characteristics of the read-only memory device, the disclosed implementation only uses one transistor to complete the information storage of one computation module, thereby improving the area efficiency. If each computation module in the disclosed implementation stores 1 bit of information, the area of the computation module is only 0.07 times that of the 6T SRAM under the same process. Moreover, the disclosed implementation also has the potential to use one transistor to achieve multi-bit data storage, which further improves the storage density.

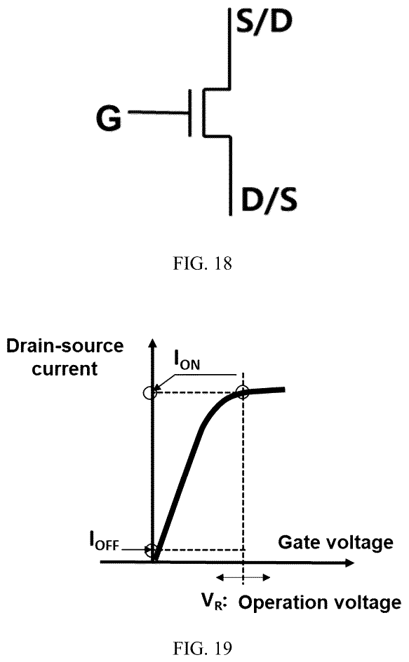

The read-only memory device in the disclosed implementation can be a metal-oxide-semiconductor field-effect transistor (MOSFET) or a switching device with similar high-pass cutoff characteristics. The gate of the read-only memory device is connected to the control terminal, and the drain and source are respectively connected to the storage terminal and the output terminal, or the drain and source are respectively connected to the output terminal and the storage terminal, as shown in FIG. 18. The MOSFET is a three-terminal device, which controls the impedance characteristic between the drain and source by the gate voltage and has high-pass cutoff characteristics as shown in FIG. 19.

It should be noted that in the disclosed implementation, the MOSFET is only an example, and all devices with switching characteristics can theoretically be used to build the compute-in-memory device proposed in the disclosed implementation.

In one possible implementation, the compute-in-memory device may include multiple computation modules, each of which includes a read-only memory device. The output end of the read-only memory device is directly connected to the corresponding computation bitline to output the result data through the computation bitline.

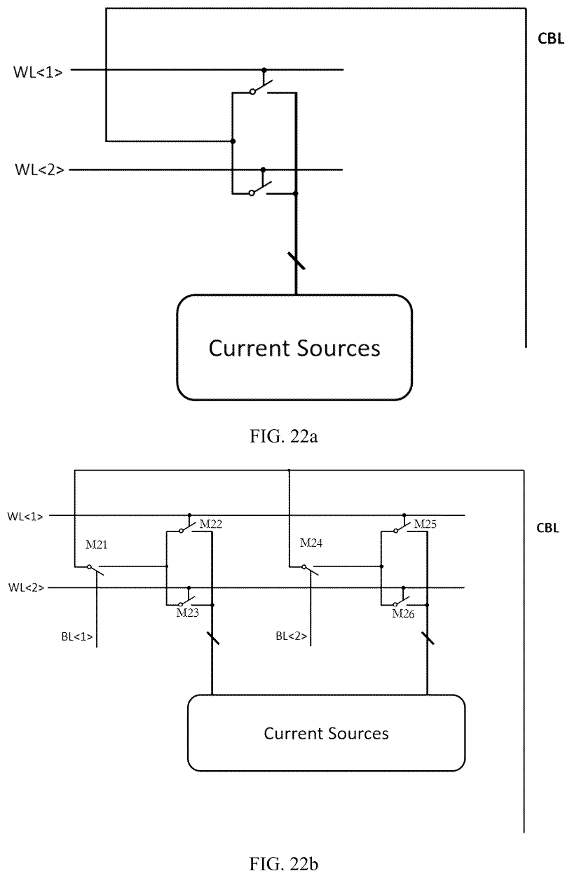

Please refer to FIGS. 22 (a) and 22 (b), which illustrate a schematic diagram of a calculation module according to an implementation of the present disclosure. For example, as shown in FIG. 22 (a), each calculation module may include two or more read-only memory devices, where the output terminals of each read-only memory device can be connected to the same calculation bitline (CBL), and the control terminals of each read-only memory device can be connected to the corresponding control wordline (WL<x>). Of course, in the calculation device, each calculation module may include a different number of read-only memory devices, and the present disclosure does not limit this.

In a possible implementation, as shown in FIG. 22 (b), the on-chip calculation device may include multiple calculation modules, with each module including two or more read-only memory devices and at least one selector device. The control terminals of the selector devices are connected to the corresponding control bitlines, while the input terminals of the selector devices are connected to the output terminals of the read-only memory devices, and the output terminals of the selector devices are connected to the corresponding calculation bitlines for outputting the resulting data. The read-only memory devices (M21-M26) in the calculation module can adjust the impedance characteristics between the drain and source electrodes via control gate voltage. For example, the drain electrode of read-only memory device M22 and the source electrode of selector device M21 are connected, and the gate electrode of read-only memory device M22 and M23 is connected to the control wordline WL<1>. The drain electrode of read-only memory device M25 and the source electrode of selector device M24 are connected, and the gate electrode of read-only memory device M25 and M26 is connected to the control wordline WL<2>. The source electrodes of read-only memory devices M22, M23, M25, and M26 are connected to a certain working current source, and information is stored through the read-only memory devices and the connection relationship with the specific working current source. The gate electrodes of selector devices M21 and M24 are connected to control bitlines BL<1> and BL<2>, respectively.

Of course, the selector devices can also be metal-semiconductor-oxide field-effect transistors or switch devices with similar high-pass characteristics, where the gate electrodes of the selector devices are connected to the control terminals, and the drain and source electrodes are respectively connected to the storage and output terminals, or the drain and source electrodes are respectively connected to the output and storage terminals.

For example, as shown in FIG. 22 (b), the calculation module may comprise read-only memory devices M22, M23, M25, and M26, selector devices M21 and M24, and a current source module. The current sources can be set in the current source module, and each current source can be connected to one or more read-only memory devices. By establishing a multi-to-multi connection relationship between the current source and the read-only memory, the present disclosure can further reduce the occupied area of the unit circuit and fully exploit the high-density characteristics of the read-only memory devices to improve overall area efficiency.

The control wordlines WL<1:2>, control bitlines BL<1:2>, and calculation bitline CBL can also serve as interfaces for the calculation module and be considered part of the calculation module, but this is not limiting according to the present disclosure.

In a possible implementation, the read-only memory devices in the calculation module can be arranged in a layout of multiple rows and columns. The control terminal of each row of read-only memory devices is connected to the same control wordline, and the output terminal of each column of read-only memory devices is connected to the same selector device. The output terminal of each selector device is connected to the same calculation bitline. For example, the gate electrodes of read-only memory devices M22 and M25 in the same row are connected to the control wordline WL<1>, and the gate electrodes of read-only memory devices M23 and M26 in the same row are connected to the control wordline WL<2>. The gate electrode of selector device M21 is connected to the control bitline BL<1>, and the gate electrode of selector device M24 is connected to the control bitline BL<2>. The drain electrode of read-only memory devices M22 and M23 in the same column is connected to the source electrode of selector device M21, and the drain electrode of read-only memory devices M25 and M26 in the same column is connected to the source electrode of selector device M24.

The present disclosure can control each storage module to perform multiplication operations (and logic operations), and an exemplary introduction of the structure of the calculation module shown in FIG. 22 (b) has been provided above.

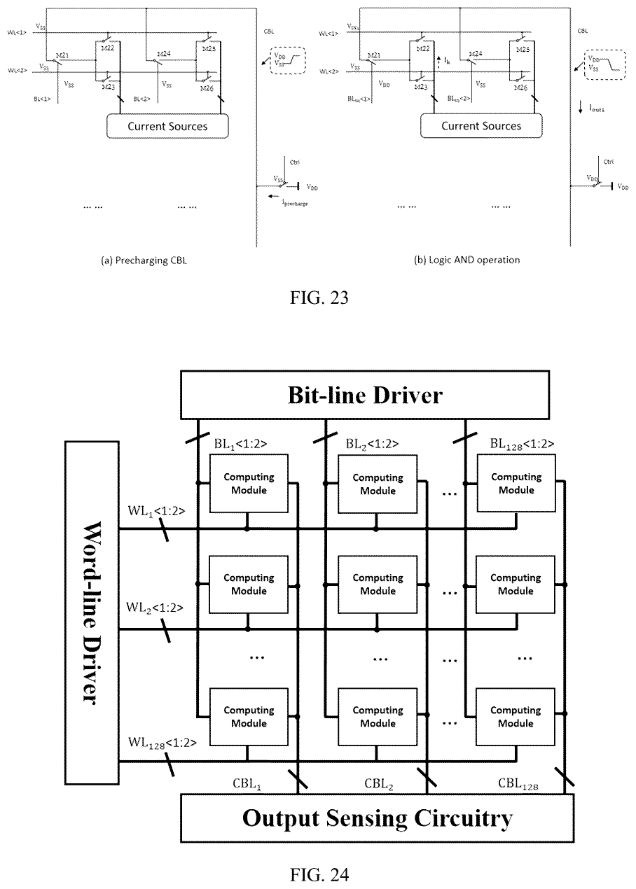

Please refer to FIGS. 23, which illustrates schematic diagrams of performing multiplication operations using the computing module of the compute-in-memory device in this implementation.

In one example, as shown in (a) of FIG. 23, all control bitlines BL<1:2> and control wordlines WL<1:2> can be set to VSS to put the computing module into idle mode. The storage terminals of the read-only memory device are disconnected from the computing wordlines, and there is no current flowing inside the unit circuit.

In another example, as shown in (b) of FIG. 23, the control wordlines WL<1> and WL<2> are set to V_{IN1} and VSS, respectively, while the control bitline BL<2> remains at VSS and the control bitline BL<1> is set to VDD. This configuration achieves the multiplication operation between the input data VIN1 on WL<1> and the weight value stored in the read-only memory device M22. The resulting current is converged onto the computation bitline CBL to complete the multiplication operation, and external circuits can obtain the multiplication result by reading the current on the computation bitline CBL.

Please refer to FIG. 24, which shows a schematic diagram of the structure of the compute-in-memory device according to this implementation.

In one possible implementation, as shown in FIG. 24, multiple computing modules are combined into several rows and columns through electrical connections. The control wordlines of the computing modules in the same row are electrically connected, the control bitlines of the computing modules in the same column are electrically connected, and the computation bitlines of the computing modules in the same column are electrically connected. The computation bitlines are connected to the selector device and power voltage. The control wordlines and bitlines are driven by the wordline driver and bitline driver, respectively. All computing modules are connected to the power supply, and the computation bitlines of all computing modules output results through the output detection interface.

The wordline driver and bitline driver may be located in the control module as an example.

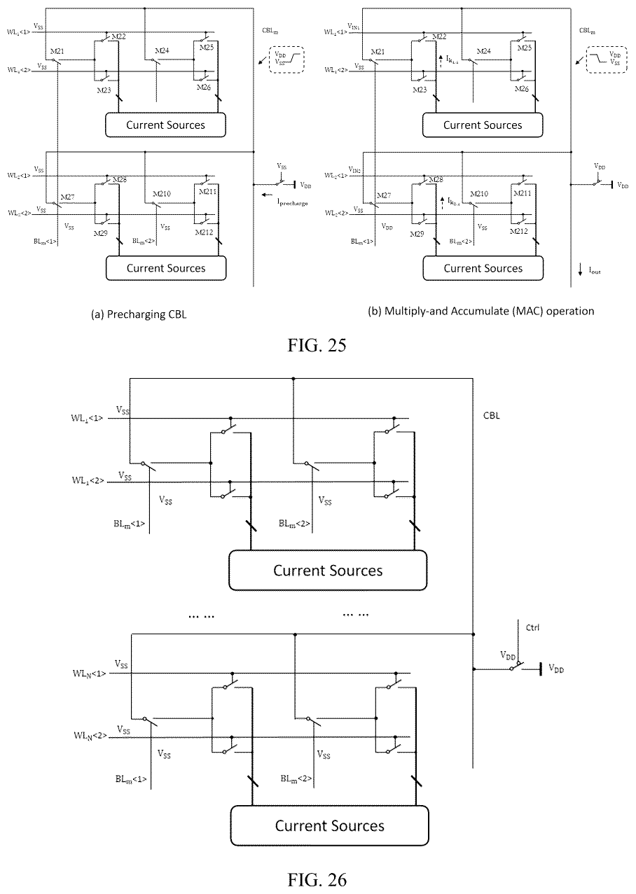

Please refer to FIG. 25, which illustrates schematic diagrams of a CiM device that performs multiply-accumulate operations according to the disclosed implementations. In one possible implementation, the operations also include multiply-accumulate operations, and the resulting data includes the multiply-accumulate result. The control module can be used to:

Input a set of data through control wordlines and activate the control terminals of the corresponding selector components through control bitlines to select the calculation modules participating in the multiply-accumulate operation.

Use the control wordlines to select the read-only memory components involved in the multiplication operation in each calculation module and complete the multiplication operation between the input data and the stored data corresponding to the preset voltage received by the current source.

Accumulate the multiplication results obtained from each calculation module and output them in the form of current through the calculation bit line to obtain the multiply-accumulate result.

For example, when performing a multiply-accumulate operation, all relevant control wordlines and control bitlines of the calculation module can be set to the lowest voltage level. One or more rows of selector components for the calculation bitline are opened. A set of data is input through the control wordlines, and if the output terminal of the read-only memory connected to the activated control wordline is connected to the input terminal of the selector component, the control terminal of the corresponding selector component is activated through the control bitline to select the read-only memory components participating in the calculation in each unit circuit. The multiplication operation is performed within the unit circuit, the results obtained are accumulated in the form of current through the calculation bitline, and the multiply-accumulate operation result is distinguished by detecting changes in the electrical characteristics of the calculation bitline.

In one example, as shown in (a) of FIG. 25 all control bitlines (such as BLₘ<1:2>) and control wordlines (WL₁<1:2>, WL₂<1:2>) are set to the low voltage level VSS, placing the calculation module connected to the calculation bitline CBLₘ in idle mode. The storage terminals of each read-only memory component are disconnected from the control wordlines, and there is no current flow within the unit circuit.

In another example, as shown in (b) of FIG. 25, the selector component between the calculation bitline CBLₘ and the power supply is turned on (by applying a high voltage level VDD to the selector component). Control wordlines WL₁<1> and WL₁<2> are set to V_{IN1} and VSS, respectively; control bitline BLₘ<2> is set to VSS, control bitline BLₘ<1> is set to VDD, and control wordlines WL₂<1> and WL₂<2> are set to V_{IN2} and VSS, respectively. This performs the multiplication operation between the input data on control wordline WL₁<1> and the weight value stored in read-only memory component M22 and the multiplication operation between the input data on control wordline WL₂<1> and the weight value stored in read-only memory component M8. The results obtained are aggregated in the form of current to the calculation bit line CBLₘ, added according to Kirchhoff s current law, the multiply-accumulate operation is completed, and the calculation bit line CBLₘ outputs the result in the form of current for external circuit reading.

In one possible implementation, the control module is also used to:
Control each calculation module to enter working mode or idle mode.

In working mode, each read-only memory component in the calculation module performs the aforementioned operations.

In idle mode, there is no current flow within the calculation module.

Please refer to FIG. 26, which shows a schematic diagram of the calculation module of the CiM device according to the present implementation being configured in idle mode. In an example shown in FIG. 26, the wordlines and bitlines connected to the read-only memory device and selection switches are all connected to the lowest voltage VSS. Since the read-only memory devices are non-volatile, there is no static power consumption in the circuit.

As for the operation mode, please refer to the previous introduction for the setting of multiplication and multiply-accumulate operations, which will not be repeated here. For the read operation, taking the control module in FIG. 26 as an example, the present implementation can control the switches of the read-only memory device by controlling the wordlines to select the required data to be read, and then connect the corresponding selection switch to output the stored data of the read-only memory device through the calculation bitline.

The present implementation can adjust the voltage of the control wordlines and control bitlines according to the actual computational needs, selectively activate the calculation module to participate in the computation, and effectively reduce the overall power consumption of the system.

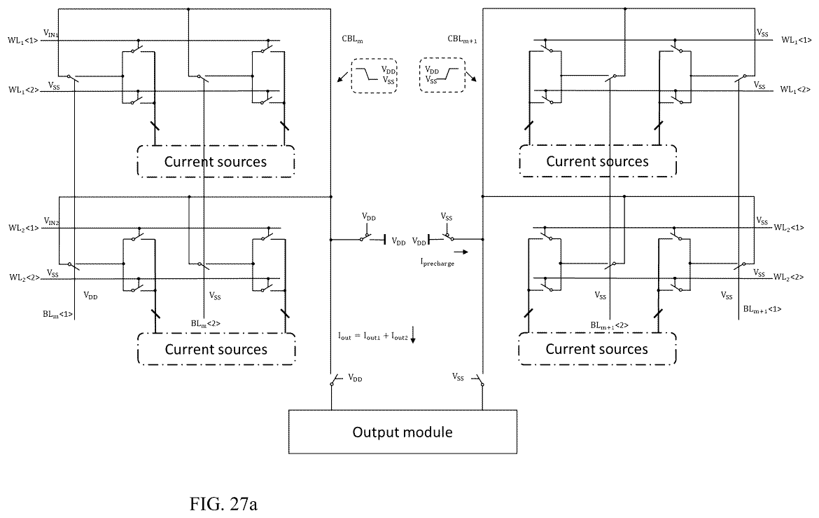

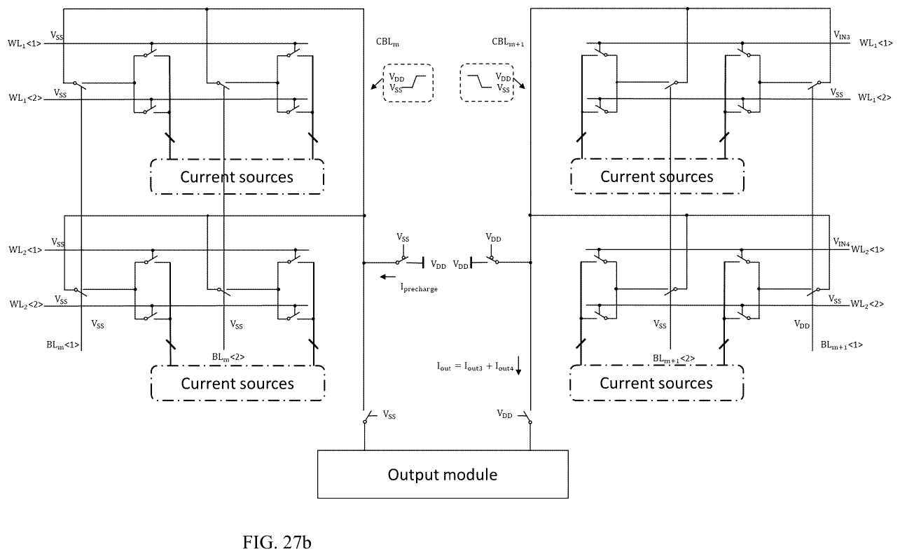

In one possible implementation, the control module is also used to adjust the signal timing of the control wordlines and control bitlines to achieve pipelining between different calculation bitlines. Please refer to FIGS. 27(a) and 27(b), which shows schematic diagrams of the pipelining operation of the CiM device according to the present implementation.

In an example shown in FIG. 27(a), following the example of the multiply-accumulate operation mentioned above, the multiplication operation of the input data of the read-only memory device M22 in calculation module 1 with control word line WL₁<1>, and the multiplication operation of the input data of the read-only memory device M8 with control word line WL₂<1> are conducted in the calculation bitline CBLₘ to obtain the corresponding multiply-accumulate result. The output detection interface outputs the multiply-accumulate result of calculation module 1 to the calculation bit line CBLₘ₊₁ of calculation module 2, as shown in FIG. 27(b). Following the multiply-accumulate operation, the multiplication operation of the input data of the read-only memory device M212 in calculation module 2 with control wordline WL₁<1>, and the multiplication operation of the input data of the read-only memory device M218 with control wordline WL₂<1> are conducted in the same manner to obtain the multiply-accumulate results of the read-only memory devices M212 and M218, and the sum of the multiply-accumulate result of calculation module 1. This achieves pipelining between calculation module 1 and calculation module 2.

It can be seen that the present implementation can achieve pipelining between different column calculation modules for multiply-accumulate operations by reasonably adjusting the signal timing on the control wordlines and control bitlines, thereby improving the throughput and utilization of the output detection interface. According to one aspect of the disclosure, a neural network accelerator is provided, which includes the aforementioned CiM device.

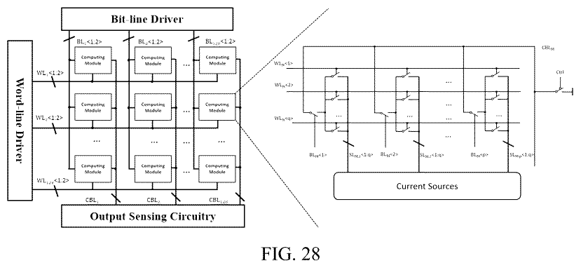

Please refer to FIG. 28, which shows a schematic diagram of a neural network accelerator according to the present implementation. The neural network accelerator is composed of an array circuit of computing modules and peripheral circuits such as wordline drivers, bitline drivers, and output detection interfaces. The weights are stored through electrical connections of read-only memory devices and different current sources. The wordline driver controls input feature maps, input data, and stored data to perform multiplication and accumulation operations inside the array circuit. The output detection interface detects the electrical characteristics of the calculation bitline and outputs them in the form of digital signals. This accelerator can be used for fixed-point neural network inference operations.

According to one aspect of the present disclosure, an electronic device is provided, which includes the above-mentioned neural network accelerator. As described above, the present implementation uses read-only memory devices to store weights, and each computing module requires at least one transistor and has the voltage for storing multiple bits. Compared with the traditional 6T SRAM structure, the storage density is significantly improved. More neural network parameters can be stored on limited chip areas, effectively reducing unnecessary memory access overhead. Each computing module of the CiM device in the present disclosure can switch between idle mode and working mode to adapt to different computing load scenarios, improve computing energy efficiency, and because the read-only memory device is non-volatile, there is no static power consumption. The multiply-accumulate operations on different calculation bitlines in the CiM device of the present disclosure can be pipelined during system implementation to improve the overall throughput rate and utilization rate of the output detection module circuit in a time-division multiplexing manner.

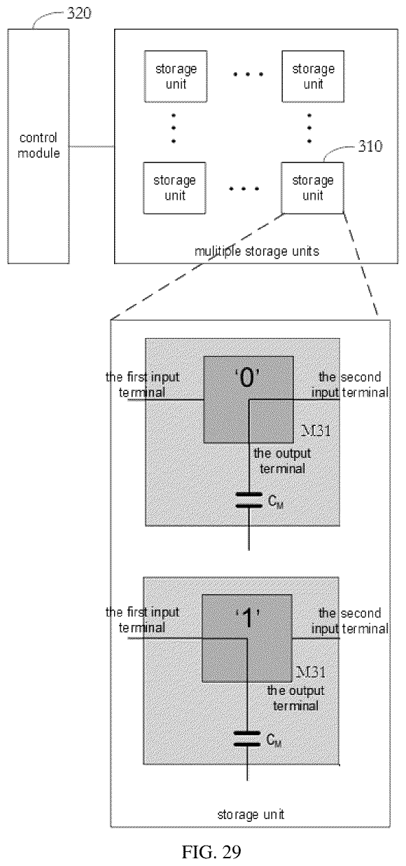

Please refer to FIG. 29, which shows a schematic diagram of an addressable storage device according to an embodiment disclosed herein.

As shown in FIG. 29, the device includes:

Multiple storage units 310, each comprising a read-only memory device M31 (Read-only memory, ROM) and a capacitor CM. The read-only memory device M31 includes the first input terminal, the second input terminal, and the output terminal. The output terminal of the read-only memory device M31 is connected to the first terminal of the capacitor CM. The read-only memory device M31 stores data based on the connection relationship between its first input terminal, second input terminal, and output terminal. Specifically, when the first input terminal and the output terminal of the read-only memory device M31 are connected (i.e., the read-only memory device M31 includes a connection relationship between the first input terminal and the output terminal), the memory device stores first storage data (such as a high level ‘1’). Alternatively, when the second input terminal of the memory device is connected to the output terminal (i.e., the memory device includes a connection relationship between the second input terminal and the output terminal), the read-only memory device M31 stores second storage data (such as a low level ‘0’). The levels of the first and second storage data are different.

The control module 320, connected to each storage unit 310, is used for:

Controlling the voltage of the first and second input terminals of the read-only memory device M31 in each storage unit 310 to perform a required operation;

Determining the operational result of the required operation based on the voltage level at the second terminal of the capacitor CM.

The read-only memory device M31 used in this implementation is a type of non-volatile memory that only reads data and does not write data. The read-only memory device M31 used in this implementation has the characteristics of high storage density and low reading power consumption. Based on the read-only memory device M31, this implementation implements a content-addressable storage device, which can improve the area efficiency of the content-addressable storage device, and reduce or even eliminate unnecessary energy consumption caused by memory access to achieve the purpose of reducing energy consumption.

Currently, the storage units used in related CAM technologies mostly use SRAM circuit structures based on at least six transistors (6T), and also require additional logic operation circuits. Therefore, they contain at least ten transistors per storage unit 310. In contrast, this implementation achieves data storage based on electrical connection relationships (such as for three-terminal devices, when the read-only memory device M31 includes a connection relationship between the first input terminal and the output terminal, the storage device stores the first storage data; or, when the storage device includes a connection relationship between the second input terminal and the output terminal, the read-only memory device M31 stores the second storage data) without the need for transistors, thus further improving area efficiency. This implementation does not limit the specific implementation of the read-only memory device M31 as long as it can achieve data storage based on electrical connection relationships.

It should be noted that in this implementation of the invention, the read-only memory device implemented through electrical connections is just an example, and theoretically any device with similar electrical characteristics can be used to construct the CAM circuit proposed in this implementation of the invention.

The matching and addressing calculations implemented in this disclosure have the advantages of high area efficiency and low power consumption, and can be used in various applications such as route searching in high-speed real-time communication systems.

This disclosure does not limit the specific implementation of control module 320. As an example, control module 320 may include a processing component. In one example, the processing component includes but is not limited to a separate processor, discrete components, or a combination of processors and discrete components. The processor may include a controller in the electronic device with a function of executing instructions and can be implemented in any suitable manner, such as by one or more application-specific integrated circuits (ASICs), digital signal processors (DSPs), digital signal processing devices (DSPDs), programmable logic devices (PLDs), field-programmable gate arrays (FPGAs), controllers, microcontrollers, microprocessors, or other electronic components. Inside the processor, the executable instructions can be executed through hardware circuits such as logic gates, switches, application-specific integrated circuits (ASICs), programmable logic controllers, and embedded microcontrollers.

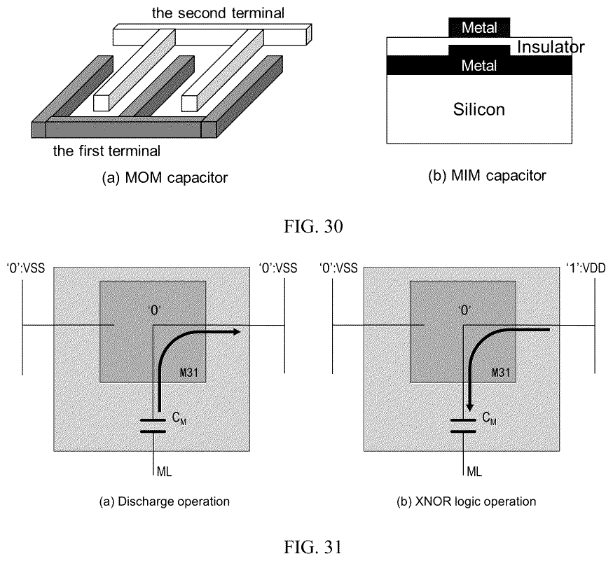

This disclosure does not limit the implementation of the capacitor CM in each storage unit 310. As an example, as shown in FIG. 31, the capacitor CM can be implemented using a Metal-Insulator-Metal capacitor (MIM), a Metal-Oxide-Metal capacitor (MOM), a gate capacitance of a transistor, or other forms of capacitors, without being specifically limited here. Among them, FIG. 30 shows a schematic structure of a MIM capacitor and a MOM capacitor that can be used in this disclosure.

It should be noted that the read-only memory device M31 in this disclosure includes electrical connections (i.e., the connection relationship), and the output terminal of the read-only memory device M31 is connected to the first or the second input terminal of the read-only memory device M31 according to the different data stored in the read-only memory device M31. This disclosure provides an example in FIG. 29, where the read-only memory device M31 stores the first storage data (e.g., high level ‘1’) when the connection relationship between the first input terminal and the output terminal of the read-only memory device M31 exists, or stores the second storage data (e.g., low level ‘0’) when the connection relationship between the second input terminal and the output terminal of the read-only memory device M31 exists. However, this disclosure is not limited to this. In practical use, the levels of the first storage data and the second storage data only need to be complementary (opposite). For example, in other implementations, the first storage data can also be low level ‘0’ and the second storage data can also be high level ‘1’.

As an example, the operation of this disclosure may include a read operation to read the data stored in storage unit 310. When performing a read operation on storage unit 310, the voltages of the first and the second input terminals can be kept complementary (high level 1, low level 0), and the output terminal connected to the first or the second input terminal can be distinguished based on the voltage level of the output terminal, thereby obtaining the stored data.

When performing a matching addressing calculation using CAM, the XNOR logic calculation and weighted accumulation required for calculating the matching value are key operations and the main sources of power consumption. For the matching value calculation of input data and stored data, this disclosure can be decomposed into the XNOR logic calculation of each bit position of the input data and stored data, and then the results of the XNOR logic calculation are weighted and accumulated to obtain the matching value. The output of the XNOR logic calculation is ‘1’ when both inputs are ‘0’ or ‘1’, otherwise it is ‘0’. Therefore, the closer the input data and stored data are, the higher the resulting matching value.

In one possible implementation, the required operation may include an XNOR logic operation and voltage control can be applied to the first and second input terminals of the read-only memory device M31 for each storage unit 310 to perform the required operation. This may include:
Grounding the first and second input terminals of the read-only memory device M31 and discharging capacitor C_{M};
Floating the first and second input terminals of the read-only memory device M31, and leaving the output terminal floating electrically;
Applying the signals to the first and second input terminals of the read-only memory device M31 according to the input data, and executing the XNOR logic operation between the input data and the stored data with the storage unit 310.

The required operation's result is then determined based on the voltage of the second terminal of the capacitor C_{M}, obtaining the XNOR logic operation result between the input data and the stored data.

Please refer to FIG. 31, which shows a schematic diagram of the content-addressable memory storage unit 310 performing an XNOR logic operation according to the present implementation. In one example, as shown in FIG. 31(a), the first and second input terminals of the read-only memory device M31 are both set to VSS, and the capacitor C_{M} on the positive electrode is first cleared of the charge and then kept in a floating state. Then, the first input terminal of the read-only memory device M31 remains at VSS, and the second input terminal of the read-only memory device M31 is set to VDD, complementary to the voltage of the first input terminal of the read-only memory device M31, indicating that the input data is ‘0’. Since the output terminal of this storage unit 310 is connected to the second input terminal, i.e., the stored data is ‘0’, the output voltage of the storage unit 310 is high-level VDD, indicating that the output data is ‘1’, thus achieving the XNOR logic operation between the input data of the first and second input terminals of the read-only memory device M31 and the stored data.

The storage unit 310 of the CAM proposed in the present implementation has the advantages of high area efficiency, low power consumption, and can effectively improve the leakage problem in idle states. It is a type of circuit that can greatly improve area efficiency and reduce power consumption for computing within memory.

Of course, this implementation can provide interfaces for configuring each storage unit 310. For example, the interfaces of each storage unit 310 may include the first bitline BL, the second bitline BLB, and the matching line ML. In one possible implementation, the control module 320 is connected to the first input terminal of the read-only memory M31 via BL and to the second input terminal of the read-only memory M31 via BLB. The control module 320 is also connected to the second terminal of the capacitor C_{M} via ML.

In practice, the output terminal of the storage unit 310 is connected to BL to represent a stored ‘1’, or to BLB to represent a stored ‘0’. Alternatively, in actual usage, the output terminal of the storage unit 310 can be connected to BLB to represent a stored ‘1’, and to BL to represent a stored ‘0’.

When reading from the storage unit 310, the voltage of BL and the voltage of BLB are kept complementary. Based on the voltage level at the output terminal, it can be determined whether the output terminal is connected to BL or BLB, thereby obtaining the stored information.

With this setup, the control module 320 can directly control the interfaces of the storage unit 310. Taking the XNOR logic operation shown in FIG. 31 as an example, the control module 320 first sets both BL and BLB to a low voltage VSS, so that the charge on the pole plate of the capacitor C_{M} is first cleared and then left floating. Then, BL is kept at VSS, and BLB is set to a high voltage VDD which is complementary to BL, indicating that the input data is ‘0’. Since the output terminal of the storage unit 310 is connected to BLB, which corresponds to a stored ‘0’, the voltage at the output terminal of the storage unit 310 is VDD, indicating that the output data is ‘1’, thus achieving an XNOR logic operation between the input data on BL and the stored data in the memory.

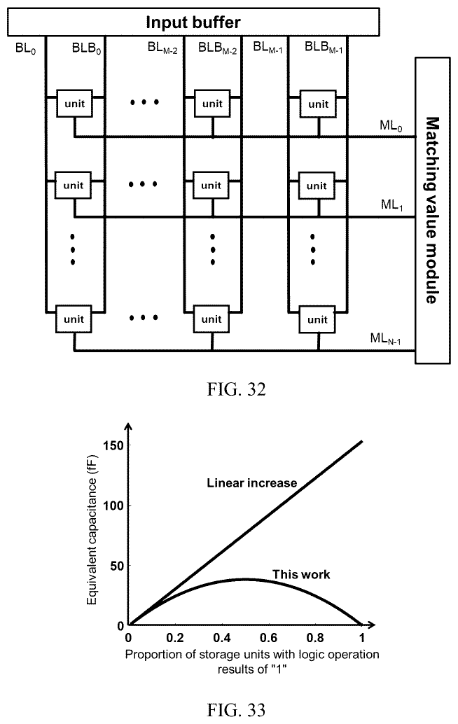

Please refer to FIG. 32, which illustrates a schematic diagram of an addressable storage device according to the disclosure of this implementation.

In a possible implementation, as shown in FIG. 32, multiple storage units 310 (also referred to as unit circuits) can be combined into a multi-row and multi-column layout by electrical connections. The electrical connection method is: connect the matching line ML of some or all storage units 310 in the same row (such as the first row of unit circuits with the same matching line ML0), and connect the first bitline BL and second bitline BLB of some or all storage units 310 in the same column respectively (such as the first column of unit circuits with the same first bitline BL0 and second bitline BLB0).

As shown in FIG. 32, for example, the control module can input a buffer (including operation data) to each BL and BLB, and obtain and process the operation result through the matching value processing module in the control module 320.

Please refer to FIG. 33, which shows a schematic diagram of the proportion of equivalent capacitance that needs to be charged and storage units with logic operation results of ‘1’ during multiplication and accumulation operations in the addressable storage device according to the present disclosed implementation.

It can be understood that the power consumption of the array circuit for matching addressing calculation in the present disclosed implementation is due to charging the capacitance C_{M}. As shown in FIG. 33, the equivalent capacitance of the storage unit 310 in the present disclosed implementation does not increase linearly with the increase of the proportion of storage units with logic operation results of “1”. After the proportion of storage units 310 with logic operation results of ‘1’ exceeds a certain value, the present disclosed implementation can greatly reduce the power consumption during the calculation process.

It should be noted that the parameters of the device used to obtain the results in FIG. 33 are: the capacitance C_{M} of the storage unit 310 is 1.2 fF, and the array size is 128×128.

In addition, in the idle state, the matching addressing calculation circuit in the present disclosed implementation has almost no leakage current, which can greatly improve the leakage problem of SRAM storage unit 310 in the idle state.

In one possible implementation, the required operation may also include a content addressing operation, where the first input and second input of the read-only memory device M31 for each storage unit 310 are voltage-controlled to perform the required operation. This may include:
Grounding the first and second inputs of each read-only memory device M31 in one or more rows of storage units 310 and discharging the corresponding capacitor C_{M} of each storage unit 310 in the same row;
Floating the first and second inputs of each read-only memory device M31 in one or more rows of storage units 310 and leaving the corresponding match lines floating;
Applying the signals to the first and second input terminals of the read-only memory devices 310 in one or more rows of storage units, according to the input data, to perform the content addressing operations in one or more rows. The operation results of the required operations are determined by the voltages of the second terminal of the capacitors C_{M}, obtaining the addressing calculation result of the input data and the stored data, based on the voltage of the match lines of each activated row of storage units 310.

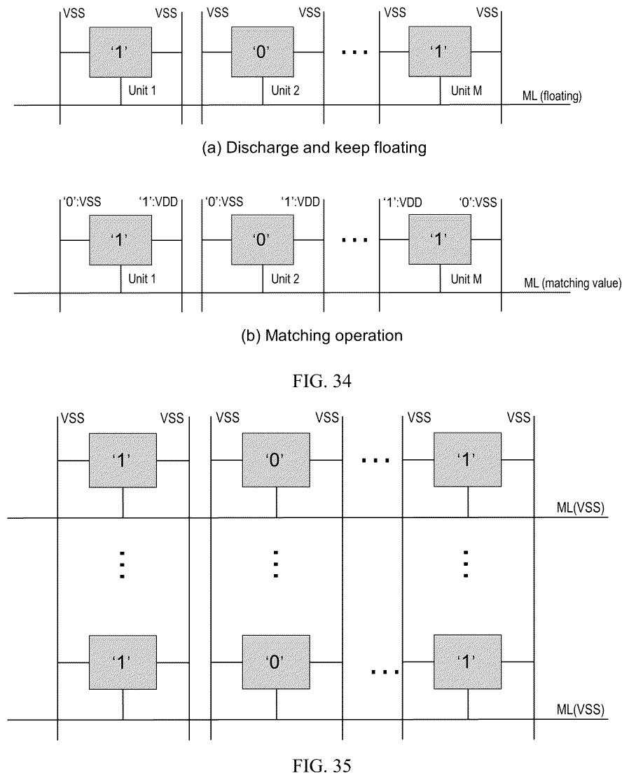

Please refer to FIG. 34, which shows a schematic diagram of content addressing using the content-addressable storage device in this implementation.

In one example, as shown in (a) of FIG. 34, all the first bitlines BL<0:M> and second bitlines BLB<0:M> connected to the unit circuits can be set to a low voltage level VSS, and the matching line ML and the capacitor C_{M} are cleared of charge and kept floating. Here, M is an integer.

In another example, as shown in (b) of FIG. 34, the data that needs to be addressed and matched can be converted into binary numbers, resulting in multiple bits of data to be operated on. The first bitlines BL<0:M> and second bitlines BLB<0:M> can be set to different voltage values according to the different bits of intput data, where the corresponding first and second bit lines have complementary voltages. This achieves the XNOR logic operation between the data to be operated on and the stored data represented by the internal electrical connection method of the storage unit 310. The entire circuit connected to the matching line ML performs a normalization and accumulation operation. The control module 320 obtains a voltage value ranging from VDD to VSS through the matching line ML. The closer the voltage value is to 1, the more successful the match is.

Of course, in addition to arranging the storage units 310 in rows or columns, the implementation can also use other ways to arrange them. When performing content addressing, certain data can be addressed and matched based on the matching line ML. For example, assuming that multiple storage units 310 are distributed in different rows and columns but connected to the same matching line ML, the data that needs to be addressed and matched can be converted into binary numbers, resulting in multiple bits of data to be operated on. Each bit of data is assigned to each storage unit 310 on the matching line ML for an XNOR operation. The entire circuit connected to the matching line ML performs a normalization and accumulation operation. The control module 320 obtains a voltage value ranging from VDD to VSS through the matching line ML. The closer the voltage value is to 1, the more successful the match is.

In a possible implementation, the target operation includes a content-addressed operation, which involves voltage control of the first and second input terminals of read-only memory devices M1 for each storage unit 310 to perform the required operation. This may include:
Grounding the first and second input terminals of each read-only storage device in the storage units 310 connected to the same matching line ML, and discharging each capacitor C_{M} connected to the storage units 310 connected to the same matching line ML;
Floating the first and second input terminals of each read-only storage device M31 in the storage units 310 connected to the same ML, and leaving the MLs electrically floating;
Applying the signals to the first and second input terminals of each read-only memory device M31 in the storage units 310 connected to the same ML, according to the input data, to perform the content addressing operations. The operation results of the required operations are determined by the voltages of the second terminal of each capacitor C_{M}, obtaining the addressing calculation result of the input data and the stored data, based on the voltage of the ML.

This public implementation example does not limit the arrangement of multiple storage units 310 and can use a multi-row and multi-column array arrangement or other methods. For different arrangements, this example can achieve addressing matching for the required data, increasing flexibility.

In one possible implementation, the control module 320 can also be used to control at least one storage unit 310 to work in either a working mode or an idle mode. In the working mode, the storage unit 310 performs the required operation, while in the idle mode, the first input terminal, second input terminal, and output terminal of the read-only memory device M31 of the storage unit 310 are set to low voltage level VSS. The configuration of the first bitline BL and the second bitline BLB of each storage unit 310 in the working mode is described above and will not be repeated here.

Please refer to FIG. 35, which shows a schematic diagram of the idle mode of the content-addressable storage device implemented in this implementation. In one example, as shown in FIG. 35, the read-only memory device M31 of the storage unit 310 has its first input terminal, second input terminal, and output terminal set to a low level, that is, each of the first bitline BL, second bitline BLB, and match line ML is set to a low level, thereby reducing array power consumption. The information stored in the circuit unit is non-volatile and will not cause data loss.

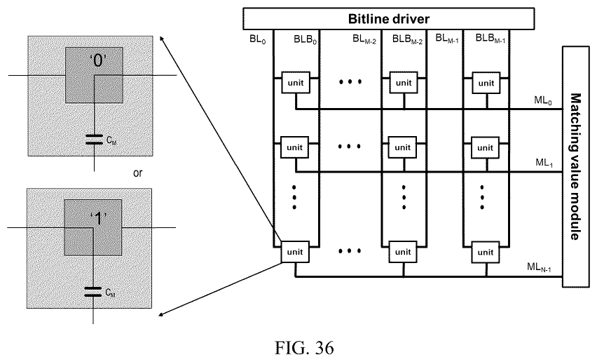

Please refer to FIG. 36, which shows a schematic diagram of the content-addressable storage device implemented using the contents of this implementation. For example, the control module 320 can drive each first bitline BL and second bitline BLB through the bit-line driver, configure each match line ML through the matching value processing module (such as setting it to a floating state in the same or logical operation), and obtain the operation result from the match line ML. As an example, the data to be matched is input through the first bitline BL and the second bitline BLB, and the result of the matching value calculation is output to the matching value processing module for subsequent operations.

According to one aspect of this disclosure, a memory is provided, which includes the above-mentioned content-addressable storage device.

According to one aspect of the present disclosure, an electronic device is provided which comprises a memory as described. The content-addressable storage device with high area efficiency and low power consumption disclosed in this embodiment can effectively improve the leakage problem of the SRAM storage unit 310 in an idle state and is a kind of content-addressable memory circuit that can greatly improve area efficiency and reduce power consumption.

A computing module and a computing array of the CiM device based on ROM with a current/charge domain computing functionality characteristic according to embodiments of the present disclosure will be described below with reference to the accompanying drawings.

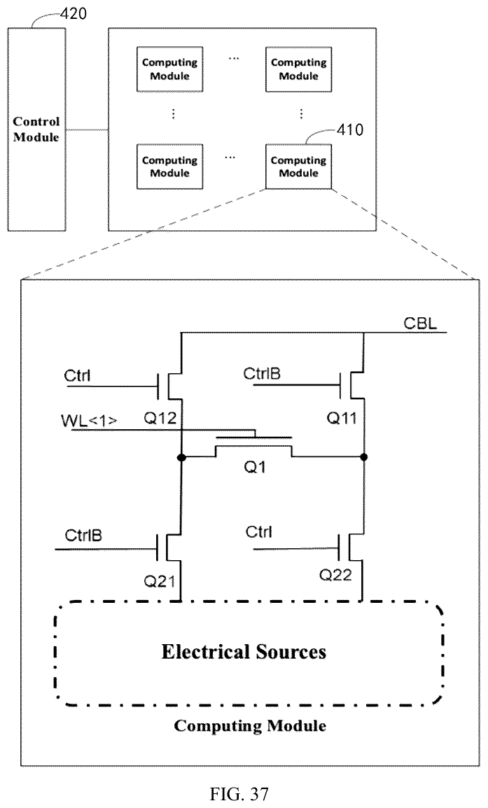

FIG. 37 schematically illustrates the CiM device based on ROM according to embodiments of the present disclosure.

As illustrated in FIG. 37, the device includes:

Multiple computing modules 410, each computing module 410 comprising at least one ROM device (Q1), multiple selection devices (Q11, Q12, Q21, Q22), electrical sources, data storage lines, control word-line (WL<1>), computing bit-lines (CBL), and data selection control lines (Ctrl, CtrlB). The control terminal of the ROM device (Q1) is connected to the corresponding control word-line (WL<1>) to receive control signals. The two data terminals of the ROM device (Q1) are connected to different data storage lines. The data storage lines are connected to the electrical source and the computing bit-line (CBL) through the selection devices. The data state of each data storage line is represented in the form of current or voltage, depending on the type of electrical source. The control terminal of the selection devices (Q11, Q12, Q21, Q22) is connected to the corresponding data selection control lines to receive data selection control signals. The data selection control signals are used to enable the corresponding selection devices.

Control module 420, the control module is connected with the control word-line and data selection control line of each computing module 410, which is used to select the corresponding ROM device and select the device for target operation through the control word-line and data selection control line, and output the result data through the computing bit-line.

The disclosed embodiment of the high-density CiM device based on ROM implements multi-level cell storage for a single ROM, enabling each computing module to have multi-bit data storage and computation capabilities. This allows each computing module to have multi-bit data storage and computation capabilities, thereby reducing or eliminating the need for off-chip memory access.

The high-density CiM device based on ROM described in this embodiment can be applied to neural network operations. Due to the multi-bit data storage and computation capabilities of each computing module, it has the potential to store all parameters of large-scale neural networks on-chip, reducing or even eliminating additional power consumption and delays caused by data movement between on-chip processing unit and off-chip memory. This reduces energy consumption and latency during inference operations, enabling efficient deployment of AI algorithms on edge devices. Additionally, due to its high-density storage characteristics, the high-density CiM device based on ROM can also achieve high energy efficiency and low latency when applied in other scenarios.

This embodiment does not impose limitations on the specific implementation of the ROM device. Those skilled in the art can choose suitable implementation methods based on practical situations and requirements. For example, the ROM device can be implemented using switches, diodes, bipolar transistors, metal-oxide-semiconductor field-effect transistors (MOSFETs), or other means.

This embodiment does not impose limitations on the specific implementation of the control module 410. Those skilled in the art can choose suitable implementation methods based on practical situations and requirements. In one example, the control module 410 may include a processing component, which can be an individual processor, discrete components, or a combination of a processor and discrete components. The processor can be implemented as a controller in an electronic device with instruction execution capabilities. The processor can be implemented in any suitable manner, such as using one or more application-specific integrated circuits (ASICs), digital signal processors (DSPs), digital signal processing devices (DSPDs), programmable logic devices (PLDs), field-programmable gate arrays (FPGAs), controllers, microcontrollers, microprocessors, or other electronic components. Inside the processor, the executable instructions can be executed by hardware circuits such as logic gates, switches, application-specific integrated circuits (ASICs), programmable logic controllers, and embedded microcontrollers.

This embodiment does not impose limitations on the number, type, or arrangement of the ROM devices and selection devices in the CiM device. It does not impose limitations on the number of data storage lines, control word-lines, computing bit-lines, or data selection control lines. It does not specify the specific data states corresponding to the data storage lines of the ROM device, nor does it impose limitations on the representation form of the data states (voltage or current). It does not impose limitations on the type of electrical source. For example, the electrical source can include multiple voltage sources or multiple current sources. The specific parameters of the current sources and voltage sources are not limited in this embodiment and can be set by those skilled in the art based on practical situations and requirements.

This embodiment does not impose limitations on the arrangement of the ROM devices in the computing module 410. For example, the memory array formed by the ROM devices in the computing module 410 can have multiple rows and one column, where each ROM device is controlled by an independent control word-line and outputs the corresponding computation result through the same computing bit-line. Alternatively, the memory array formed by the ROM devices in the computing module 410 can have multiple columns and one row, where multiple ROM devices are controlled by the same control word-line and output the corresponding computation results through computing bit-lines corresponding to different columns. The memory array formed by the ROM devices in the computing module 410 can have multiple rows and multiple columns, where each row of ROM devices is controlled by independent control word-lines and outputs the corresponding computation result through the same computing bit-line, or through computing bit-lines corresponding to different columns. This embodiment does not impose limitations on the specific configuration of the ROM devices in the CiM device. Those skilled in the art can choose suitable methods of implementation based on practical situations and requirements.

Based on the above description, the CiM device of this embodiment can include multiple computing modules 410, each of which can include at least one ROM device. Each ROM device in this disclosure is capable of storing multiple bits of data, which significantly increases the storage density on the processor chip compared to other related CiM techniques.

The specific implementation of the ROM devices and selection devices is not limited in this disclosure. Those skilled in the art can choose appropriate devices based on practical situations and requirements. For example, metal-oxide-semiconductor field-effect transistors (MOSFETs) can be used to implement the ROM devices and selection devices as switches.

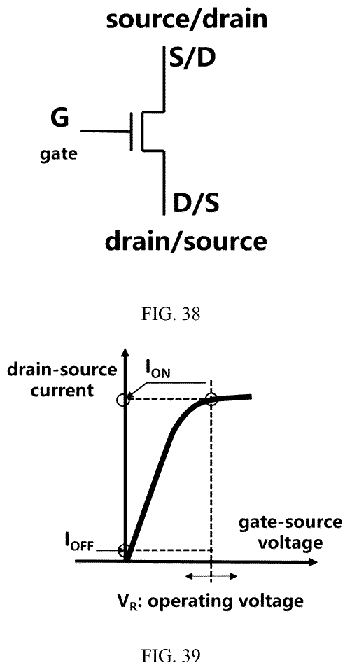

FIG. 38 schematically illustrates the circuit symbol of a metal-oxide-semiconductor field-effect transistor (MOSFET) according to embodiments of the present disclosure. FIG. 39 schematically illustrates the i_{DS}-v_{GS} characteristic of the MOSFET according to embodiments of present disclosure.

As illustrated in FIG. 38, the metal-oxide-semiconductor field-effect transistor (MOSFET) is a three-terminal device. It is controlled by the gate voltage to modulate the impedance characteristics between the drain and source terminals. The MOSFET exhibits switch-like characteristics, as illustrated in FIG. 39.

This disclosure utilizes MOSFETs to implement ROM devices, data selection devices, column selection devices, and reset switches. The impedance characteristics between the drain and source terminals of the MOSFETs are leveraged to create switches. The gate of the MOSFET serves as the control terminal, enabling the device to store information and perform switching functions.

The chosen MOSFETs in this disclosure are specifically the N-type MOSFETS. A single MOSFET can change its impedance characteristics between the drain and source terminals by controlling the potential difference between the gate voltage and the source voltage. When the drain and source are in a low-impedance state, the circuit is conductive, and when they are in a high-impedance state, the circuit is disconnected.

It should be noted that in this disclosure, the MOSFET is just one example, and theoretically, any device with switch-like characteristics can be used to construct the CiM device proposed in this disclosure.

In one possible implementation, as shown in FIG. 37, the device comprises selection devices, specifically data selection devices (Q11, Q12, Q21, Q22), the data selection devices consist of upper data selection devices (Q11, Q12) and lower data selection devices (Q21, Q22), the upper data selection devices include a first upper data selection device Q11 and a second upper data selection device Q12, the lower data selection devices include a first lower data selection device Q21 and a second lower data selection device Q22, the device also includes data selection control lines, namely the first data selection control line CtrlB and the second data selection control line Ctrl, additionally, it comprises data storage lines, which are the first data storage lines and the second data storage lines;

Both the input terminals of the first lower data selection device Q21 and the second lower data selection device Q22 are connected to the electrical source;

The output terminal of the first lower data selection device Q21 is connected to the input terminal of the second upper data selection device Q12 through the first data storage line; The output terminal of the second lower data selection device Q22 is connected to the input terminal of the first upper data selection device Q11 through the second data storage line;

The control terminal of the first lower data selection device Q21 and the control terminal of the first upper data selection device Q11 are both connected to the first data selection control line CtrlB;

The control terminal of the second lower data selection device Q22 and the control terminal of the second upper data selection device Q12 are both connected to the second data selection control line Ctrl;

The output terminals of the first upper data selection device Q11 and the second upper data selection device Q12 are connected to the computing bit-lines;

The first data terminal and the second data terminal of each ROM device (Q1) are respectively connected to the corresponding first data storage line and second data storage line.

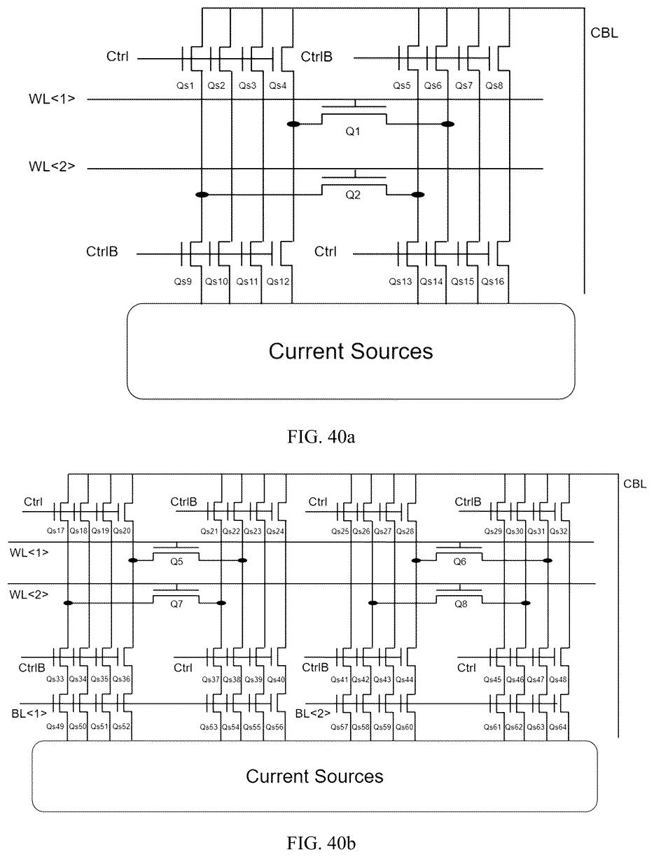

FIGS. 40a and 40b schematically illustrate the computing module implemented in the current domain according to embodiments of present disclosure.

In one possible implementation, as illustrated in FIG. 40a, the electrical source may be a current source. The current source module may include multiple current sources. Each computing module can include two or more ROM devices and data selection devices. The data selection devices include lower data selection devices and upper data selection devices. The control terminal of the lower data selection devices is connected to the corresponding data selection control line (CtrlB or Ctrl). The input terminal of the lower data selection devices is connected to the current sources in the current source module. The output terminal of the lower data selection devices is connected to the data terminals of the ROM devices that are connected to the same data storage line. The control terminal of the upper data selection devices is connected to the corresponding data selection control line (CtrlB or Ctrl). The input terminal of the upper data selection devices is connected to the data terminals of the ROM devices that are connected to the same data storage line. The output terminal of the upper data selection devices is connected to the corresponding computing bit-line. As an example, in the working mode, the states of the first data selection control line CtrlB and the second data selection control line Ctrl are complementary. When one is at a high voltage level, the other is at a low voltage level. The control terminals of each ROM device are connected to the corresponding control word-lines. In the proposed CiM device, each module may contain any number of ROM devices. The present disclosure does not impose any limitations on this.

For example, the number of data selection devices may be directly related to the number of bits stored in the ROM devices. When more bits are stored in the ROM devices, the number of data selection devices will increase. In the example shown in FIG. 40a, each ROM device stores 4 bits of information, 2 bits on the left and 2 bits on the right. Therefore, in this example, 4 data storage lines are used on each of the left and right sides. Each data storage line has an upper data selection device and a lower data selection device, as shown in FIG. 40a. In this computing module, there are a total of 16 data selection devices, 8 on each side.

It should be noted that the descriptions in FIG. 40a and other accompanying figures regarding the number of ROM devices and selection devices are exemplary and should not be considered as limitations of the present disclosure. In practical applications, professionals in this field can set a larger number of read-only memory devices to further increase the storage density.

In one possible implementation, as illustrated in FIG. 40b, the CiM device may include multiple computing modules. Each computing module may consist of two or more ROM devices, data selection devices, and column selection devices. The data selection devices can include lower data selection devices and upper data selection devices. The ROM devices within each computing module are arranged in rows and columns. The control terminals of the column selection devices connected to the same column of ROM devices are connected to the same control line. The control terminals of the ROM devices in the same row are connected to the same control word-line. The control terminals of the lower data selection devices are connected to the corresponding data selection control line (CtrlB), and the column selection devices are connected in series with the lower data selection devices. The input terminals of the serially connected components are connected to a current source, and the output terminal of the serially connected components is connected to the data terminals of the ROM devices connected to the same data storage line. The control terminals of the upper data selection devices are connected to the corresponding data selection control line (Ctrl), and the input terminals of the upper data selection devices are connected to the data terminals of the ROM devices connected to the same data storage line. The output terminals of the upper data selection devices are connected to the corresponding computing bit-lines. In the working mode, the input states of the data selection control lines (Ctrl) and (CtrlB) are complementary, that is, when one is in a high voltage level, the other is in a low voltage level.

In one example, as illustrated in FIG. 40b, the computing module may include ROM devices Q5-Q8, data selection devices Qs17-Qs48, and column selection devices Qs49-Qs64. The control terminals of ROM devices Q5 and Q6 are both connected to control word-line WL<1>, and the control terminals of ROM devices Q7 and Q8 are both connected to control word-line WL<2>. The control terminals of data selection devices Qs17-Qs20, Qs25-Qs28, Qs37-Qs40, and Qs45-Qs48 are all connected to the data selection control line Ctrl. The control terminals of data selection devices Qs21-Qs24, Qs29-Qs32, Qs33-Qs36, and Qs41-Qs44 are all connected to the data selection control line CtrlB. The control terminals of column selection devices Qs49-Qs56 are all connected to the control bit-line BL<1>, and the control terminals of column selection devices Qs57-Qs64 are all connected to the control bit-line BL<2>.

It should be noted that the specific connection of the serially connected components is not limited in this disclosed embodiment. As illustrated in FIG. 40b, the input terminal of the serially connected components can be the input terminal of the column selection device, and the output terminal of the serially connected components can be the output terminal of the lower data selection device. In this case, the input terminal of the column selection device is connected to the current source module, and the output terminal of the column selection device is connected to the lower data selection device's input terminal. The serially connected components can also be in other serial forms (i.e., the positions of the column selection device and the lower data selection device can be exchanged). For example, the input terminal of the serially connected components can be the input terminal of the lower data selection device, and the output terminal of the serially connected components can be the output terminal of the column selection device. In this case, the input terminal of the lower data selection device is connected to the current source module, and the output terminal of the column selection device is connected to the data storage line, while the input terminal of the column selection device is connected to the output terminal of the lower data selection device.

In one possible implementation, if the electrical source is multiple voltage sources, the computing module further includes a reset switch and a capacitor, the control terminal of the reset switch is connected to a reset control word-line to receive a reset signal, the reset terminal of the reset switch is used to receive a reset state voltage, the reset detection terminal of the reset switch and the first terminal of the capacitor are connected to the output terminal of the upper data selection device, the second terminal of the capacitor is connected to the computing bit-line.

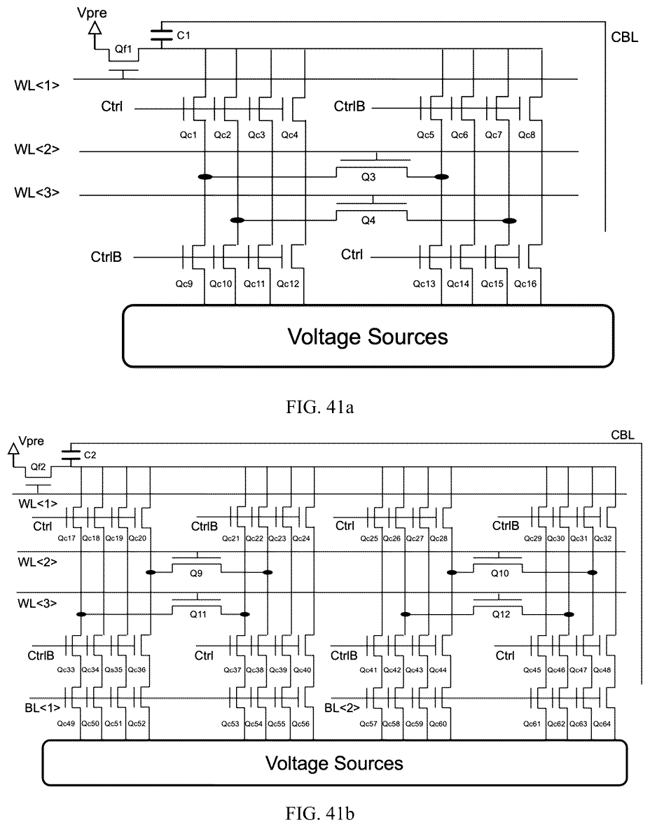

FIGS. 41a and 41b schematically illustrate the computing module implemented in the charge domain according to embodiments of present disclosure.

In one possible implementation, as illustrated in FIG. 41a, each computing module may include two or more ROM devices, data selection devices, reset switch Qf1, and capacitor C1. The data selection devices consist of lower data selection devices and upper data selection devices. The control terminal of the lower data selection devices is connected to the corresponding data selection control line. The input terminal of the lower data selection devices is connected to the voltage source. The output terminal of the lower data selection devices is connected to the data terminals of the ROM devices connected to the same data storage line. The control terminal of the upper data selection devices is connected to the corresponding data selection control line. The input terminal of the upper data selection devices is connected to the data terminals of the ROM devices connected to the same data storage line. The output terminal of the upper data selection devices is connected to the corresponding computing bit-line via a capacitor.

As an example, as illustrated in FIG. 41a, the reset switch Qf1 may include a reset control terminal, a reset detection terminal, and a reset terminal. The reset control terminal is connected to the control word-line WL<1> to adjust the impedance characteristics between the reset detection terminal and the reset terminal. The reset terminal is used to receive a reset state voltage Vpre. The reset detection terminal is connected to the first terminal of the capacitor C1 through the upper data selection devices and connected to the data terminals of the read-only memory devices. The second terminal of the capacitor C1 is connected to the computing bit-line CBL and outputs the resulting data. In the working mode, the input states of the data selection control lines Ctrl and CtrlB are complementary, that is, when one is in a high voltage level, the other is in a low voltage level. The control terminals of the ROM devices are respectively connected to the corresponding control word-lines. In the CiM device, each module may contain any number of ROM devices, and this embodiment does not impose any specific limitations on that.

In one possible implementation, as illustrated in FIG. 41b, the CiM device may include multiple computing modules. Each computing module may consist of two or more ROM devices, data selection devices, column selection devices, reset switch Qf2, capacitor C2. The data selection devices include lower data selection devices and upper data selection devices. The ROM devices in each computing module are arranged in rows and columns. The control terminals of the column selection devices connected to the ROM devices in the same column are connected to the same control bit-line. The control terminals of the ROM devices in the same row are connected to the same control word-line. The control terminal of the lower data selection is connected to the corresponding data selection control line. The column selection devices are connected in series with the lower data selections to form a serially connected component. The input terminal of the serially connected component is connected to the voltage source, and the output terminal of the serially connected component is connected to the data terminals of the ROM devices connected to the same data storage line. The control terminal of the upper data selection device is connected to the corresponding data selection control line. The input terminal of the upper data selection device is connected to the data terminals of the ROM devices connected to the same data storage line. The output terminal of the upper data selection device is connected to the corresponding computing bit-line via a capacitor.

For example, as illustrated in FIG. 41b, the reset switch Qf2 includes a reset control terminal, a reset detection terminal, and a reset terminal. The reset control terminal is connected to the control word-line WL<1> to adjust the impedance characteristics between the reset detection terminal and the reset terminal. The reset terminal is used to receive the reset state voltage Vpre. The reset detection terminal is connected to the first terminal of the capacitor C2 through the upper data selection device and connected to the data terminals of each ROM device. The second terminal of the capacitor C2 is connected to the computing bit-line CBL, and the result data is output through this computing bit-line. In the working mode, the states of the data selection control lines Ctrl and CtrlB are complementary. When one is at a high voltage level, the other is at a low voltage level.

For example, as illustrated in FIG. 41b, the computing module may include ROM devices Q9-Q12, data selection devices Qc17-Qc48, and column selection devices Qc49-Qc64. The control terminals of ROM devices Q9 and Q10 are connected to the control word-line WL<2>, and the control terminals of ROM devices Q11 and Q12 are connected to the control word-line WL<3>. Data selection devices Qc17-Qc20, Qc25-Qc28, Qc37-Qc40, and Qc45-Qc48 are connected to the data selection control line Ctrl. Data selection devices Qc21-Qc24, Qc29-Qc32, Qc33-Qc36, and Qc41-Qc44 are connected to the data selection control line CtrlB. Column selection devices Qc49-Qc56 are connected to the control bit-line BL<1>, and column selection devices Qc57-Qc64 are connected to the control bit-line BL<2>.

For example, each computing module may be connected to one or more current sources or voltage sources with different operating values. In current-domain computing mode, the current sources may be connected to one or more ROM devices. In charge-domain computing mode, the voltage sources may be connected to one or more ROM devices. This embodiment combines the high storage density characteristics of the ROM devices through the reuse of the current sources and voltage sources, thereby improving the overall area efficiency.

For example, in the computing modules shown in FIGS. 40a, 40b, 41a, and 41b, each ROM device may store 4 bits of information. Each data terminal of the ROM device is connected to one of the four data storage lines on each side (there are four possible states for 2-bit data) to store 2 bits of information for each data terminal of the ROM device. The number of data storage lines on each side of the ROM devices in the computing modules of the CiM device is not limited. Those skilled in the art may choose a suitable method based on the semiconductor manufacturing process, layout method, and requirements used in practice to implement it.

In one possible implementation, this disclosure enables the sharing of selection devices and data storage lines, further increasing the storage density of the CiM device.

In one possible implementation, the individual ROM devices within the computing module are combined in a layout consisting of multiple rows and columns. The control terminals of each row of ROM devices are connected to the same control word-line. The two data terminals of each ROM device in each column are respectively connected to the corresponding first data storage line and second data storage line. The output terminals of each upper data selection device are connected to the corresponding computing bit-line through capacitors or directly, and the desired result data is output through these computing bit-lines.

In one possible implementation, the first data storage line connected to each ROM device in the (K+1)th column is the same as the second data storage line connected to each ROM device in the Kth column, where K is an integer.

The following provides an illustrative explanation of such implementation.

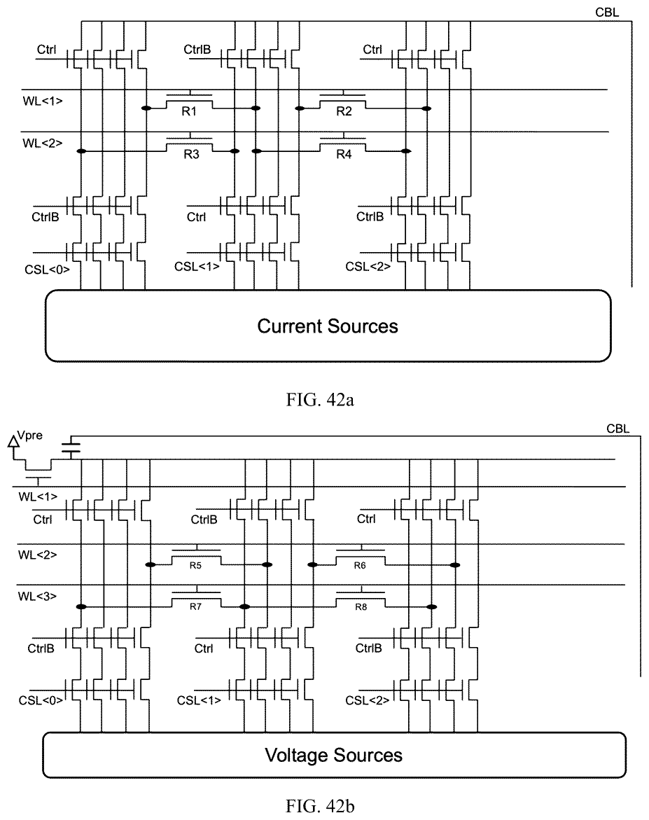

FIGS. 42a and 42b schematically illustrate the computing module implemented in the first type of sharing of selection devices in the current domain and charge domain according to embodiments of present disclosure.

In one possible implementation, as illustrated in FIGS. 42a and 42b, data storage lines and selection devices (including lower data selection devices, upper data selection devices, and column selection devices) between adjacent column ROM devices within the CiM device may be shared. In the first type of sharing, the two data terminals of the ROM devices in the same column are each connected to a serially connected component formed by the column selection device and the lower data selection device. The column selection devices in the serially connected components connected to the two data terminals of the ROM devices in the same column are controlled by two different column select lines (CSL). When performing operations on a column of ROM devices, both CSLs on the corresponding sides need to be activated simultaneously.

For example, as illustrated in FIG. 42a, in the current domain, to perform a read or multiplication operation on the ROM device R1, both column select lines CSL<0> and CSL<1> are set to the high voltage level VDD, while setting the remaining column select lines to the low voltage level VSS. Activate the corresponding control word-line WL<1> and set the remaining control word-lines WL to the low voltage level VSS. Depending on the desired operation, set either the data select control line Ctrl or the data select control line CtrlB to the high voltage level VDD, and set the other one to the low voltage level VSS. The result is output in the form of current to the computing bit-line CBL.

Similarly, as illustrated in FIG. 42b, in the charge domain, to perform a read or multiplication operation on the ROM device R5, both column select lines CSL<0> and CSL<1> are set to the high voltage level VDD, while setting the remaining column select signals to the low voltage level VSS. Activate the corresponding control word-line WL<2> and set the remaining control word-lines WL to the low voltage level VSS. Depending on the desired operation, set either the data select control line Ctrl or the data select control line CtrlB to the high voltage level VDD, and set the other one to the low voltage level VSS. The result is output in the form of charge to the computing bit-line CBL through a capacitor.

The above describes partial possible implementations of the computing module in the charge domain and current domain, as well as the first type of sharing of selection devices in each possible implementation. However, this disclosure is not limited to these implementations. The computing module may have other implementations in the charge domain and current domain, as well as other sharing methods. The following provides an illustrative explanation.

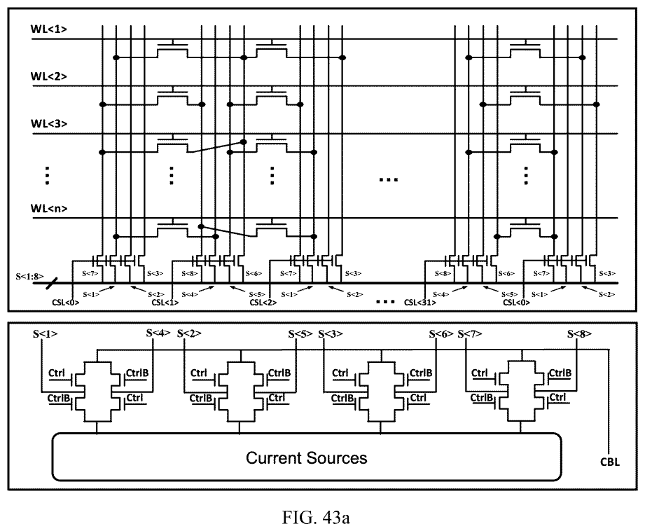

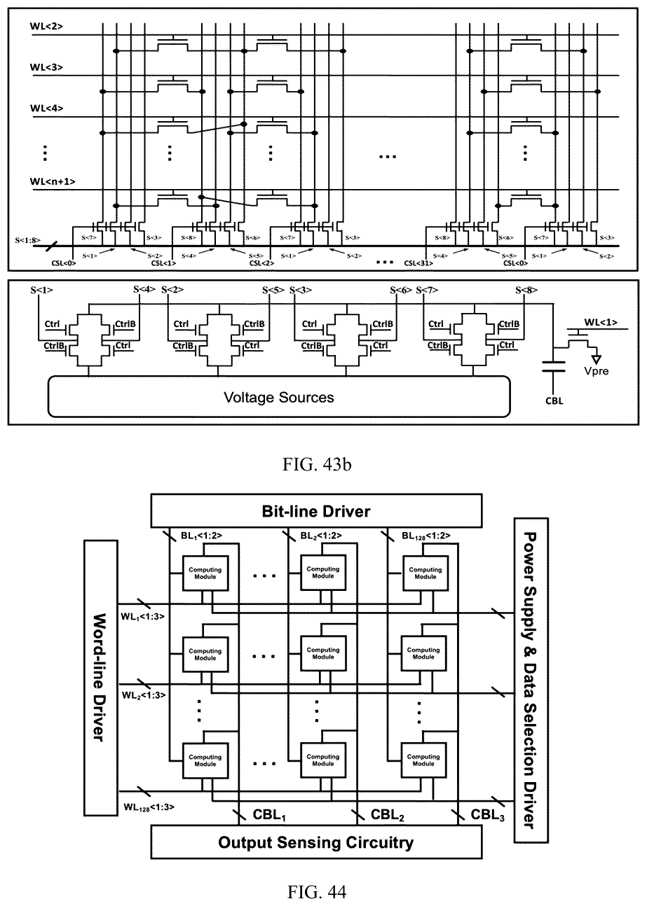

FIGS. 43a and 43b schematically illustrate the computing module implemented in the second type of sharing of selection devices in the current domain and charge domain according to embodiments of present disclosure.

In one possible implementation, as shown in FIG. 43a, the selection devices include data selection devices and column selection devices, the data selection devices include upper data selection devices and lower data selection devices, the upper data selection devices consist of the first upper data selection device Q11 and the second upper data selection device Q12, the lower data selection devices consist of the first lower data selection device Q21 and the second lower data selection device Q22, the data selection control lines include the first data selection control line CtrlB and the second data selection control line Ctrl, the data storage lines include the first data storage lines and the second data storage lines;

The input terminals of the first lower data selection device Q21 and the input terminals of the second lower data selection device Q22 are connected to each other and connected to the electrical source (such as current sources and voltage sources); The output terminal of the first lower data selection device Q21 is connected to the input terminal of the second upper data selection device Q12, and it is also connected to the input terminal of the corresponding column selection device;

The output terminal of the second lower data selection device Q22 is connected to the input terminal of the first upper data selection device Q11, and it is also connected to the input terminal of another column selection device, the output terminals of each column selection device are connected to the corresponding data storage lines;

The output terminals of the first upper data selection device Q11 and the second upper data selection device Q12 are connected to the computing bit-line;

The control terminal of the first lower data selection device Q21 and the control terminal of the first upper data selection device Q11 are both connected to the first data selection control line;

The control terminal of the second lower data selection device Q22 and the control terminal of the second upper data selection device Q12 are both connected to the second data selection control line;

The first data terminal and the second data terminal of each ROM device are respectively connected to the corresponding first data storage line and second data storage line.

In one possible implementation, the individual ROM devices within the computing module are combined in a layout consisting of multiple rows and columns. The control terminals of each row of ROM devices are connected to the same control word-line. The two data terminals of each ROM device in each column are respectively connected to the corresponding first data storage line and second data storage line. The output terminals of each upper data selection device are connected to the corresponding computing bit-line through capacitors or directly, and the desired result data is output through these computing bit-lines.

In one possible implementation, the first data storage line connected to each ROM device in the (K+1)th column is the same as the second data storage line connected to each ROM device in the Kth column, where K is an integer.

Wherein, multiple column selection devices corresponding to each column of ROM devices share the same group of data selection devices, as illustrated in FIGS. 43a and 43b, which generate signals S<1>˜S<8>. The output terminals of each first upper data selection device Q11 and each second upper data selection device Q12 in the group of data selection devices are connected to the same computing bit-line, either through capacitors or directly.

In one possible implementation, as illustrated in FIGS. 43a and 43b, data storage lines and selection devices (including lower data selection devices, upper data selection devices, and column selection devices) between adjacent column ROM devices within the CiM device may be shared. In the second type of sharing, the two data terminals of the ROM devices in the same column are connected to the corresponding column selection devices. The column selection devices connected to the data terminals of the ROM devices in the same column are controlled by two different column select lines (CSL). When performing operations on a column of ROM devices, both CSLs on the corresponding sides need to be activated simultaneously.

Furthermore, as shown in FIGS. 43a and 43b, in the second type of sharing, the data selection devices (including lower data selection devices and upper data selection devices) can be shared for all ROM devices within the computing module. By directly connecting the current source module or voltage source to the symmetrical serially connected component formed by the data selection devices (lower data selection devices and upper data selection devices) and connecting each connection point between the lower data selection devices and upper data selection devices to the corresponding column selection device, the required number of selection devices in the computing module can be further reduced, significantly improving the area efficiency of the computing module.

For example, as shown in FIGS. 43a and 43b, each column of ROM devices, along with the connected data storage lines and column selection devices, can be considered as a unit. A set of (16) data selection devices, directly connected to the electrical source, generate signals S<1>˜<8> that are respectively connected to the input terminals of the column selection devices in each unit. This enables the sharing of data selection devices and also allows for the sharing of column selection devices. For instance, as shown in FIGS. 43a and 43b, adjacent pairs of columns of ROM devices can share a set of data storage lines and column selection devices.

In the current domain and charge domain, the control method for performing read or multiplication operations on the ROM devices in the second type of sharing method is the same as the first type of sharing method, and will not be further elaborated here.

FIG. 44 schematically illustrates the structure of the CiM device according to embodiments of the present disclosure.

In one possible implementation, as illustrated in FIG. 44, multiple computing modules can be combined in a layout of several rows and columns through electrical connections. In this implementation, the control word-lines of computing modules in the same row are electrically connected, the control bit-lines of computing modules in the same column are electrically connected, and the computing bit-lines of computing modules in the same column are electrically connected.

In one possible implementation, as illustrated in FIG. 44, multiple computing modules are arranged in a layout of several rows and columns. The control bit-lines and computing bit-lines of some or all computing modules in the same column are electrically connected, while the control word-lines of some or all computing modules in the same row are electrically connected. Each control word-line is driven by a word-line driver, and each control bit-line is driven by a bit-line driver. Each computing module is connected to a power supply and data selection driver. The computing bit-lines of each computing module are connected to an output sensing circuitry. Each computing module supports MAC operations based on the computing bit-lines. The MAC operations can be performed parallelly on multiple compute bit-lines.

In one possible implementation, the target operations include multiplication, data reading, and MAC operations, in the case of multiplication, the result data is the product of the stored data of the corresponding ROM device at the respective moment and the input data from the control word-line, in the case of data reading operation, the result data is the stored data of the corresponding read-only memory device at the respective moment, the result data also includes the MAC result.

The control module is further used to control one or multiple columns of computing modules to perform MAC operations, and/or control a portion or all of the computing modules connected to the same compute bit-line to perform MAC operations;

Specifically, the control module input a set of data through the control word-line and select the computing modules participating in the MAC operation, select the ROM devices participating in the calculation in each computing module using the control word-line, select the stored data participating in the calculation using the data selection control line, perform the multiplication operation between the input data and the stored data in each computing module, accumulate the multiplication results from each computing module through the computing bit-line and output the MAC result.

The following provides an illustrative example of possible implementations to achieve the target operations.

The embodiments of the present disclosure control each computing module to realize multiplication operation. The following is an illustrative description on the operation using the computing modules in the current domain and charge domain shown in FIGS. 4b and 5b.

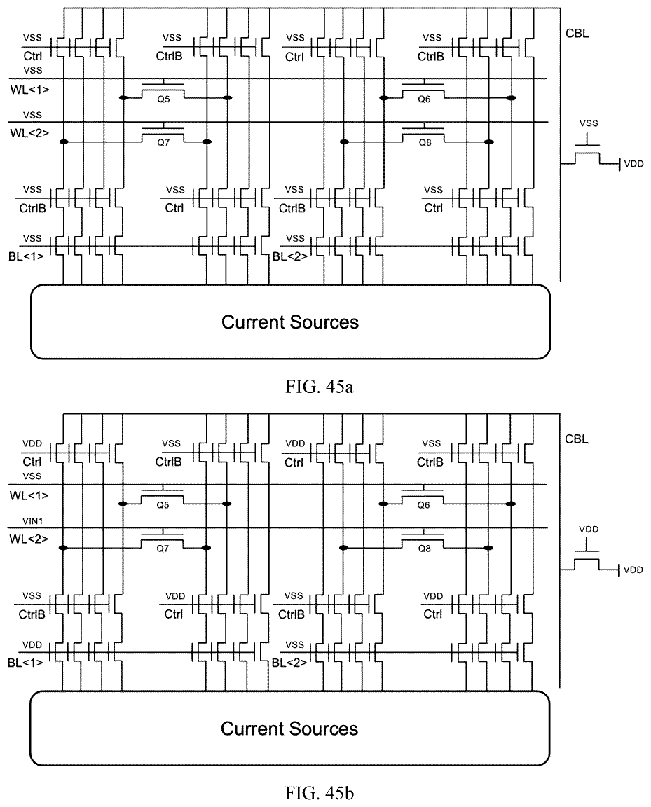

FIGS. 45a and 45b schematically illustrate the multiplication operation of the computing module implemented in the current domain according to embodiments of present disclosure.

In one example, as shown in FIG. 45a, the data selection control lines Ctrl and CtrlB serve as global control signals for the CiM device. Therefore, the data selection control lines Ctrl and CtrlB can be simultaneously set to a low voltage level (VSS) to set all computing modules in idle mode. Alternatively, one of them can be set to a high voltage level (VDD) and the other to a low voltage level (VSS) to set some computing modules in working mode. Regardless of the configuration of data selection control lines, computing modules could be set into idle mode with no current flow inside by the following configuration: all word-lines WL<1:2> and all bit-lines BL<1:2> are set to VSS to disconnect computing modules from the computing bit-line CBL.

In another example, as shown in FIG. 45b, the control bit-line BL<1> and the data selection control line Ctrl are set to high level VDD; the control bit-line BL<2>, the control word-line WL<1> and the data selection control line CtrlB are set to low level VSS; through setting the voltage of the control word-line WL<1> to VIN1, a multiplication operation can be performed on the input data VIN1 and the data stored by the ROM device Q7 when Ctrl is at high level VDD, and the output sensing circuitry senses the current on the computing bit-line CBL to obtain the result of the multiplication operation.

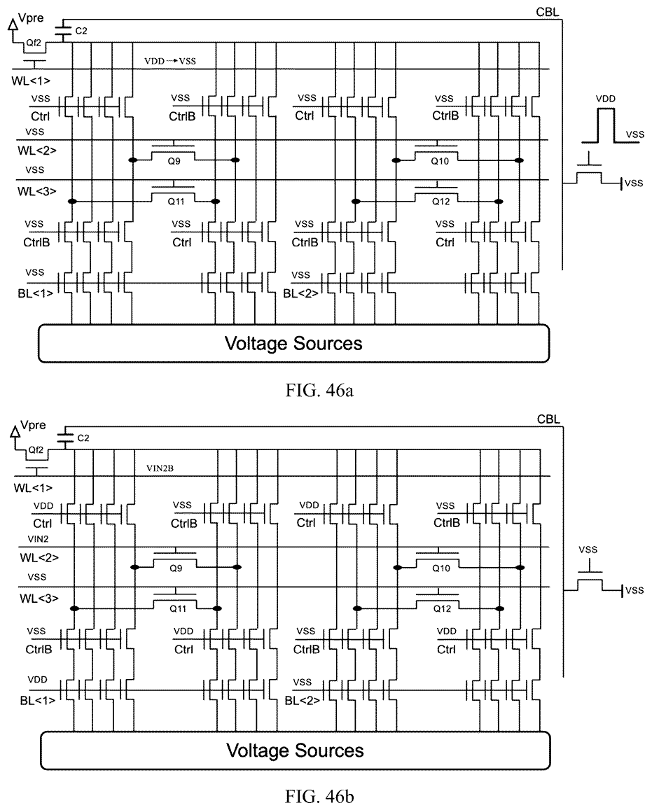

FIGS. 46a and 46b schematically illustrate the multiplication operation of the computing module implemented in the charge domain according to embodiments of present disclosure.

In one example, as shown in FIG. 46a, the data selection control lines Ctrl and CtrlB are global control signals of the CiM device. Therefore, Ctrl and CtrlB can be simultaneously set to low level VSS to set all computing module into the idle mode, and can also be configured such that one of them is at high level VDD while the other is at low level VSS to set some computing modules into the working mode. Regardless of the configuration of data selection control lines, computing modules could be set into idle state by the following process: first, WL<1> is set to high level VDD, and the control word-lines WL<2:3> and all the control bit-lines BL<1:2> are set to low level VSS in order to clear the charge on the bottom plate of the capacitor C2 and the computing bit-line CBL, and then the control word-line WL<1> is set to low level VSS to set the computing bit-line CBL into floating state.

In another example, as shown in FIG. 46b, the control bit-line BL<1> and the data selection control line Ctrl are set to high level VDD, and the control bit-line BL<2> and the data selection control line CtrlB are set to low level VSS; through setting the voltage of the control word-line WL<2> to VIN2 and setting the voltage of the control word-line WL<1> to be complimentary to that of WL<2>, a multiplication operation can be performed on the input data VIN2 and the data stored by the ROM device Q9 when Ctrl is at high level VDD, and the output sensing circuitry senses the amount of charge on the computing bit-line CBL to obtain the result of the multiplication operation.

In one possible implementation, the disclosed example may also include MAC operations. The control module may control the corresponding control word-lines, control bit-lines, and data selection control lines to select the corresponding stored data from the ROM devices participating in the computation within the CiM device's computing modules. By realizing one or more computing bit-lines, MAC operations of the computing modules connected with the same computing bit-line are carried out simultaneously.

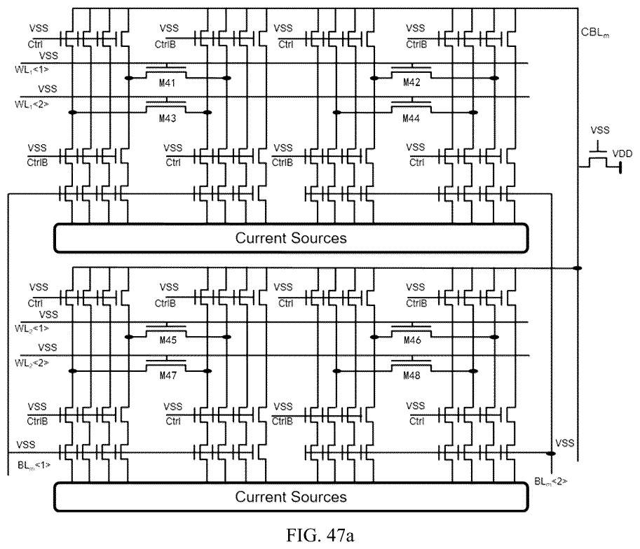

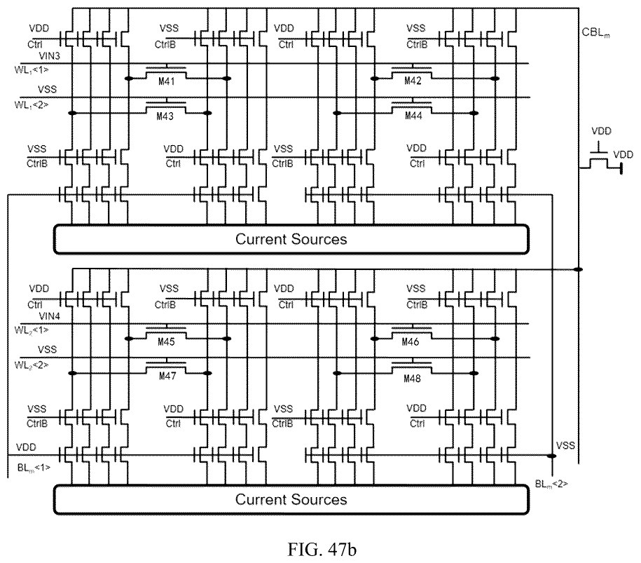

FIGS. 47a and 47b schematically illustrate the Multiply- and Accumulate (MAC) operation of the computing module implemented in the current domain according to embodiments of present disclosure.

In an example, as illustrated in FIG. 47a, the data selection control lines Ctrl and CtrlB are global control signals. Therefore, Ctrl and CtrlB can be simultaneously set to low level VSS to set all computing module into the idle mode, and can also be configured such that one of them is at high level VDD while the other is at low level VSS to set some computing modules into the working mode. Regardless of the configuration of data selection control lines, computing modules could be set into idle mode with no current flow inside by the following configuration: all word-lines WL₁<1:2>, WL₂<1:2> and all bit-lines BLₘ<1:2> are set to VSS to disconnect computing modules from the computing bit-line CBLₘ.

In another example, as shown in FIG. 47b, the control bit-line BLₘ<1> and the data selection control line Ctrl are set to high level VDD; the control bit-line BLₘ<2>, the control word-line WL₁<2>, WL₂<2> and the data selection control line CtrlB are set to low level VSS. By setting the control word-lines WL₁<1> and WL₂<1> to VIN3 and VIN4 respectively, setting the voltage of the control word-line WL₁<1> to be complimentary to that of WL₁<2>, multiplication operations can be performed on the input data VIN3 and the data stored in ROM device M41 as well as on the input data VIN4 and the data stored in the ROM device M45 when Ctrl is at high level VDD; the output sensing circuitry senses the current on the computing bit-line CBLₘ, accumulating the corresponding multiplication results according to Kirchhoff's Current Law (KCL), and obtain the result of the MAC operation in the form of current accumulation.

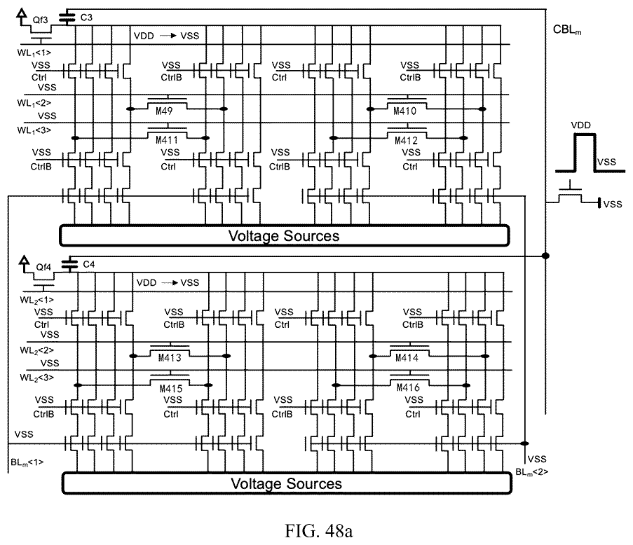

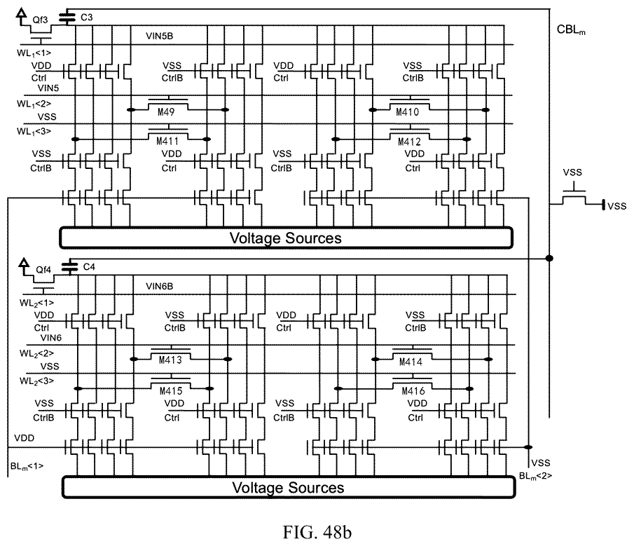

FIGS. 48a and 48b schematically illustrate the Multiply- and Accumulate (MAC) operation of the computing module implemented in the charge domain according to embodiments of present disclosure.

In an example, as illustrated in FIG. 48a, the data selection control lines Ctrl and CtrlB are global control signals of the computing array. Therefore, Ctrl and CtrlB can be simultaneously set to low level VSS to set all computing module into the idle mode, and can also be configured such that one of them is at high level VDD while the other is at low level VSS to set some computing modules into the working mode. Regardless of the configuration of data selection control lines, computing modules could be set into idle state by the following process: first, WL₁<1> and WL₂<1> are set to high level VDD, and the control word-lines WL₁<2:3> and WL₂<2:3> and all the control bit-lines BLₘ<1:2> are set to low level VSS to clear the charge on the computing bit-line CBLₘ and the lower plates of the capacitors C3 and C4; then, the control word-lines WL₁<1> and WL₂<1> are set to low level VSS to set the computing bit-line CBLₘ into floating state.

In another example, as shown in FIG. 48b, the control bit-line BLₘ<1> and the data selection control line Ctrl are set to high level VDD, the control bit-line BLₘ<2> and the data selection control line CtrlB are set to low level VSS. By setting the control word-lines WL₁<2> and WL₂<2> to VIN5 and VIN6 respectively, setting the voltage of the control word-line WL₁<1> to be complimentary to that of WL₁<2>, and setting the voltage of WL₂<1> to be complimentary to that of WL₂<2>, multiplication operations can be performed on the input data VIN5 and the data stored in ROM device M49 as well as on the input data VIN6 and the data stored in the ROM device M413 when Ctrl is at high level VDD; the output sensing circuitry senses the amount of charge on the computing bit-line CBLₘ, accumulating the corresponding multiplication results according to capacitive coupling or the redistribution of charges, and obtain the result of the MAC operation in the form of charges.

In one possible implementation, the control module is further used to control each computing module to enter the working mode or idle mode. In the working mode, each computing module performs the target operations.

Exemplarily, the computing modules of the CiM device of the embodiments of the present disclosure can be configured to the working mode or the idle mode. Wherein, in the working mode, the read, multiply and MAC operations can be performed; by controlling the voltage levels of the control word-lines and control bit-lines, the computing module can be set to the idle mode, thereby reducing energy consumption. In addition, data are stored through hard-wiring the data terminal of the ROM device with the corresponding data storage lines to realize the non-volatile characteristics of the CiM device according to embodiments of the present disclosure.

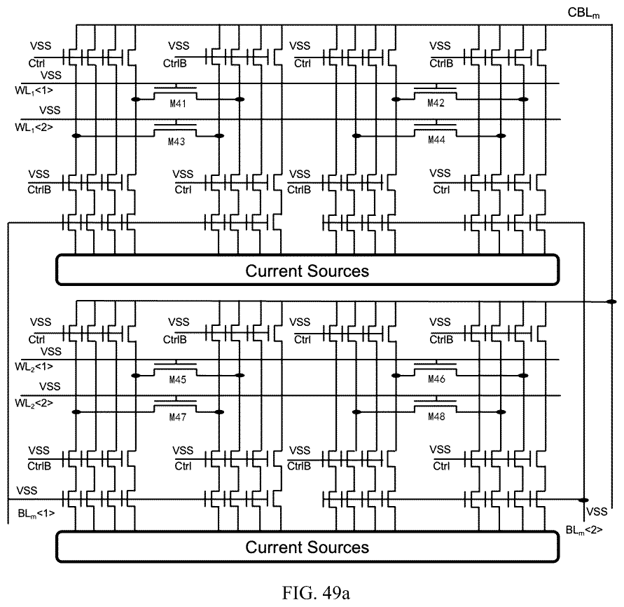

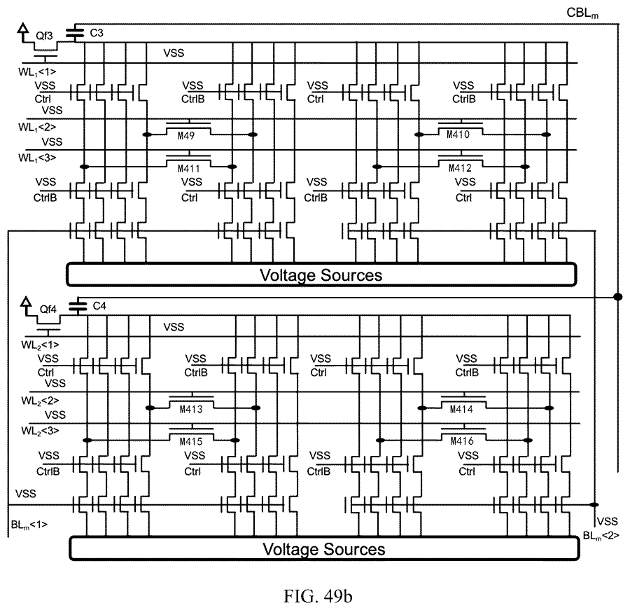

FIGS. 49a and 49b schematically illustrate the idle mode of the computing module implemented in the current domain and the charge domain according to embodiments of present disclosure.

In an example, as illustrated in FIGS. 47a and 47b, in embodiments of the present disclosure, by setting all the control word-lines and control bit-lines to low level VSS, the computing modules of the CiM device are set to the idle mode, thus reducing unnecessary energy consumption.

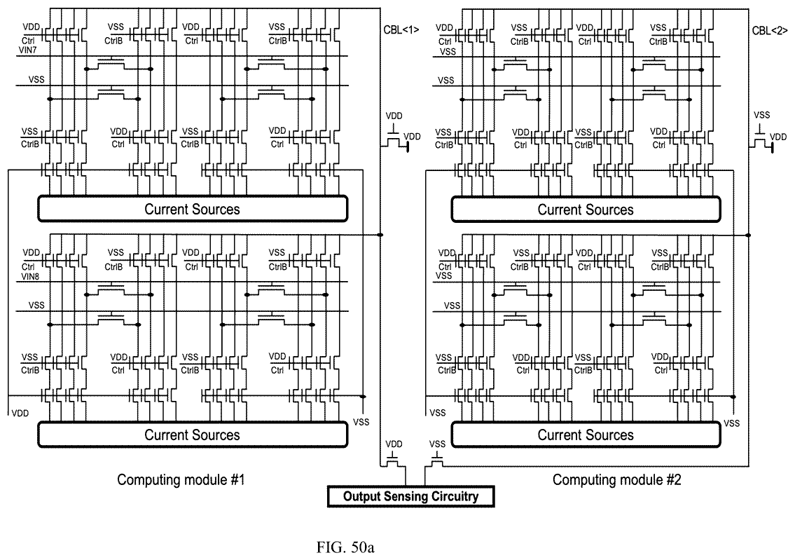

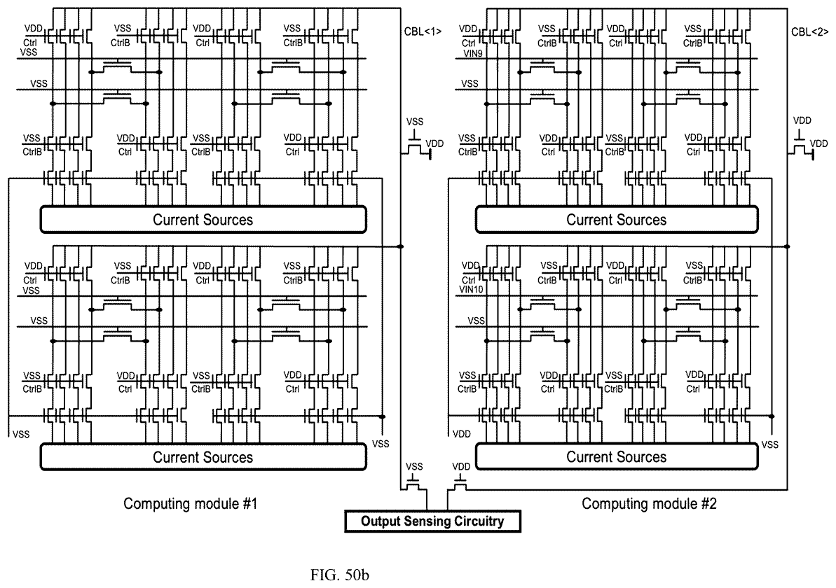

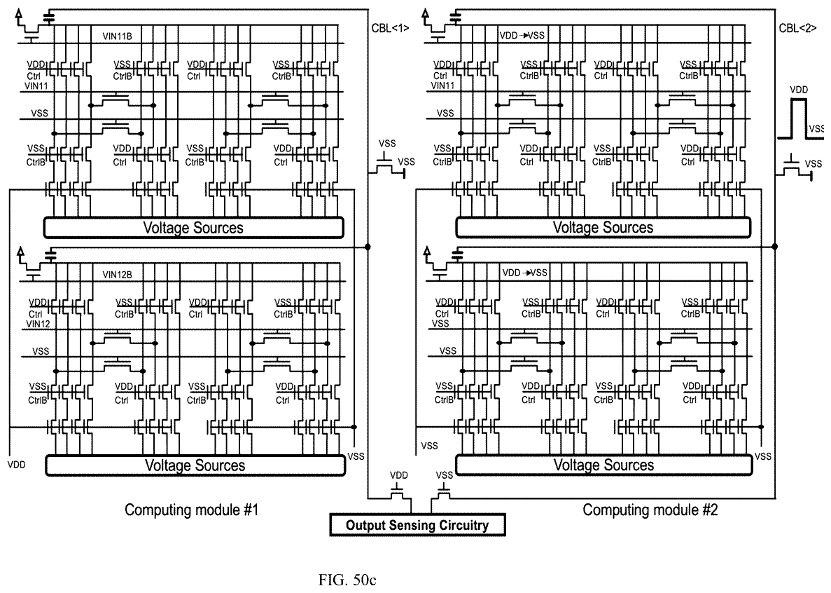

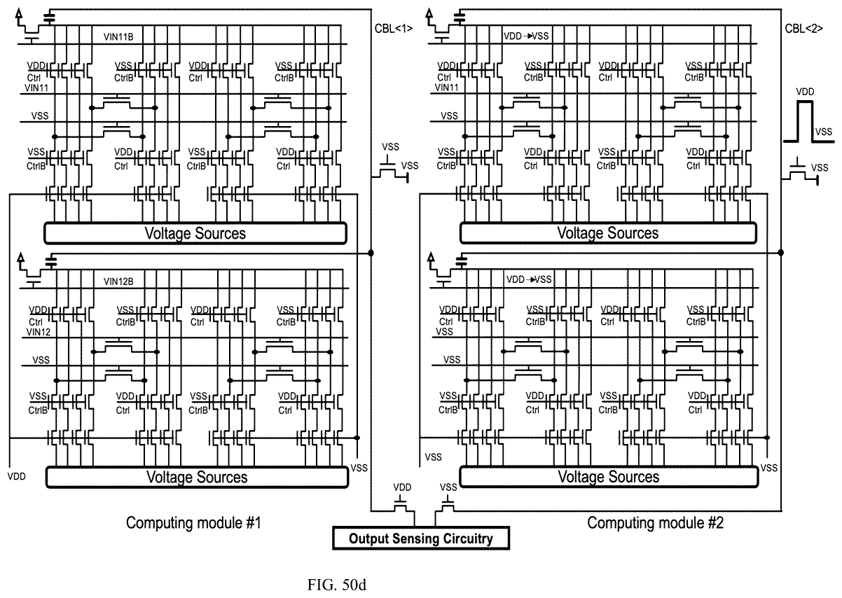

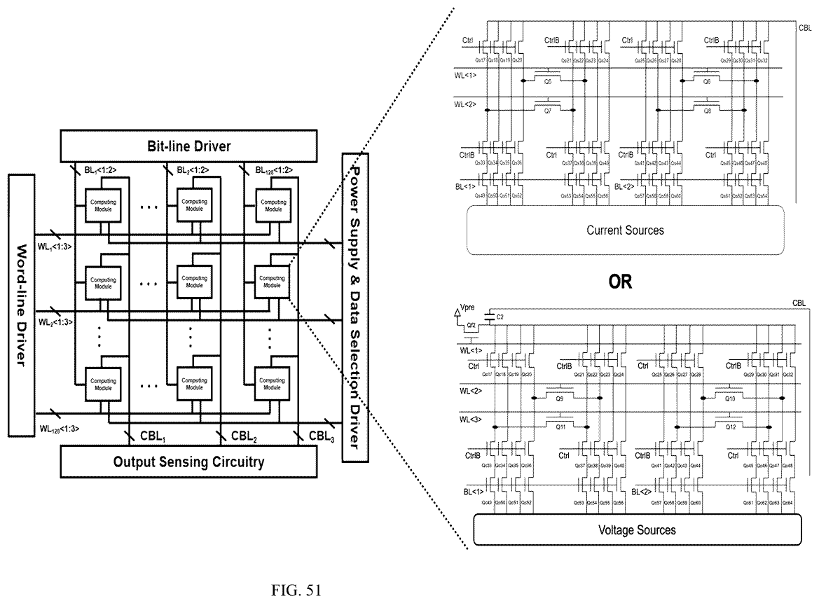

FIGS. 50a, 50b, 50c and 50d schematically illustrate the pipeline operation of the CiM device according to embodiments of present disclosure.

In an example, the computing modules in the aforementioned examples that perform MAC operations can be used with other circuits, for example, one or more switching devices can be inserted between the computing modules. In embodiments of the present disclosure, MOSFET is adopted as the switching device; by adjusting the timing of signals such as the control word-lines and the control bit-lines, pipelined operations between the computation and output detection interfaces of computing modules connected to different computing bit-lines can be implemented.

In another example, the pipelined operation may refer to the operation such that the result of the previous computing module is passed to the current computing module via the computing bit-line CBL and participates the compute operation of the current computing module, then the result of the current computing module is passed to the next computing module via the computing bit-line CBL.

In an example, as illustrated in FIG. 50a and FIG. 50b, a pipelined operation can be implemented with the configuration of the current-domain computing module.

In an example, as illustrated in FIG. 50c and FIG. 50d, a pipelined operation can be implemented with the configuration of the charge-domain computing module.

In the disclosed embodiments, by adjusting the timing of the signals of the control word-lines and the control bit-lines, pipelined operations can be achieved between the MAC operations and the output detection interfaces of computing modules connected to different computing bit-lines, therefore improving the throughput and output detection interface utilization of the system.

The specific timing of the control word-lines and control bit-lines during pipeline operations is not limited in the disclosed example. Those skilled in the art can choose appropriate methods to implement it based on practical considerations and requirements.

According to one aspect of the disclosure, a neural network accelerator is provided, which includes the aforementioned CiM device.

FIG. 51 schematically illustrates the neural network accelerator according to embodiments of present disclosure.

As illustrated in FIG. 51, the neural network accelerator is composed of a computing array composing of a word-line driver, a bit-line driver and computing arrays, and external modules such as the output detection interface, wherein, the weights of the neural network model can be stored by the electric connections between the ROM devices and the data storage lines according to embodiments of the present disclosure, and the input data such as feature maps can be inputted via the control word-lines, thus implementing MAC operations between the input values and the weight values in the computing array of the neural network accelerator; through detecting the electric characteristics of the computing bit-lines with the output detection interface, the detected analog output signals can be converted to corresponding digital signals and then be outputted.

In an exemplary embodiment, this disclosed example can be used to accelerate the inference of fixed-point neural network.

According to one aspect of the disclosure, an electronic device is provided, which includes the aforementioned neural network accelerator.

Based on the above description, in this disclosed example, the use of ROM for weight storage in the in-memory computing device is utilized. By making full use of both terminals of the ROM devices and employing selection device sharing methods, the CiM device exhibits high storage density characteristics. Traditional 6T SRAM structures use 6 transistors to store 1-bit of information, whereas in this disclosed example, a single transistor can be used to store multi-bit information in a ROM device. In an exemplary embodiment, a single ROM device can be used to store 4-bit information, greatly increasing the storage density and enabling the chip to have the potential to store all parameters of large-scale neural networks on-chip, thereby reducing or even eliminating the additional power consumption and delay caused by data movement between on-chip processing unit and off-chip memory, and reducing the energy consumption and delay during inference. This enables efficient deployment of artificial intelligence algorithms on edge or terminal devices.

The present disclosure may be a system, a method and/or a computer program product. The computer program product may comprise the computer-readable storage medium, which carried the compute-readable program instructions that are used for the processor to realize various aspects of the present disclosure.

The computer-readable storage medium may be a tangible device that can hold and store instructions used by the instruction execution device. The computer-readable storage medium may be, for example, but is not limited to, an electrical storage device, a magnetic storage device, an optical storage device, an electromagnetic storage device, a semiconductor storage device, or any suitable combination of the foregoing. More specific examples of computer-readable storage medium (a non-exhaustive list) include terminalable computer diskettes, hard disks, random access memory (RAM), read-only memory (ROM), erasable programmable read-only memory (EPROM or flash memory), static random access memory (SRAM), compact disc read-only memory (CD-ROM), digital versatile disc (DVD), memory stick, floppy disk, mechanically encoded device, a hole card or a raised structure in a groove with instructions stored thereon, and any suitable combination of the above. The computer-readable storage medium as used herein shall not be construed as transient signals per se, such as radio waves or other freely propagating electromagnetic waves, electromagnetic waves propagating through waveguides or other transmission media (e.g., pulses of light through fiber optic cables), or transmitted electrical signals.

The computer-readable program instructions described herein may be downloaded from the computer-readable storage medium to each computing/processing device or downloaded to an external computer or external storage device through a network, such as the Internet, a local area network, a wide area network, and/or a wireless network. The network may include copper transmission cables, fiber optic transmission, wireless transmission, routers, firewalls, switches, gateway computers, and/or edge servers. A network adapter card or a network interface in each computing/processing device receives computer-readable program instructions from the network and forwards the computer-readable program instructions for storage in the computer-readable storage medium of each computing/processing device.

Computer program instructions for performing the operations of the present disclosure may be assembly instructions, instruction set architecture (ISA) instructions, machine instructions, machine-dependent instructions, microcode, firmware instructions, state setting data, or source or object code written in one or any combination of more programming languages, wherein the programming language includes object-oriented programming languages—such as Smalltalk, C++, etc., and conventional procedural programming languages—such as the “C” language or similar programming languages. The computer-readable program instructions may be executed entirely on the user's computer, partly on the user's computer, as a stand-alone software package, partly on the user's computer and partly on a remote computer, or entirely on the remote computer or server. In cases involving a remote computer, the remote computer may be connected to the user computer through any kind of network, such as a local area network (LAN) or a wide area network (WAN), or it may be connected to an external computer (such as through the Internet via an Internet service provider). In some embodiments, the computer-readable program instructions may be executed by electronic circuits that can be customized using the state information of computer-readable program instructions such as programmable logic circuits, field programmable gate arrays (FPGAs), and programmable logic arrays (PLAs), thereby realizing the various aspects of the present disclosure.

Various aspects of the present disclosure are described here with reference to the methods and the flowcharts and/or block diagrams of the apparatuses (systems) and computer program products according to embodiments of the present disclosure. It shall be understood that each block of the flowcharts and/or block diagrams, and combinations of the blocks of the flowcharts and/or block diagrams, may be implemented with computer-readable program instructions.

These computer-readable program instructions may be provided to a processor of a general-purpose computer, a special-purpose computer, or other programmable data processing apparatus to produce a machine so that when the instructions are executed by the processor of the computer or other programmable data processing apparatus, the apparatus for realizing the functions/actions specified in one or more blocks of the flowcharts and/or block diagrams is produced. These computer-readable program instructions may also be stored in a computer-readable storage medium, and these instructions cause computers, programmable data processing devices, and/or other devices to work in a specific manner so that the computer-readable medium storing instructions includes an article of manufacture comprising instructions for implementing the various aspects of the functions/actions specified in one or more blocks of the flowcharts and/or block diagrams.

The computer-readable program instructions may also be loaded into a computer, other programmable data processing device, or other equipment; thereby a series of operational steps are performed on the computer, other programmable data processing device, or other equipment to produce a computer-implemented process, so that instructions executed on computers, other programmable data processing devices, or other devices implement the functions/actions specified in one or more blocks in the flowcharts and/or block diagrams.

The flowcharts and block diagrams in the drawings illustrate the systems, methods, as well as system architectures, functionalities, and operations that can be implemented by computer program products according to the various embodiments of the present disclosure. In this regard, each block in a flowchart or block diagram may represent a module, a terminalion of a program segment, or an instruction that includes one or more executable instructions. In some alternative implementations, the functionalities noted in the blocks may occur out of the order noted in the drawings. For example, two blocks in successive may in fact be executed substantially concurrently, or they may sometimes be executed in the reverse order, depending upon the functionality involved. It shall also be noted that each block of the block diagrams and/or flowcharts, and combinations of blocks in the block diagrams and/or flowchart illustration, may be implemented with a dedicated hardware-based system that performs the specified function or action, or may be implemented with a combination of dedicated hardware and computer instructions.

The computer program product may be implemented by means of hardware, software, or a combination thereof. In an optional embodiment, the computer program product is embodied as a computer storage medium. In another optional embodiment, the computer program product is embodied as a software product, such as a software development kit (SDK), etc.

Various embodiments of the present disclosure are described above. The foregoing descriptions are exemplary, not exhaustive, and are not limited to the disclosed embodiments. Many modifications and alterations will be apparent to a person skilled in the art without departing from the scope and spirit of the described embodiments. The terminology used herein is chosen to best explain the principles of each embodiment, the practical applications, or improvements over technologies in the market, or to enable a person skilled in the art to understand each embodiment disclosed herein.

1. A compute-in-memory apparatus, wherein the apparatus comprises:
a computing array, which includes a plurality of computing modules, the computing module comprises at least one storage cell, a reset switch and a capacitor, the storage cell comprises at least one storage switch, wherein:
the storage switch comprises a storage control terminal, a storage detection terminal and a storage terminal, the storage terminal is connected to a data storage line to receive a storage state voltage and information associated with the storage state voltage, the storage control terminal is connected to a control word-line to receive a control voltage to adjust the impedance characteristic between the storage detection terminal and the storage terminal;
the reset switch comprises a reset control terminal, a reset detection terminal and a reset terminal, the reset control terminal is connected to a control word-line to receive a reset voltage to adjust the impedance characteristic between the reset detection terminal and the reset terminal;
the reset terminal is connected to a reset state voltage line to receive a reset state voltage, the reset detection terminal and a first terminal of the capacitor are connected to an output terminal of at least one storage module, a second terminal of the capacitor is connected to a computing bit-line;
a control module, which is connected to the computing array to control the computing array to perform at least one of a store operation, a read operation and a compute operation.

2. The apparatus of claim 1, wherein the storage cell comprises a first storage switch and a second storage switch, the storage detection terminals of both the first storage switch and the second storage switch are connected to the output terminal of the storage cell.

3. The apparatus of claim 1, wherein the computing module additionally comprises a selection switch, the selection switch comprises a selection control terminal, a first detection terminal and a second detection terminal, wherein:
the selection control terminal is connected to a control bit line to receive a control voltage to adjust the impedance characteristic between the first detection terminal and the second detection terminal;
the first detection terminal is connected to the output terminal of the storage cell, the second detection terminal is connected to each storage detection terminal.

4. The apparatus of claim 3, wherein the storage cell comprises a first selection switch, a second selection switch, a third storage switch, a fourth storage switch, a fifth storage switch and a sixth storage switch,
the first detection terminals of the first selection switch and the second selection switch are connected to the output terminal of the storage cell, the second detection terminal of the first selection switch is connected to the storage detection terminals of the third storage switch and the fourth storage switch, the selection control terminal of the first selection switch is connected to a first control bit line, and the selection control terminal of the second selection switch is connected to a second control bit line;
the storage control terminals of the third storage switch and the fifth storage switch are connected to a second control word-line, the storage terminals of both the third storage switch and the fourth storage switch are connected to a first data storage line, the storage control terminals of the fourth storage switch and the sixth storage switch are connected to a third control bit line, and the storage terminals of the fifth storage switch and the sixth storage switch are connected to a second data storage line.

5. The apparatus of claim 1, wherein the compute operation includes a multiply-and-accumulate operation, the control module is additionally used to:
activate the storage control terminal of the storage switch of the storage cell of a target computing module, thereby a logic AND operation is performed on the information carried by the control word-line connected to the storage control terminal of the activated storage switch and the information associated with the storage state voltage of the storage terminal of the activated storage switch;
obtain a result of the multiply-and-accumulate operation via the computing bit-line.

6. The apparatus of claim 3, wherein the compute operation includes a multiply-and-accumulate operation, the control module is additionally used to:
activate the storage control terminal of the storage switch of the storage cell of the target computing module and the selection control terminal of the selection switch connected with the storage switch, thereby a logic AND operation is performed on the information carried by the control word-line which is connected to the storage control terminal of the activated storage switch and the information associated with the storage state voltage of the storage terminal of the activated storage switch;
obtain a result of the logic AND operation via the computing bit-line.

7. The apparatus of claim 1, wherein the compute operation includes a logic AND operation, the control module is additionally used to:
activate the reset control terminal of the reset switch of a target computing module and the computing bit-line, thereby a voltage difference is maintained between the two terminals of the capacitor of the target computing module;
turn off the reset control terminal and set the computing bit-line into floating state;
input a set of operands for the logic AND operation via the reset control terminal, the control word-line connected to the storage control terminal of the storage switch and the data storage line connected to the storage terminal of the storage switch;
obtain a result of the logic AND operation on the set of operands via the computing bit-line.

8. The apparatus of claim 1, wherein within the same column of the computing array, the control bit lines and computing bit-lines of at least one computing module are connected; within the same row of the computing array, the control word-lines, data storage lines and reset state voltage lines of at least one computing module are connected.

9. The apparatus of claim 8, wherein the compute operation includes a multiply-and-accumulate operation, the control module is additionally used to:
control one or more columns of computing modules of the computing array to perform a multiply-and-accumulate operation, and/or control some or all of the computing modules connected to the same computing bit-line to perform the multiply-and-accumulate operation.

10. The apparatus of claim 8, wherein the control module is additionally used to:
control the computing modules connected to different computing bit-lines to perform a pipelined compute operation.

11. The apparatus of claim 8, wherein the control module is additionally used to:
control each control word-line, control bit line, computing bit-line, data storage line and reset state voltage line to be grounded, whereby the computing array enters an idle mode.

12. A neural network accelerator, wherein the neural network accelerator comprises at least one neural network module, the neural network module comprises at least one original convolutional layer, and the original convolutional layer comprises a backbone layer that has fixed weights and a branch layer that has adjustable weights. The backbone layer comprises one or more convolutional layers, and the branch layer at least comprises a first branch convolutional layer, a second branch convolutional layer, and a third branch convolutional layer, which are sequentially connected. The input channel number of the first branch convolutional layer is equal to that of the backbone layer, the output channel number of the third branch convolutional layer is equal to that of the backbone layer, the input channel number of the second branch convolution layer is smaller than that of the backbone layer, and the output channel number of the second branch convolution layer is smaller than that of the backbone layer,
the backbone layer and the convolutional layers of the branch layer are implemented using the compute-in-memory apparatus.

13. The neural network accelerator of claim 12, wherein the backbone layer and the first branch layer are used to receive an input to the neural network, and an output of the neural network module is obtained by aggregating the output of the backbone layer and the output of the third branch convolution layer.

14. The neural network accelerator of claim 12, wherein in a training process of the neural network accelerator, the weights of each backbone layer are fixed, and/or the weight gradient of the backbone layer is zero in a back-propagation stage of the training process, and the weights of each branch layer are adjusted by gradient descent.

15. An electronic device, wherein the electronic device includes:
compute-in-memory apparatus, wherein the apparatus comprises:
a computing array, which includes a plurality of computing modules, the computing module comprises at least one storage cell, a reset switch and a capacitor, the storage cell comprises at least one storage switch, wherein:
the storage switch comprises a storage control terminal, a storage detection terminal and a storage terminal, the storage terminal is connected to a data storage line to receive a storage state voltage and information associated with the storage state voltage, the storage control terminal is connected to a control word-line to receive a control voltage to adjust the impedance characteristic between the storage detection terminal and the storage terminal;
the reset switch comprises a reset control terminal, a reset detection terminal and a reset terminal, the reset control terminal is connected to a control word-line to receive a reset voltage to adjust the impedance characteristic between the reset detection terminal and the reset terminal;
the reset terminal is connected to a reset state voltage line to receive a reset state voltage, the reset detection terminal and a first terminal of the capacitor are connected to an output terminal of at least one storage module, a second terminal of the capacitor is connected to a computing bit-line; and
a control module, which is connected to the computing array to control the computing array to perform at least one of a store operation, a read operation and a compute operation; and
a neural network accelerator, wherein the neural network accelerator comprises at least one neural network module, the neural network module comprises at least one original convolutional layer, and the original convolutional layer comprises a backbone layer that has fixed weights and a branch layer that has adjustable weights, the backbone layer comprises one or more convolutional layers, and the branch layer at least comprises a first branch convolutional layer, a second branch convolutional layer, and a third branch convolutional layer, which are sequentially connected, the input channel number of the first branch convolutional layer is equal to that of the backbone layer, the output channel number of the third branch convolutional layer is equal to that of the backbone layer, the input channel number of the second branch convolution layer is smaller than that of the backbone layer, and the output channel number of the second branch convolution layer is smaller than that of the backbone layer, wherein the backbone layer and the convolutional layers of the branch layer are implemented using the compute-in-memory apparatus.
